(19) United States
(12) Patent Application Publication
(10) Pub. No.: US 2025/0275475 A1
(43) Pub. Date: Aug. 28, 2025

(54) ORGANIC LIGHT EMITTING DIODE AND ORGANIC LIGHT EMITTING DEVICE INCLUDING THE SAME

(71) Applicants: LG Display Co., Ltd., Seoul (KR); Research & Business Foundation SUNGKYUNKWAN UNIVERSITY, Suwon-si (KR)

(72) Inventors: Suk-Young BAE, Paju-si (KR); Dong-Ryun LEE, Paju-si (KR); Han-Jin AHN, Paju-si (KR); Jun-Yun KIM, Paju-si (KR); Jun-Yeob LEE, Suwon-si (KR); Sook-Hee JEONG, Suwon-si (KR); Jin-Ho PARK, Suwon-si (KR)

(73) Assignees: LG Display Co., Ltd., Seoul (KR); Research & Business Foundation SUNGKYUNKWAN UNIVERSITY, Suwon-si (KR)

(21) Appl. No.: 19/006,911

(22) Filed: Dec. 31, 2024

(30) Foreign Application Priority Data
Feb. 26, 2024 (KR) 10-2024-0027300

(51) Int. Cl. H10K 85/60; H10K 50/12; H10K 50/13; H10K 50/19; H10K 85/30; H10K 85/40; H10K 101/00; H10K 101/10; H10K 101/20; H10K 101/30; H10K 101/40

(52) U.S. Cl. CPC H10K 85/658; H10K 50/12; H10K 50/13; H10K 50/19; H10K 85/346; H10K 85/40; H10K 85/615; H10K 85/636; H10K 85/6572; H10K 2101/10; H10K 2101/20; H10K 2101/27; H10K 2101/30; H10K 2101/40; H10K 2101/90

(57) ABSTRACT

Organic light-emitting diodes and organic light emitting devices including the same are described. The organic light emitting diode can include a first electrode; a second electrode facing the first electrode; and a first blue emitting material layer including a first compound, a second compound and a third compound and positioned between the first and second electrodes. The first compound is an n-type host, the second compound is a p-type host, and the third compound is a dopant or an auxiliary host.

### CROSS-REFERENCE TO RELATED APPLICATIONS

The present application claims priority to Korean Patent Application No. 10-2024-0027300 filed in the Republic of Korea on Feb. 26, 2024, which is hereby incorporated by reference in its entirety into the present application.

### BACKGROUND

### Technical Field

The present disclosure relates to an organic light emitting diode, and more particularly, to an organic light emitting diode having an advantage in at least one of a driving voltage, an emitting efficiency, a color purity and a lifespan and an organic light emitting device including the organic light emitting diode.

### Discussion of the Background Art

A need for flat panel display devices having small occupied area has increased. Among the flat panel display devices, a technology of an organic light emitting display device, which includes an organic light emitting diode (OLED) and can be called to as an organic electroluminescent device, is rapidly developed.

The OLED emits light by injecting electrons from a cathode as an electron injection electrode and holes from an anode as a hole injection electrode into an emitting material layer (EML), combining the electrons with the holes, generating an exciton, and transforming the exciton from an excited state to a ground state.

However, the related art OLED can have a limitation in an emitting performance, e.g., a driving voltage, an emitting efficiency, a color purity and a lifespan. In particular, a blue OLED has a big limitation in the emitting performance.

### SUMMARY OF THE DISCLOSURE

Accordingly, embodiments of the present disclosure are directed to an OLED and an organic light emitting device that substantially obviate one or more of the problems associated with the limitations and disadvantages of the related art.

An aspect of the present disclosure is to provide an OLED and an organic light emitting device having an advantage in at least one of a driving voltage, an emitting efficiency, a color purity and a lifespan.

Additional features and aspects will be set forth in the description that follows, and in part will be apparent from the description, or can be learned by practice of the present disclosure concepts provided herein. Other features and aspects of the present disclosure concepts can be realized and attained by the structure particularly pointed out in the written description, or derivable therefrom, and the claims hereof as well as the appended drawings.

To achieve these and other advantages in accordance with the purpose of the embodiments of the present disclosure, as described herein, an aspect of the present disclosure is an organic light emitting diode comprising a first electrode; a second electrode facing the first electrode; and a first blue emitting material layer including a first compound, a second compound and a third compound and positioned between the first and second electrodes, wherein the first compound is represented by Formula 1:

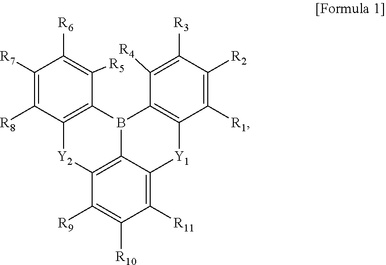

wherein in Formula 1, at least one of R₁ to R₁₁ is represented by Formula 1-1, at least another one of R₁ to R₁₁ is represented by Formula 1-2, each of the rest of R₁ to R₁₁ is independently selected from the group consisting of hydrogen, deuterium, halogen, cyano, a substituted or unsubstituted C1 to C20 alkyl group, a substituted or unsubstituted C3 to C30 cycloalkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group, or optionally, adjacent two of the rest of R₁ to R₁₁ are combined to form a ring, each of Y₁ and Y₂ is independently selected from O or NR₁₂, R₁₂ is selected from the group consisting of a substituted or unsubstituted C1 to C20 alkyl group, a substituted or unsubstituted C3 to C30 cycloalkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group,

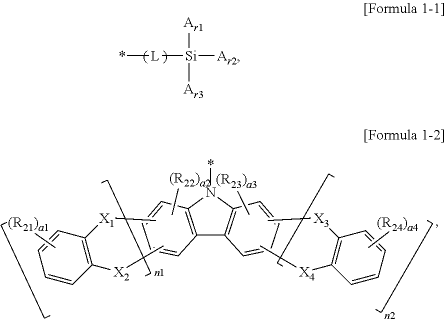

wherein in Formula 1-1, L is selected from a substituted or unsubstituted C6 to C30 arylene group, and each of Ar₁, Ar₂ and Ar₃ is independently selected from a substituted or unsubstituted C6 to C30 aryl group,
wherein in Formula 1-2, each of a1 and a4 is independently an integer of 0 to 4, each of a2 and a3 is independently an integer of 0 to 2, when a1 is 2 or more, two or more R₂₁ are same or different, when a2 is 2, two R₂₂ are same or different, when a3 is 2, two R₂₃ are same or different, when a4 is 2 or more, two or more R₂₄ are same or different, each of R₂₁, R₂₂, R₂₃ and R₂₄ is independently selected from the group consisting of deuterium, halogen, cyano, a substituted or unsubstituted C1 to C20 alkyl group, a substituted or unsubstituted C3 to C30 cycloalkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group, each of n1 and n2 is independently 0 or 1, one of X₁ and X₂ is a single bond, the other one of X₁ and X₂ is selected from O, S, Se, NR₂₅ and C(R₂₅)₂, one of X₃ and X₄ is a single bond, the other one of X₃ and X₄ is selected from O, S, Se, NR₂₆ and C(R₂₆)₂, and each of R₂₅ and R₂₆ is independently selected from the group consisting of hydrogen, deuterium, halogen, cyano, a substituted or unsubstituted C1 to C20 alkyl group, a substituted or unsubstituted C3 to C30 cycloalkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group, wherein the second compound is represented by Formula 3:

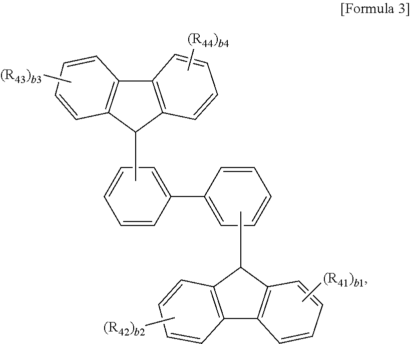

wherein in Formula 3, each of b1, b2, b3 and b4 is independently an integer of 0 to 4, when b1 is 2 or more, two or more R₄₁ are same or different, when b2 is 2 or more, two or more R₄₂ are same or different, when b3 is 2 or more, two or more R₄₃ are same or different, when b4 is 2 or more, two or more R₄₄ are same or different, and each of R₄₁ to R₄₄ is independently selected from the group consisting of deuterium, halogen, cyano, a substituted or unsubstituted C1 to C20 alkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group, and wherein the third compound is represented by Formula 5:

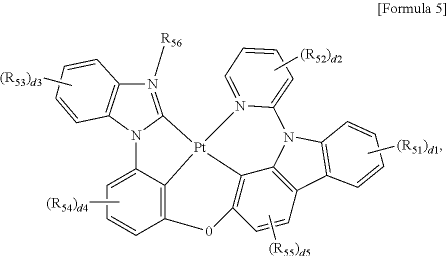

wherein in Formula 5, each of d1, d2 and d3 is independently an integer of 0 to 4, d4 is an integer of 0 to 3, d5 is an integer of 0 to 2, when d1 is 2 or more, two or more R₅₁ are same or different, when d2 is 2 or more, two or more R₅₂ are same or different, when d3 is 2 or more, two or more R₅₃ are same or different, when d4 is 2 or more, two or more R₅₄ are same or different, when d5 is 2, two R₅₅ are same or different, each of R₅₁ to R₅₅ is independently selected from the group consisting of deuterium, halogen, cyano, a substituted or unsubstituted C1 to C20 alkyl group, a substituted or unsubstituted C3 to C30 cycloalkyl group, a substituted or unsubstituted C1 to C20 alkylsilyl group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, and R₅₆ is selected from the group consisting of hydrogen, deuterium, halogen, cyano, a substituted or unsubstituted C1 to C20 alkyl group, a substituted or unsubstituted C3 to C30 cycloalkyl group, a substituted or unsubstituted C1 to C20 alkylsilyl group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group.

Another aspect of the present disclosure is an organic light emitting device comprising a substrate; the above organic light emitting diode disposed on the substrate; and an encapsulation layer covering the organic light emitting diode.

It is to be understood that both the foregoing general description and the following detailed description are exemplary and explanatory and are intended to provide further explanation of the inventive concepts.

### BRIEF DESCRIPTION OF THE DRAWINGS

The accompanying drawings, which are included to provide a further understanding of the present disclosure and are incorporated in and constitute a part of this application, illustrate embodiments of the present disclosure and together with the description serve to explain principles of the present disclosure.

FIG. 1 is a schematic circuit diagram of an organic light emitting display device according to one or more embodiments of the present disclosure.

FIG. 2 is a schematic cross-sectional view of an organic light emitting display device according to a first embodiment of the present disclosure.

FIG. 3 is a schematic cross-sectional view of an OLED according to a second embodiment of the present disclosure.

FIG. 4 is a schematic energy band diagram in an emitting material layer (EML) of an OLED according to the second embodiment of the present disclosure.

FIG. 5 is a schematic cross-sectional view of an OLED according to a third embodiment of the present disclosure.

FIG. 6 is a schematic energy band diagram in an EML of an OLED according to the third embodiment of the present disclosure.

FIG. 7 is a schematic cross-sectional view of an OLED according to a fourth embodiment of the present disclosure.

FIG. 8 is a schematic cross-sectional view of an OLED according to a fifth embodiment of the present disclosure.

FIG. 9 is a schematic cross-sectional view of an OLED according to a sixth embodiment of the present disclosure.

FIG. 10 is a schematic cross-sectional view of an organic light emitting display device according to a seventh embodiment of the present disclosure.

FIG. 11 is a schematic cross-sectional view of an organic light emitting display device according to an eighth embodiment of the present disclosure.

FIG. 12 is a schematic cross-sectional view of an OLED according to a ninth embodiment of the present disclosure.

### DETAILED DESCRIPTION OF THE EMBODIMENTS

Reference will now be made in detail to aspects of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout the specification. Names of the respective elements used in the following explanations are selected only for convenience of writing the specification and can be thus different from those used in actual products. Further, the term “can” fully encompasses all the meanings and coverages of the term “may.”

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘including’, ‘having’, ‘consisting’, and the like are used in this specification, other parts can be added unless ‘only’ is used. When a component is expressed in the singular, cases including the plural are included unless specific statement is described.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a case that is not continuous can be included unless a more limiting term, such as “just,” “immediate(ly),” or “direct(ly)” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure can be partially or overall coupled to or combined with each other, and can be variously inter-operated with each other and driven technically as those skilled in the art can sufficiently understand. The aspects of the present disclosure can be carried out independently from each other, or can be carried out together in co-dependent relationship.

A photoluminescence (PL) spectrum can be measured using an organic solvent, e.g., toluene, at room temperature, i.e., 25° C. For example, after a thin film having a thickness of 30 nm is formed using a solution, in which a compound is dissolved in an organic solvent, e.g., toluene, with about 1*10⁻⁵M, a PL spectrum can be measured using a PL detection and a fluorescent spectrometer, e.g., FS-5 fluorescent spectrometer (Edinburgh Instruments).

Various methods of determining a highest occupied molecular orbital (HOMO) energy level are known to the skilled person. For example, the HOMO energy level can be determined using a conventional surface analyser such as an AC3 surface analyser made by RKI instruments. The surface analyser can be used to interrogate a single film (neat film) of a compound with a thickness of 50 nm. The LUMO energy level can be calculated as follows:

LUMO energy level (eV)=HOMO energy level (eV)−bandgap energy level (eV).

The bandgap can be measured using a SCINCO S-3100 spectrophotometer. The HOMO and LUMO values of the compounds of the examples and embodiments disclosed herein can be determined in this way. Namely, the HOMO and LUMO values can be experimentally or empirically determined values of thin films, such as 50 nm films.

Reference will now be made in detail to some of the examples and preferred embodiments, which are illustrated in the accompanying drawings.

In an OLED and an organic light emitting device, a blue emitting material layer (EML) includes an n-type host, a p-type host and a dopant (e.g., an emitter). For example, the organic light emitting device can be an organic light emitting display device or an organic lightening device. As an example, an organic light emitting display device, which is a display device including the OLED of the present disclosure, will be mainly described.

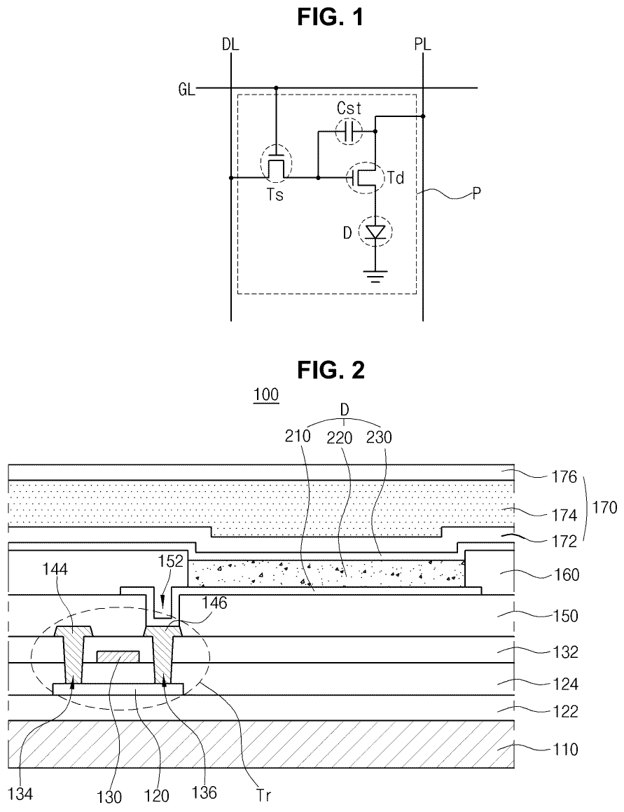

FIG. 1 is a schematic circuit diagram of an organic light emitting display device of the present disclosure.

As shown in FIG. 1, an organic light emitting display device includes a gate line GL, a data line DL, a power line PL, a switching thin film transistor TFT Ts, a driving TFT Td, a storage capacitor Cst, and an OLED D. The gate line GL and the data line DL cross each other to define a pixel region P. The pixel region P can include a red pixel region, a green pixel region and a blue pixel region.

The switching TFT Ts is connected to the gate line GL and the data line DL, and the driving TFT Td and the storage capacitor Cst are connected to the switching TFT Ts and the power line PL. The OLED D is connected to the driving TFT Td.

In the organic light emitting display device, when the switching TFT Ts is turned on by a gate signal applied through the gate line GL, a data signal from the data line DL is applied to the gate electrode of the driving TFT Td and an electrode of the storage capacitor Cst.

When the driving TFT Td is turned on by the data signal, an electric current is supplied to the OLED D from the power line PL. As a result, the OLED D emits light. In this case, when the driving TFT Td is turned on, a level of an electric current applied from the power line PL to the OLED D is determined such that the OLED D can produce a gray scale.

The storage capacitor Cst serves to maintain the voltage of the gate electrode of the driving TFT Td when the switching TFT Ts is turned off. Accordingly, even if the switching TFT Ts is turned off, a level of an electric current applied from the power line PL to the OLED D is maintained to next frame.

As a result, the organic light emitting display device displays a desired image.

FIG. 2 is a schematic cross-sectional view of an organic light emitting display device according to a first embodiment of the present disclosure.

As shown in FIG. 2, the organic light emitting display device 100 includes a substrate 110, a TFT Tr on or over the substrate 110, a planarization layer 150 covering the TFT Tr and an OLED D on the planarization layer 150 and connected to the TFT Tr. A red pixel region, a green pixel region and a blue pixel region can be defined on the substrate 110.

The substrate 110 can be a glass substrate or a flexible substrate. For example, the flexible substrate can be one of a polyimide (PI) substrate, a polyethersulfone (PES) substrate, a polyethylenenaphthalate (PEN) substrate, a polyethylene terephthalate (PET) substrate and a polycarbonate (PC) substrate.

A buffer layer 122 is formed on the substrate 110, and the TFT Tr is formed on the buffer layer 122. The buffer layer 122 can be omitted. For example, the buffer layer 122 can be formed of an inorganic insulating material, e.g., silicon oxide or silicon nitride.

A semiconductor layer 120 is formed on the buffer layer 122. The semiconductor layer 120 can include an oxide semiconductor material or polycrystalline silicon.

When the semiconductor layer 120 includes the oxide semiconductor material, a light-shielding pattern can optionally be formed under the semiconductor layer 120. The light to the semiconductor layer 120 is shielded or blocked by the light-shielding pattern such that thermal degradation of the semiconductor layer 120 can be prevented. On the other hand, when the semiconductor layer 120 includes polycrystalline silicon, impurities can be doped into both sides of the semiconductor layer 120.

A gate insulating layer 124 is formed on the semiconductor layer 120. The gate insulating layer 124 can be formed of an inorganic insulating material such as silicon oxide or silicon nitride.

A gate electrode 130, which is formed of a conductive material, e.g., metal, is formed on the gate insulating layer 124 to correspond to a center of the semiconductor layer 120. In FIG. 2, the gate insulating layer 124 is formed on an entire surface of the substrate 110. Alternatively, the gate insulating layer 124 can be patterned to have the same shape as the gate electrode 130.

An interlayer insulating layer 132 is formed on the gate electrode 130 and over an entire surface of the substrate 110. The interlayer insulating layer 132 can be formed of an inorganic insulating material, e.g., silicon oxide or silicon nitride, or an organic insulating material, e.g., benzocyclobutene or photo-acryl.

The interlayer insulating layer 132 includes first and second contact holes 134 and 136 exposing both sides of the semiconductor layer 120. The first and second contact holes 134 and 136 are positioned at both sides of the gate electrode 130 to be spaced apart from the gate electrode 130.

The first and second contact holes 134 and 136 are formed through the gate insulating layer 124 and the interlayer insulating layer 132. Alternatively, when the gate insulating layer 124 is patterned to have the same shape as the gate electrode 130, the first and second contact holes 134 and 136 is formed only through the interlayer insulating layer 132.

A source electrode 144 and a drain electrode 146, which are formed of a conductive material, e.g., metal, are formed on the interlayer insulating layer 132.

The source electrode 144 and the drain electrode 146 are spaced apart from each other with respect to the gate electrode 130 and respectively contact both sides of the semiconductor layer 120 through the first and second contact holes 134 and 136.

The semiconductor layer 120, the gate electrode 130, the source electrode 144 and the drain electrode 146 constitute the TFT Tr. The TFT Tr serves as a driving element. Namely, the TFT Tr is the driving TFT Td (of FIG. 1).

In the TFT Tr, the gate electrode 130, the source electrode 144, and the drain electrode 146 are positioned over the semiconductor layer 120. Namely, the TFT Tr has a coplanar structure.

Alternatively, in the TFT Tr, the gate electrode can be positioned under the semiconductor layer, and the source and drain electrodes can be positioned over the semiconductor layer such that the TFT Tr can have an inverted staggered structure. In this instance, the semiconductor layer can include amorphous silicon.

Optionally, the gate line and the data line cross each other to define the pixel region, and the switching TFT is formed to be connected to the gate and data lines. The switching TFT is connected to the TFT Tr as the driving element. In addition, the power line, which can be formed to be parallel to and spaced apart from one of the gate and data lines, and the storage capacitor for maintaining the voltage of the gate electrode of the TFT Tr in one frame can be further formed.

A planarization layer 150 is formed on an entire surface of the substrate 110 to cover the source and drain electrodes 144 and 146. The planarization layer 150 provides a flat top surface and has a drain contact hole 152 exposing the drain electrode 146 of the TFT Tr.

The OLED D is disposed on the planarization layer 150 and includes a first electrode 210, which is connected to the drain electrode 146 of the TFT Tr, an organic light emitting layer 220 and a second electrode 230. The organic light emitting layer 220 and the second electrode 230 are sequentially stacked on the first electrode 210. The OLED D is positioned in each of the red, green and blue pixel regions and respectively emits the red, green and blue light.

The first electrode 210 is separately formed in each pixel region. The first electrode 210 can be an anode and can include a transparent conductive oxide material layer, which can be formed of a conductive material, e.g., a transparent conductive oxide (TCO), having a relatively high work function.

For example, the transparent conductive oxide material layer can be formed of one of indium-tin-oxide (ITO), indium-zinc-oxide (IZO), indium-tin-zinc-oxide (ITZO), tin oxide (SnO), zinc oxide (ZnO), indium-copper-oxide (ICO) and aluminum-zinc-oxide (Al:ZnO, AZO).

The first electrode 210 can have a single-layered structure of the transparent conductive oxide material layer. Namely, the first electrode 210 can be a transparent electrode.

Alternatively, the first electrode 210 can further include a reflective layer to have a double-layered structure or a triple-layered structure. Namely, the first electrode 210 can be a reflective electrode.

For example, the reflective layer can be formed of one of silver (Ag), an alloy of Ag and one of palladium (Pd), copper (Cu), indium (In) and neodymium (Nd), and aluminum-palladium-copper (APC) alloy. For example, the first electrode 210 can have a double-layered structure of Ag/ITO or APC/ITO or a triple-layered structure of ITO/Ag/ITO or ITO/APC/ITO.

In addition, a bank layer 160 is formed on the planarization layer 150 to cover an edge of the first electrode 210. Namely, the bank layer 160 is positioned at a boundary of the pixel region and exposes a center of the first electrode 210 in the pixel region.

The organic light emitting layer 220 including an emitting material layer (EML) is formed on the first electrode 210. In the OLED D in the blue pixel region, the EML of the organic light emitting layer 220 includes a first compound represented by Formula 1, a second compound represented by Formula 3 and a third compound represented by Formula 5. In addition, the EML can further include a fluorescent compound represented by Formula 7.

The organic light emitting layer 220 can further include at least one of a hole injection layer (HIL), a hole transporting layer (HTL), an electron blocking layer (EBL), a hole blocking layer (HBL), an electron transporting layer (ETL) and an electron injection layer (EIL) to have a multi-layered structure.

In an aspect of the present disclosure, the organic light emitting layer 220 of the OLED D in the blue pixel region can include a first blue emitting part including a first blue EML and a second blue emitting part including a second blue EML to have a tandem structure, and at least one of the first and second blue EMLs includes the first compound represented by Formula 1, the second compound represented by Formula 3 and the third compound represented by Formula 5. In addition, at least one of the first and second blue EMLs can further include the fluorescent compound represented by Formula 7. In this case, the organic light emitting layer 220 can further include a charge generation layer (CGL) between the first and second blue emitting parts.

The second electrode 230 is formed over the substrate 110 where the organic light emitting layer 220 is formed. The second electrode 230 covers an entire surface of the display area and can be formed of a conductive material having a relatively low work function to serve as a cathode. For example, the second electrode 230 can be formed of aluminum (Al), magnesium (Mg), calcium (Ca), silver (Ag) or their alloy, e.g., Mg—Ag alloy (MgAg).

In a top-emission type OLED D, the first electrode 210 serves as a reflective electrode, and the second electrode 230 has a thin profile to serve as a transparent (or a semi-transparent) electrode. Alternatively, in a bottom-emission type OLED D, the first electrode 210 serves as a transparent electrode, and the second electrode 230 serves as a reflective electrode.

Optionally, the top-emission type OLED D can further include a capping layer on the second electrode 230. The emitting efficiency of the OLED D and the organic light emitting display device 100 including the OLED D can be further improved by the capping layer.

An encapsulation layer (or an encapsulation film) 170 is formed on the second electrode 230 to prevent penetration of moisture into the OLED D. The encapsulation layer 170 includes a first inorganic insulating layer 172, an organic insulating layer 174 and a second inorganic insulating layer 176 sequentially stacked, but it is not limited thereto.

In the bottom-emission type organic light emitting display device 100, a metal encapsulation plate can be disposed over the second electrode 230 or the encapsulation layer 170. For example, the metal encapsulation plate can be attached to the second electrode 230 or the encapsulation layer 170 using an adhesive layer.

Optionally, the organic light emitting display device 100 can include a color filter layer corresponding to the red, green and blue pixel regions. In the top-emission type organic light emitting display device 100, the color filter layer can be disposed over the OLED D. In the bottom-emission type organic light emitting display device 100, the color filter layer can be disposed between the substrate 110 and the OLED D.

The color filter layer can include red, green and blue color filters respectively corresponding to the red, green and blue pixel regions. The red color filter can include at least one of a red dye and a red pigment, the green color filter can include at least one of a green dye and a green pigment, and the blue color filter can include at least one of a blue dye and a blue pigment.

The organic light emitting display device 100 can further include a polarization plate for reducing an ambient light reflection. For example, the polarization plate can be a circular polarization plate. In the bottom-emission type organic light emitting display device 100, the polarization plate can be disposed under the substrate 110. In the top-emission type organic light emitting display device 100, the polarization plate can be disposed on or over the encapsulation layer 170.

In addition, the organic light emitting display device 100 can further include a cover window on or over the encapsulation layer 170 or the polarization plate. In this instance, the substrate 110 and the cover window have a flexible property such that a flexible organic light emitting display device can be provided.

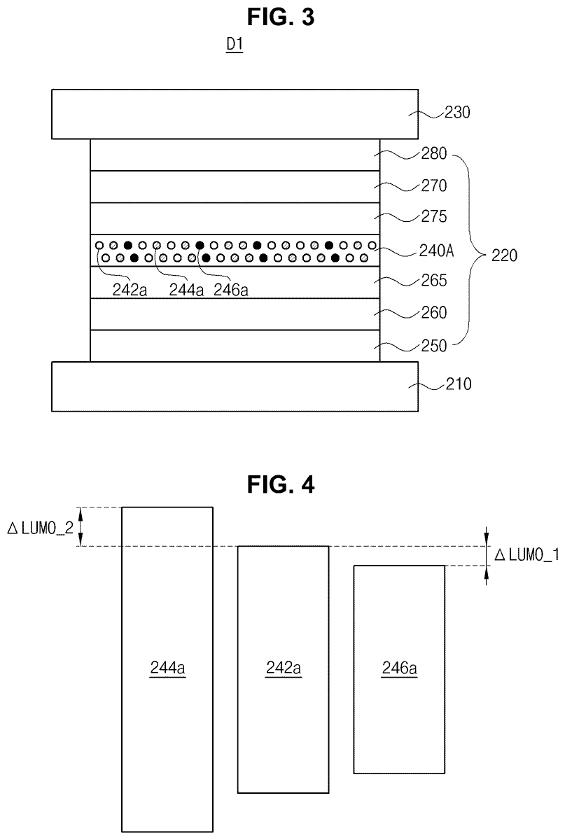

FIG. 3 is a schematic cross-sectional view of an OLED according to a second embodiment of the present disclosure.

As shown in FIG. 3, the OLED D1 includes first and second electrodes 210 and 230, which face each other, and an organic light emitting layer 220 therebetween. The organic light emitting layer 220 includes an emitting material layer (EML) 240A, e.g., a blue EML. The OLED D1 can further include a capping layer on the second electrode 230 to enhance a light extraction efficiency.

The organic light emitting display device 100 (of FIG. 2) can include a red pixel region, a green pixel region and a blue pixel region, and the OLED D1 can be positioned in the blue pixel region.

The first electrode 210 can be an anode, and the second electrode 230 can be a cathode. One of the first and second electrodes 210 and 230 can be a reflective electrode, and the other one of the first and second electrodes 210 and 230 can be a transparent (or a semi-transparent) electrode. In the bottom-emission type OLED D1, the first electrode 210 can have a single-layered structure of ITO, and the second electrode 230 can be formed of Al. The first electrode 210 can have a thickness of 10 nm to 100 nm, e.g., 40 nm to 60 nm, and the second electrode 230 can have a thickness of 100 nm to 300 nm, e.g., 150 nm to 250 nm.

The organic light emitting layer 220 can further include at least one of a hole transporting layer (HTL) 260 between the first electrode 210 and the EML 240A and an electron transporting layer (ETL) 270 between the second electrode 230 and the EML 240A.

In addition, the organic light emitting layer 220 can further include at least one of a hole injection layer (HIL) 250 between the first electrode 210 and the HTL 260 and an electron injection layer (EIL) 280 between the second electrode 230 and the ETL 270.

Moreover, the organic light emitting layer 220 can further include at least one of an electron blocking layer (EBL) 265 between the HTL 260 and the EML 240A and a hole blocking layer (HBL) 275 between the EML 240A and the ETL 270.

For example, the HIL 250 can include a hole injection material being at least one compound selected from the group consisting of 4,4′,4″-tris(3-methylphenylamino)triphenylamine (MTDATA), 4,4′,4″-tris(N,N-diphenyl-amino)triphenylamine (NATA), 4,4′,4″-tris(N-(naphthalene-1-yl)-N-phenyl-amino)triphenylamine (1T-NATA), 4,4′,4″-tris(N-(naphthalene-2-yl)-N-phenyl-amino)triphenylamine (2T-NATA), copper phthalocyanine(CuPc), tris(4-carbazoyl-9-yl-phenyl)amine (TCTA), N,N′-diphenyl-N,N′-bis(1-naphthyl)-1,1′-biphenyl-4,4″-diamine (NPB or NPD), 1,4,5,8,9,11-hexaazatriphenylenehexacarbonitrile(dipyrazino[2,3-f:2′3′-h]quinoxaline-2,3,6,7,10,11-hexacarbonitrile) (HAT-CN), 1,3,5-tris[4-(diphenylamino)phenyl]benzene (TDAPB), poly(3,4-ethylenedioxythiphene)polystyrene sulfonate (PEDOT/PSS), and N-(biphenyl-4-yl)-9,9-dimethyl-N-(4-(9-phenyl-9H-carbazol-3-yl)phenyl)-9H-fluoren-2-amine, but it is not limited thereto. In an aspect of the present disclosure, the hole injection material of the HIL 250 can be a compound in Formula 9. For example, the HIL 250 can have a thickness of 1 nm to 20 nm, e.g., 5 nm to 15 nm.

The HTL 260 can include a hole transporting material being at least one compound selected from the group consisting of N,N′-diphenyl-N,N′-bis(3-methylphenyl)-1,1′-biphenyl-4,4′-diamine (TPD), NPB(NPD), 4,4′-bis(N-carbazolyl)-1,1′-biphenyl (CBP), poly[N,N′-bis(4-butylphenyl)-N,N′-bis(phenyl)-benzidine](poly-TPD), poly[(9,9-dioctylfluorenyl-2,7-diyl)-co-(4,4′-(N-(4-sec-butylphenyl)diphenylamine))](TFB), di-[4-(N,N-di-p-tolyl-amino)-phenyl]cyclohexane (TAPC), 3,5-di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, and N-(biphenyl-4-yl)-N-(4-(9-phenyl-9H-carbazol-3-yl)phenyl)biphenyl-4-amine, but it is not limited thereto. In an aspect of the present disclosure, the hole transporting material of the HTL 260 can be a compound in Formula 10. For example, the HTL 260 can have a thickness of 30 nm to 60 nm, e.g., 40 nm to 50 nm.

The ETL 270 can include an electron transporting material being at least one of an oxadiazole-based compound, a triazole-based compound, a phenanthroline-based compound, a benzoxazole-based compound, a benzothiazole-based compound, a benzimidazole-based compound, and a triazine-based compound. For example, the ETL 270 can include at least one compound selected from the group consisting of tris-(8-hydroxyquinoline) aluminum (Alq₃), 2-biphenyl-4-yl-5-(4-t-butylphenyl)-1,3,4-oxadiazole (PBD), spiro-PBD, lithium quinolate (Liq), 1,3,5-tris(N-phenylbenzimidazol-2-yl)benzene (TPBi), bis(2-methyl-8-quinolinolato-N1,08)-(1,1′-biphenyl-4-olato)aluminum (BAlq), 4,7-diphenyl-1,10-phenanthroline (Bphen), 2,9-bis(naphthalene-2-yl)4,7-diphenyl-1,10-phenanthroline (NBphen), 2,9-dimethyl-4,7-diphenyl-1,10-phenathroline (BCP), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 1,3,5-tri(p-pyrid-3-yl-phenyl)benzene (TpPyPB), 2,4,6-tris(3′-(pyridin-3-yl)biphenyl-3-yl)1,3,5-triazine (TmPPPyTz), Poly[9,9-bis(3′-((N,N-dimethyl)-N-ethylammonium)-propyl)-2,7-fluorene]-alt-2,7-(9,9-dioctylfluorene)](PFNBr), tris(phenylquinoxaline) (TPQ), and diphenyl-4-triphenylsilyl-phenylphosphine oxide (TSPO1), but it is not limited thereto. In an aspect of the present disclosure, the electron transporting material of the ETL 270 can be a compound in Formula 13. For example, the ETL 270 can have a thickness of 10 nm to 50 nm, e.g., 20 nm to 40 nm.

The EIL 280 can include an electron injection material being at least one of an alkali halide compound, such as LiF, CsF, NaF, or BaF₂, and an organo-metallic compound, such as Liq, lithium benzoate, or sodium stearate, but it is not limited thereto. For example, the EIL 280 can have a thickness of 0.1 nm to 10 nm, e.g., 1 nm to 5 nm.

The EBL 265, which is positioned between the HTL 260 and the EML 240A to block the electron transfer from the EML 240A into the HTL 260, can include an electron blocking material being at least one compound selected from the group consisting of TCTA, tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, 1,3-bis(carbazol-9-yl)benzene (mCP), 3,3′-bis(N-carbazolyl)-1,1′-biphenyl (mCBP), CuPc, N,N′-bis[4-[bis(3-methylphenyl)amino]phenyl]-N,N′-diphenyl-[1,1′-biphenyl]-4,4′-diamine (DNTPD), TDAPB, DCDPA, and 2,8-bis(9-phenyl-9H-carbazol-3-yl)dibenzo[b,d]thiophene, but it is not limited thereto. In an aspect of the present disclosure, the electron blocking material of the EBL 265 can be a compound in Formula 11. For example, the EBL 265 can have a thickness of 5 nm to 20 nm, e.g., 5 nm to 15 nm.

The HBL 275, which is positioned between the EML 240A and the ETL 270 to block the hole transfer from the EML 240A into the ETL 270, can include the above material of the ETL 270. For example, the material of the HBL 275 has a HOMO energy level being lower than a material of the EML 240A and can be at least one compound selected from the group consisting of BCP, BAlq, Alq₃, PBD, spiro-PBD, Liq, bis-4,6-(3,5-di-3-pyridylphenyl)-2-methylpyrimidine (B3PYMPM), bis[2-(diphenylphosphino)phenyl]ether oxide (DPEPO), (9-(6-9H-carbazol-9-yl)pyridine-3-yl)-9H-3,9′-bicarbazole, and TSPO1, but it is not limited thereto. In an aspect of the present disclosure, the hole blocking material of the HBL 275 can be a compound in Formula 12. For example, the HBL 275 can have a thickness of 5 nm to 20 nm, e.g., 5 nm to 15 nm.

The EML 240A can have a thickness of 10 nm to 100 nm, e.g., 10 nm to 50 nm, preferably 20 nm to 40 nm. The EML 240A can include a first compound 242a, a second compound 244a and a third compound 246a. The first compound 242a can be an n-type host, the second compound 244a can be a p-type host, and the third compound 246a can be a dopant (e.g., an emitter).

The first compound 242a is represented by Formula 1.

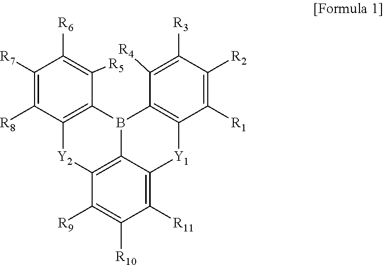

In Formula 1,
at least one of R₁ to R₁₁ is represented by Formula 1-1, at least another one of R₁ to R₁₁ is represented by Formula 1-2,
each of the rest of R₁ to R₁₁ is independently selected from the group consisting of hydrogen, deuterium, halogen, cyano, a substituted or unsubstituted C1 to C20 alkyl group, a substituted or unsubstituted C3 to C30 cycloalkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group, or optionally, adjacent two of the rest of R₁ to R₁₁ are combined to form a ring,
each of Y₁ and Y₂ is independently selected from O or NR₁₂,
R₁₂ is selected from the group consisting of a substituted or unsubstituted C1 to C20 alkyl group, a substituted or unsubstituted C3 to C30 cycloalkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group,

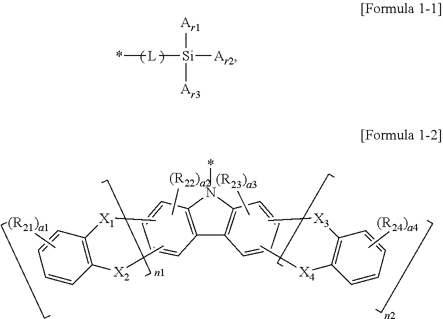

in Formula 1-1,
L is selected from a substituted or unsubstituted C6 to C30 arylene group,
each of Ar₁, Ar₂ and Ar₃ is independently selected from a substituted or unsubstituted C6 to C30 aryl group,
in Formula 1-2,
each of a1 and a4 is independently an integer of 0 to 4, each of a2 and a3 is independently an integer of 0 to 2,
when a1 is 2 or more, two or more R₂₁ are same or different, when a2 is 2, two R₂₂ are same or different, when a3 is 2, two R₂₃ are same or different, when a4 is 2 or more, two or more R₂₄ are same or different,
each of R₂₁, R₂₂, R₂₃ and R₂₄ is independently selected from the group consisting of deuterium, halogen, cyano, a substituted or unsubstituted C1 to C20 alkyl group, a substituted or unsubstituted C3 to C30 cycloalkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group,
each of n1 and n2 is independently 0 or 1,
one of X₁ and X₂ is a single bond, the other one of X₁ and X₂ is selected from O, S, Se, NR₂₅ and C(R₂₅)₂, one of X₃ and X₄ is a single bond, the other one of X₃ and X₄ is selected from O, S, Se, NR₂₆ and C(R₂₆)₂, and
each of R₂₅ and R₂₆ is independently selected from the group consisting of hydrogen, deuterium, halogen, cyano, a substituted or unsubstituted C1 to C20 alkyl group, a substituted or unsubstituted C3 to C30 cycloalkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group.

In each of Formulas 1-1 and 1-2, the mark “*” denotes a bonding site.

In the present disclosure, without specific definition, when an alkyl group, an alkoxy group, a cycloalkyl group, an alkylamino group, an alkylsilyl group, an alkenyl group, an alkynyl group, an arylamino group, an arylsilyl group, an aryloxy group, an aryl group and a heteroaryl group are substituted, a substituent can be deuterium, halogen, cyano, a cycloalkyl group, an arylamino group, an alkylamino group, an alkyl group unsubstituted or substituted with at least one of deuterium and halogen, an alkoxy group unsubstituted or substituted with at least one of deuterium and halogen, an alkylsilyl group unsubstituted or substituted with at least one of deuterium and halogen, an alkoxysilyl group unsubstituted or substituted with at least one of deuterium and halogen, an arylsilyl group unsubstituted or substituted with at least one of deuterium and halogen, an aryl group unsubstituted or substituted with at least one of deuterium and halogen, and a heteroaryl group unsubstituted or substituted with at least one of deuterium and halogen.

In the present disclosure, without specific definition, an alkyl group can include a linear alkyl group and a branched alkyl group, and can include a C1 to C20 alkyl group and a C1 to C10 alkyl group. The alkyl group can be selected from the group consisting of methyl, ethyl, propyl, butyl and tert-butyl.

In the present disclosure, without specific definition, a C3 to C30 cycloalkyl group can include a C3 to C20 cycloalkyl group and a C3 to C10 cycloalkyl group, and can be selected from the group consisting of cyclopropyl, cyclobutyl, cyclohexyl and adamantanyl.

In the present disclosure, without specific definition, a C6 to C30 arylsilyl group can be triphenylsilyl.

In the present disclosure, without specific definition, a ring, which is formed by adjacent two substituents, can be one of a substituted or unsubstituted C3 to C30 alicyclic ring, a substituted or unsubstituted C6 to C30 aromatic ring such as a phenyl ring, and a substituted or unsubstituted C3 to C30 heteroaromatic ring.

In the present disclosure, without specific definition, a C6 to C30 aryl group can include a C6 to C20 aryl group and can be selected from the group consisting of phenyl, biphenyl, terphenyl, naphthyl, anthracenyl, pentalenyl, indenyl, indenoindenyl, heptalenyl, biphenylenyl, indacenyl, phenanthrenyl, benzophenanthrenyl, dibenzophenanthrenyl, azulenyl, pyrenyl, fluoranthenyl, triphenylenyl, chrysenyl, tetraphenyl, tetracenyl, picenyl, pentaphenyl, pentacenyl, fluorenyl, indenofluorenyl and spiro-fluorenyl.

In the present disclosure, without specific definition, the C6 to C30 arylene group can include a C6 to C20 arylene group and can be selected from the group consisting of phenylene, biphenylene, terphenylene, naphthylene, anthracenylene, pentalenylene, indenylene, indenoindenylene, heptalenylene, biphenylenylene, indacenylene, phenanthrenylene, benzophenanthrenylene, dibenzophenanthrenylene, azulenylene, pyrenylene, fluoranthenylene, triphenylenylene, chrysenylene, tetraphenylene, tetracenylene, picenylene, pentaphenylene, pentacenylene, fluorenylene, indenofluorenylene, and spiro-fluorenylene.

In the present disclosure, without specific definition, a C3 to C30 heteroaryl group can include a C3 to C20 heteroaryl group and can be selected from the group consisting of pyrrolyl, pyridinyl, pyrimidinyl, pyrazinyl, pyridazinyl, triazinyl, tetrazinyl, imidazolyl, pyrazolyl, indolyl, isoindolyl, indazolyl, indolizinyl, pyrrolizinyl, carbazolyl, benzocarbazolyl, dibenzocarbazolyl, indolocarbazolyl, indenocarbazolyl, benzofurocarbazolyl, benzothienocarbazolyl, quinolinyl, isoquinolinyl, phthalazinyl, quinoxalinyl, cinnolinyl, quinazolinyl, quinozolinyl, purinyl, benzoquinolinyl, benzoisoquinolinyl, benzoquinazolinyl, benzoquinoxalinyl, acridinyl, phenanthrolinyl, perimidinyl, phenanthridinyl, pteridinyl, naphtharidinyl, furanyl, oxazinyl, oxazolyl, oxadiazolyl, triazolyl, dioxynyl, benzofuranyl, dibenzofuranyl, thiopyranyl, xanthenyl, chromanyl, isochromanyl, thioazinyl, thiophenyl, benzothiophenyl, dibenzothiophenyl, difuropyrazinyl, benzofurodibenzofuranyl, benzothienobenzothiophenyl, benzothienodibenzothiophenyl, benzothienobenzofuranyl, and benzothienodibenzofuranyl.

In the present disclosure, without specific definition, the C3 to C30 heteroarylene group can include a C3 to C20 heteroarylene group and can be selected from the group consisting of pyrrolylene, pyridinylene, pyrimidinylene, pyrazinylene, pyridazinylene, triazinylene, tetrazinylene, imidazolylene, pyrazolylene, indolylene, isoindolylene, indazolylene, indolizinylene, pyrrolizinylene, carbazolylene, benzocarbazolylene, dibenzocarbazolylene, indolocarbazolylene, indenocarbazolylene, benzofurocarbazolylene, benzothienocarbazolylene, quinolinylene, isoquinolinylene, phthalazinylene, quinoxalinylene, cinnolinylene, quinazolinylene, quinozolinylene, purinylene, benzoquinolinylene, benzoisoquinolinylene, benzoquinazolinylene, benzoquinoxalinylene, acridinylene, phenanthrolinylene, perimidinylene, phenanthridinylene, pteridinylene, cinnolinylene, naphtharidinylene, furanylene, oxazinylene, oxazolylene, oxadiazolylene, triazolylene, dioxynylene, benzofuranylene, dibenzofuranylene, thiopyranylene, xanthenylene, chromanylene, isochromanylene, thioazinylene, thiophenylene, benzothiophenylene, dibenzothiophenylene, difuropyrazinylene, benzofurodibenzofuranylene, benzothienobenzothiophenylene, benzothienodibenzothiophenylene, benzothienobenzofuranylene, and benzothienodibenzofuranylene.

In an aspect of the present disclosure, one of R₁ and R₂ can have a structure of Formula 1-1, and the other one of R₁ and R₂ can have a structure of Formula 1-2.

In an aspect of the present disclosure, R₁ can have a structure of Formula 1-1, and R₂ can have a structure of Formula 1-2.

In an aspect of the present disclosure, one of R₂ and R₃ can have a structure of Formula 1-1, and the other one of R₂ and R₃ can have a structure of Formula 1-2.

In an aspect of the present disclosure, R₃ can have a structure of Formula 1-1, and R₂ can have a structure of Formula 1-2. In an aspect of the present disclosure, one of R₂ and R₄ can have a structure of Formula 1-1, and the other one of R₂ and R₄ can have a structure of Formula 1-2. In an aspect of the present disclosure, R₄ can have a structure of Formula 1-1, and R₂ can have a structure of Formula 1-2.

In an aspect of the present disclosure, one of Y₁ and Y₂ can be O, and in particular, both Y₁ and Y₂ can be O.

In an aspect of the present disclosure, one of R₁ to R₄ can have a structure of Formula 1-2, and one of R₅ to R₈ can have a structure of Formula 1-1.

In an aspect of the present disclosure, one of R₁ to R₄ can have a structure of Formula 1-2, and one of R₉ to R₁₁ can have a structure of Formula 1-1.

In an aspect of the present disclosure, one of R₁ to R₁₁ can have a structure of Formula 1-1, and two of R₁ to R₁₁ can have a structure of Formula 1-2.

In an aspect of the present disclosure, one of R₁ to R₄ can have a structure of Formula 1-1, and the other two of R₁ to R₄ can have a structure of Formula 1-2.

In an aspect of the present disclosure, one of R₁ to R₄ can have a structure of Formula 1-1, and the other one of R₁ to R₄ and one of R₉ to R₁₁ can have a structure of Formula 1-2.

In an aspect of the present disclosure, one of R₁ to R₄ can have a structure of Formula 1-1, and the other one of R₁ to R₄ and one of R₅ to R₈ can have a structure of Formula 1-2.

In Formula 1-1, L can be a substituted or unsubstituted phenylene group, and each of Ar₁, Ar₂ and Ar₃ can independently be a substituted or unsubstituted phenyl group. Namely, the structure of Formula 1-1 can be a structure of tetraphenylsilane. For example, Formula 1-1 can be represented by Formula 1-1a.

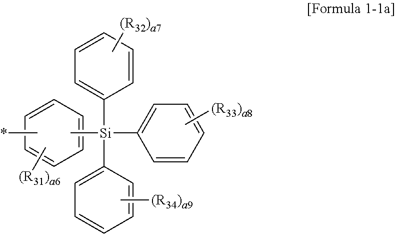

In Formula 1-1a,
a6 is an integer of 0 to 4, each of a7, a8 and a9 is independently an integer of 0 to 5,
when a6 is 2 or more, two or more R₃₁ are same or different, when a7 is 2 or more, two or more R₃₂ are same or different, when a8 is 2 or more, two or more R₃₃ are same or different, when a9 is 2 or more, two or more R₃₄ are same or different, and
each of R₃₁, R₃₂, R₃₃ and R₃₄ is independently selected from the group consisting of deuterium, halogen, cyano, a substituted or unsubstituted C1 to C20 alkyl group, a substituted or unsubstituted C3 to C30 cycloalkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group.

In Formula 1-1a, the mark “*” denotes a bonding site.

In Formula 1-2, each of n1 and n2 can be 0.

In Formula 1-2, n1 can be 0, n2 can be 1, one of X₃ and X₄ can be a single bond, and the other one of X₃ and X₄ can be NR₂₆. In this case, R₂₆ can be a substituted or unsubstituted C6 to C30 aryl group, e.g., phenyl. For example, the structure of Formula 1-2 can be represented by one of Formulas 1-2a to 1-2g.

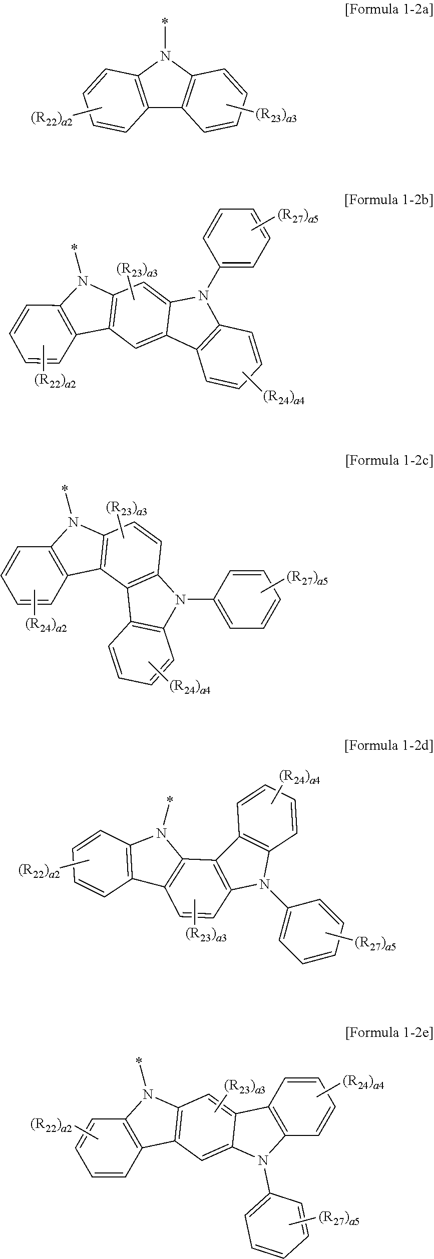

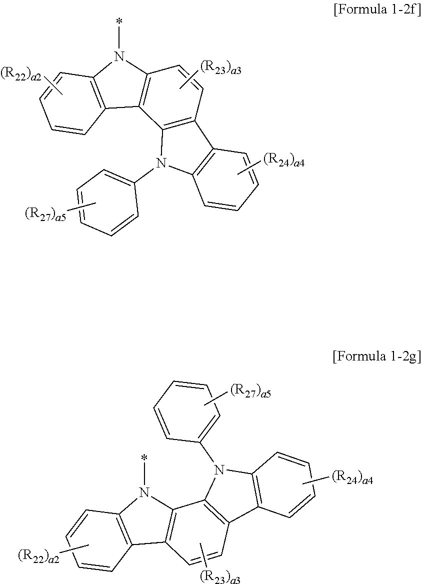

In Formula 1-2a, the definitions of R₂₂, R₂₃, a2 and a3 are same as those in Formula 1-2,
in each of Formulas 1-2b to 1-2g, the definitions of R₂₂ to R₂₄, and a2 to a4 are same as those in Formula 1-2,
a5 is an integer of 0 to 5,
when a5 is 2 or more, two or more R₂₇ are same or different, and
R₂₇ is selected from the group consisting of deuterium, halogen, cyano, a substituted or unsubstituted C1 to C20 alkyl group, a substituted or unsubstituted C3 to C30 cycloalkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group.

In each of Formulas 1-2a to 1-2g, the mark “*” denotes a bonding site.

In Formula 1-2a, each of a2 and a3 can be independently 0 or 1. In an aspect of the present disclosure, each of R₂₂ and R₂₃ can be independently carbazolyl.

In each of Formulas 1-2b to 1-2g, each of a2 to a5 can be 0.

For example, the first compound 242a can be one of the compounds in Formula 2.

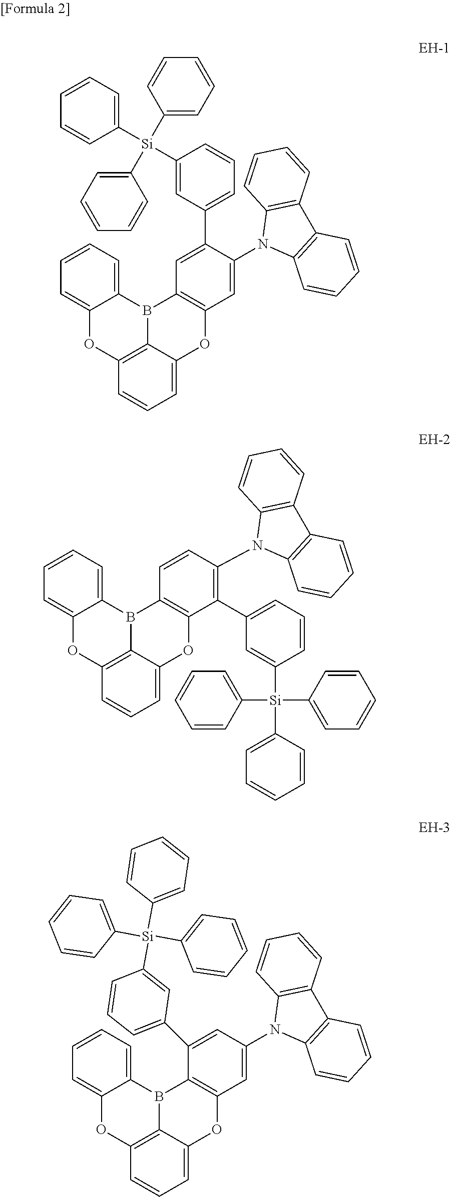 [SMILES: c1ccc([Si](c2ccccc2)(c2ccccc2)c2cccc(-c3cc4c(cc3-n3c5ccccc5c5ccccc53)Oc3cccc5c3B4c3ccccc3O5)c2)cc1 ; c1ccc([Si](c2ccccc2)(c2ccccc2)c2cccc(-c3c(-n4c5ccccc5c5ccccc54)ccc4c3Oc3cccc5c3B4c3ccccc3O5)c2)cc1 ; c1ccc([Si](c2ccccc2)(c2ccccc2)c2cccc(-c3cc(-n4c5ccccc5c5ccccc54)cc4c3B3c5ccccc5Oc5cccc(c53)O4)c2)cc1]

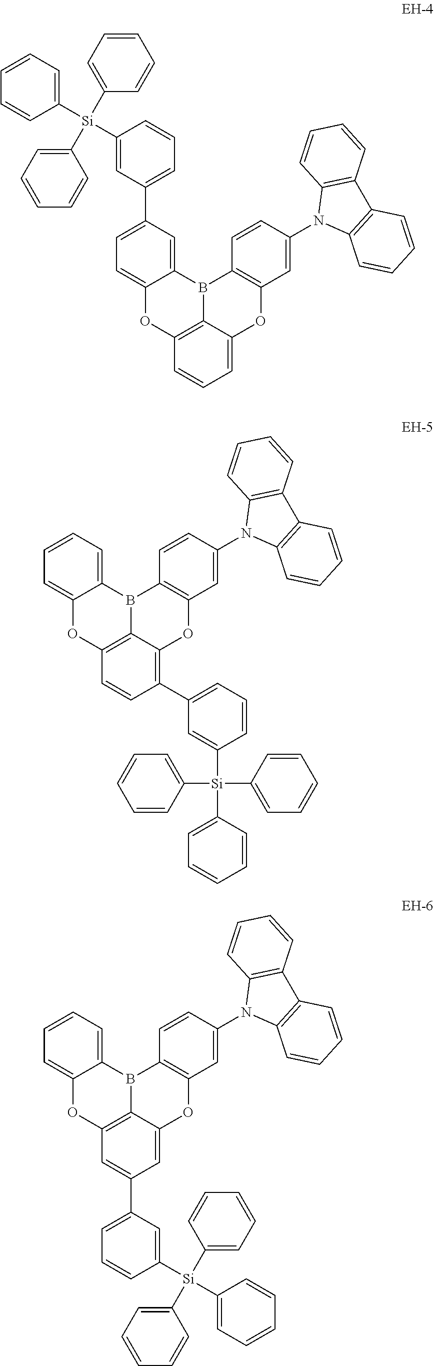

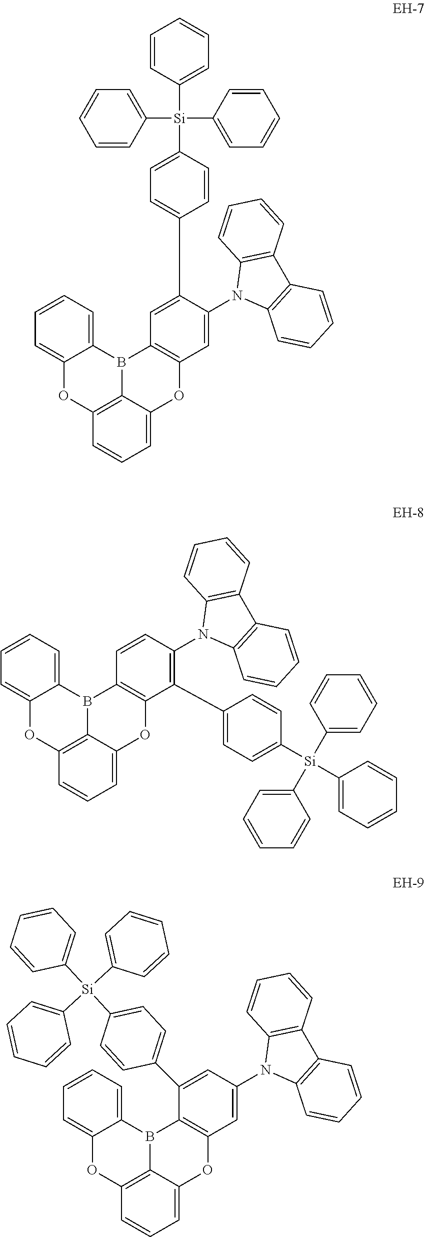 [SMILES: c1ccc([Si](c2ccccc2)(c2ccccc2)c2ccc(-c3cc4c(cc3-n3c5ccccc5c5ccccc53)Oc3cccc5c3B4c3ccccc3O5)cc2)cc1 ; c1ccc([Si](c2ccccc2)(c2ccccc2)c2ccc(-c3c(-n4c5ccccc5c5ccccc54)ccc4c3Oc3cccc5c3B4c3ccccc3O5)cc2)cc1 ; c1ccc([Si](c2ccccc2)(c2ccccc2)c2ccc(-c3cc(-n4c5ccccc5c5ccccc54)cc4c3B3c5ccccc5Oc5cccc(c53)O4)cc2)cc1]

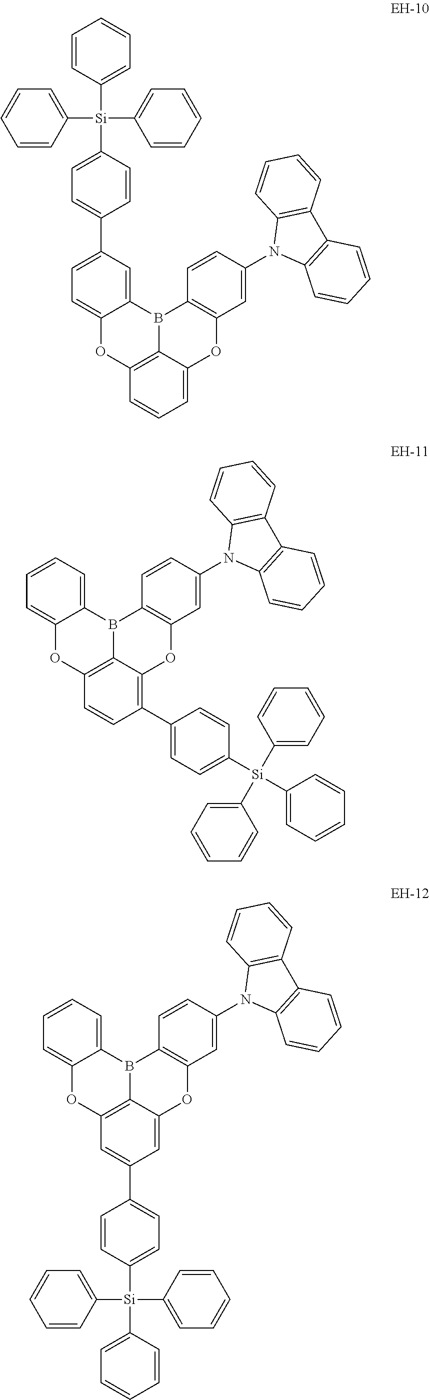 [SMILES: c1ccc([Si](c2ccccc2)(c2ccccc2)c2ccc(-c3ccc4c(c3)B3c5ccc(-n6c7ccccc7c7ccccc76)cc5Oc5cccc(c53)O4)cc2)cc1 ; c1ccc([Si](c2ccccc2)(c2ccccc2)c2ccc(-c3ccc4c5c3Oc3cc(-n6c7ccccc7c7ccccc76)ccc3B5c3ccccc3O4)cc2)cc1 ; c1ccc([Si](c2ccccc2)(c2ccccc2)c2ccc(-c3cc4c5c(c3)Oc3cc(-n6c7ccccc7c7ccccc76)ccc3B5c3ccccc3O4)cc2)cc1]

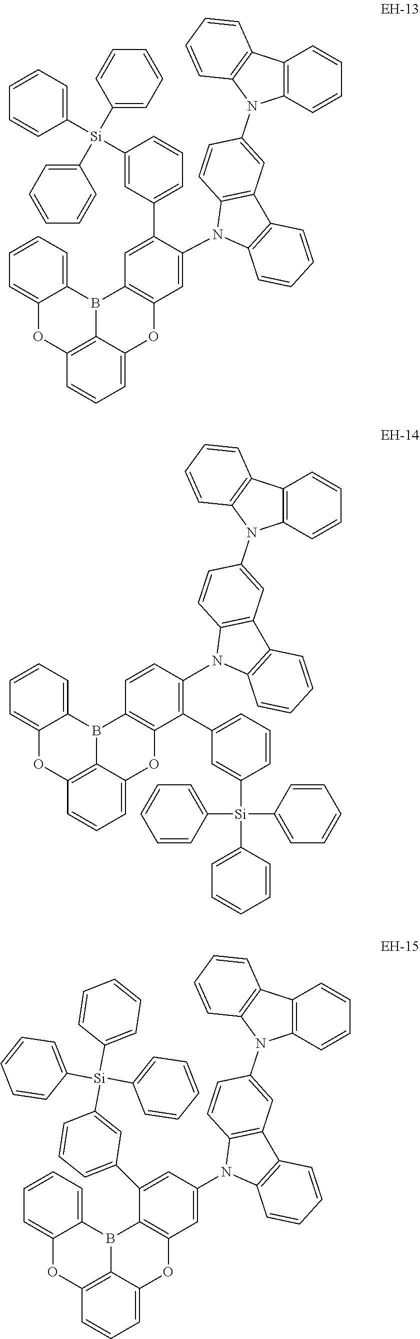

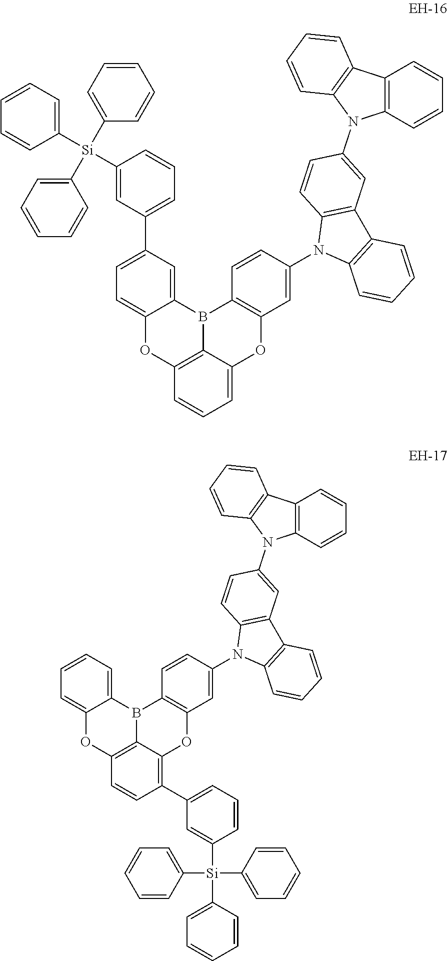 [SMILES: c1ccc([Si](c2ccccc2)(c2ccccc2)c2cccc(-c3ccc4c(c3)B3c5ccc(-n6c7ccccc7c7cc(-n8c9ccccc9c9ccccc98)ccc76)cc5Oc5cccc(c53)O4)c2)cc1 ; c1ccc([Si](c2ccccc2)(c2ccccc2)c2cccc(-c3ccc4c5c3Oc3cc(-n6c7ccccc7c7cc(-n8c9ccccc9c9ccccc98)ccc76)ccc3B5c3ccccc3O4)c2)cc1]

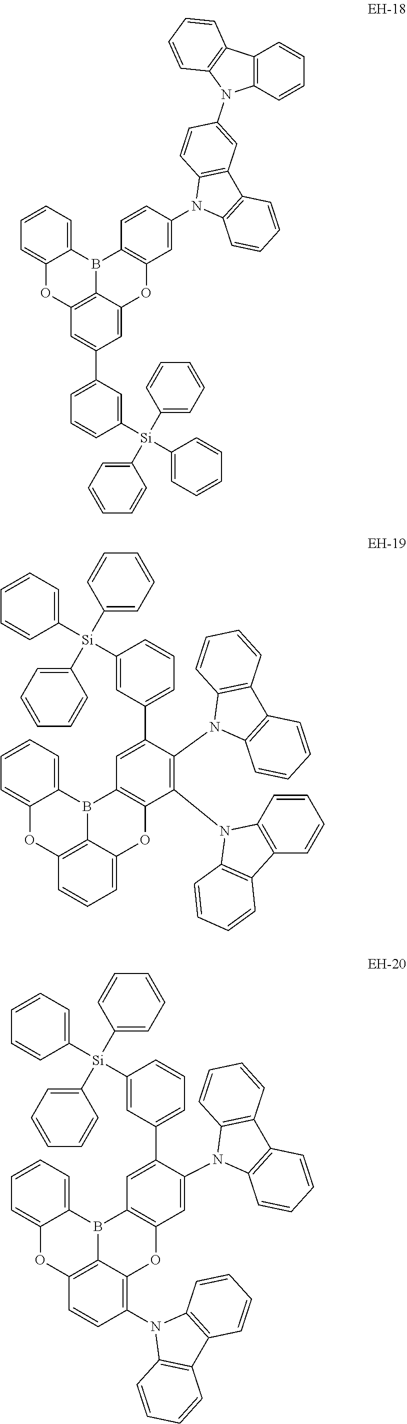

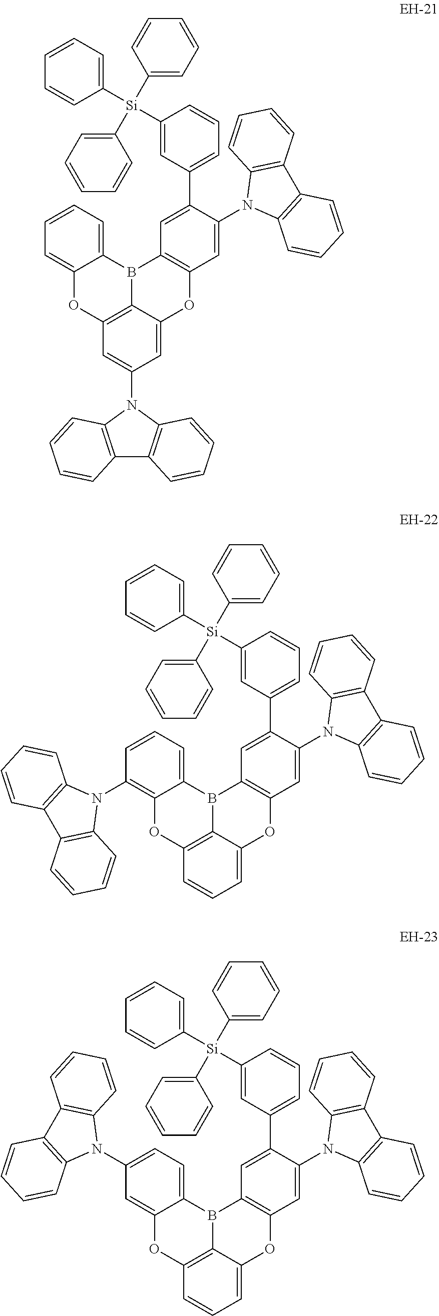 [SMILES: c1ccc([Si](c2ccccc2)(c2ccccc2)c2cccc(-c3cc4c(cc3-n3c5ccccc5c5ccccc53)Oc3cc(-n5c6ccccc6c6ccccc65)cc5c3B4c3ccccc3O5)c2)cc1 ; c1ccc([Si](c2ccccc2)(c2ccccc2)c2cccc(-c3cc4c(cc3-n3c5ccccc5c5ccccc53)Oc3cccc5c3B4c3cccc(-n4c6ccccc6c6ccccc64)c3O5)c2)cc1 ; c1ccc([Si](c2ccccc2)(c2ccccc2)c2cccc(-c3cc4c(cc3-n3c5ccccc5c5ccccc53)Oc3cccc5c3B4c3ccc(-n4c6ccccc6c6ccccc64)cc3O5)c2)cc1]

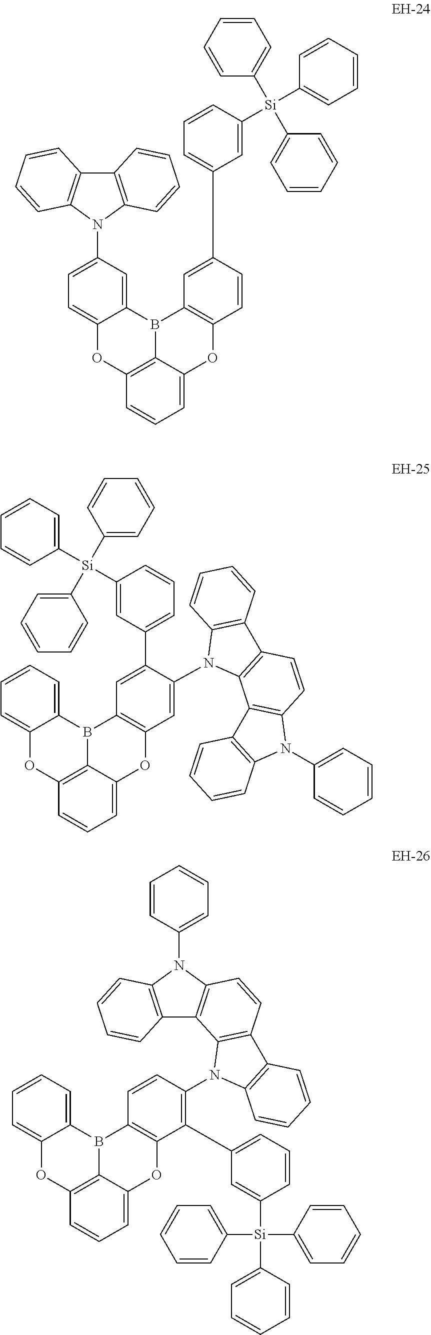 [SMILES: c1ccc([Si](c2ccccc2)(c2ccccc2)c2cccc(-c3ccc4c(c3)B3c5cc(-n6c7ccccc7c7ccccc76)ccc5Oc5cccc(c53)O4)c2)cc1 ; c1ccc(-n2c3ccccc3c3c2ccc2c4ccccc4n(-c4cc5c(cc4-c4cccc([Si](c6ccccc6)(c6ccccc6)c6ccccc6)c4)B4c6ccccc6Oc6cccc(c64)O5)c23)cc1 ; c1ccc(-n2c3ccccc3c3c2ccc2c4ccccc4n(-c4ccc5c(c4-c4cccc([Si](c6ccccc6)(c6ccccc6)c6ccccc6)c4)Oc4cccc6c4B5c4ccccc4O6)c23)cc1]

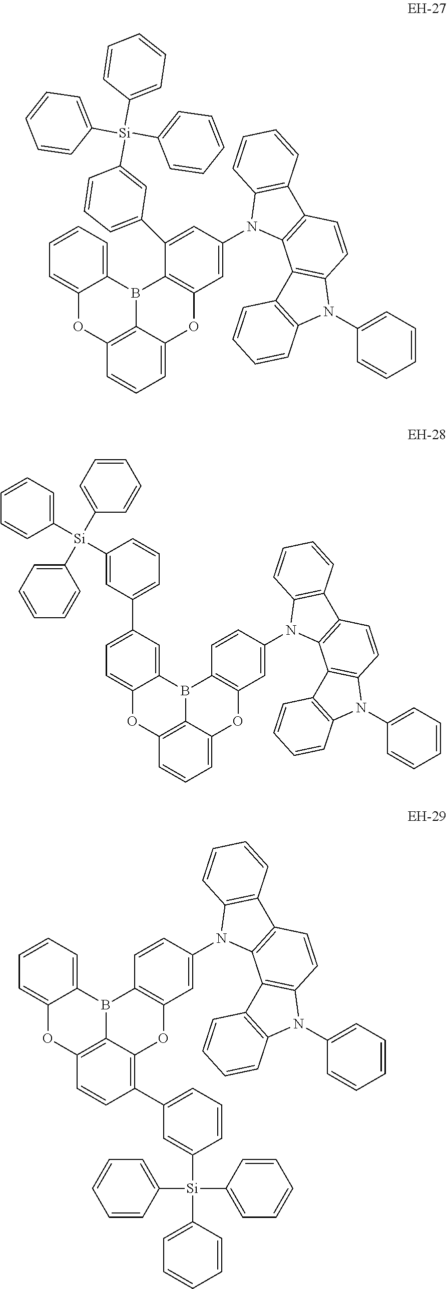 [SMILES: c1ccc(-n2c3ccccc3c3c2ccc2c4ccccc4n(-c4cc5c(c(-c6cccc([Si](c7ccccc7)(c7ccccc7)c7ccccc7)c6)c4)B4c6ccccc6Oc6cccc(c64)O5)c23)cc1 ; c1ccc(-n2c3ccccc3c3c2ccc2c4ccccc4n(-c4ccc5c(c4)Oc4cccc6c4B5c4cc(-c5cccc([Si](c7ccccc7)(c7ccccc7)c7ccccc7)c5)ccc4O6)c23)cc1 ; c1ccc(-n2c3ccccc3c3c2ccc2c4ccccc4n(-c4ccc5c(c4)Oc4c(-c6cccc([Si](c7ccccc7)(c7ccccc7)c7ccccc7)c6)ccc6c4B5c4ccccc4O6)c23)cc1]

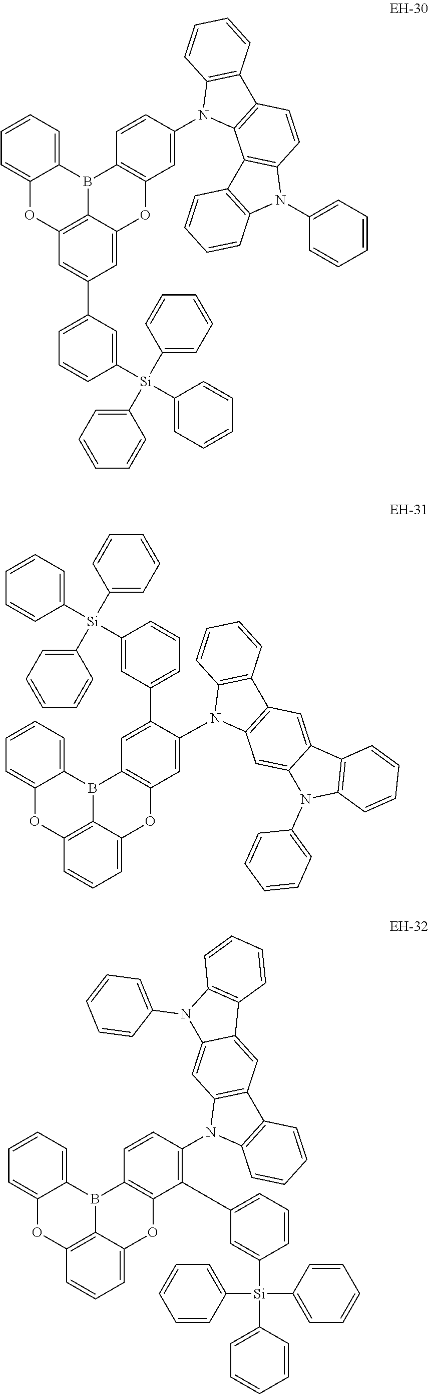 [SMILES: c1ccc(-n2c3ccccc3c3c2ccc2c4ccccc4n(-c4ccc5c(c4)Oc4cc(-c6cccc([Si](c7ccccc7)(c7ccccc7)c7ccccc7)c6)cc6c4B5c4ccccc4O6)c23)cc1 ; c1ccc(-n2c3ccccc3c3cc4c5ccccc5n(-c5cc6c(cc5-c5cccc([Si](c7ccccc7)(c7ccccc7)c7ccccc7)c5)B5c7ccccc7Oc7cccc(c75)O6)c4cc32)cc1 ; c1ccc(-n2c3ccccc3c3cc4c5ccccc5n(-c5ccc6c(c5-c5cccc([Si](c7ccccc7)(c7ccccc7)c7ccccc7)c5)Oc5cccc7c5B6c5ccccc5O7)c4cc32)cc1]

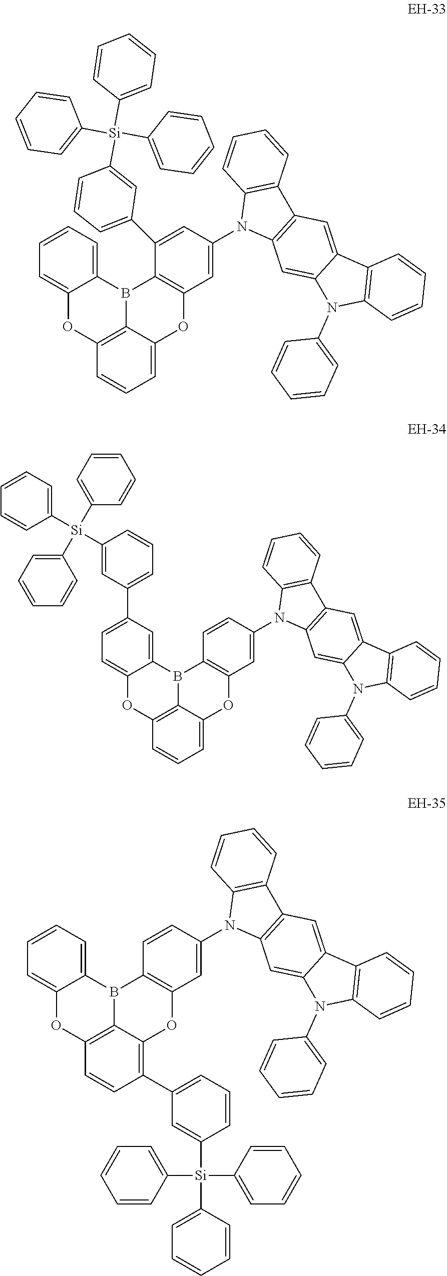 [SMILES: c1ccc(-n2c3ccccc3c3cc4c5ccccc5n(-c5cc6c(c(-c7cccc([Si](c8ccccc8)(c8ccccc8)c8ccccc8)c7)c5)B5c7ccccc7Oc7cccc(c75)O6)c4cc32)cc1 ; c1ccc(-n2c3ccccc3c3cc4c5ccccc5n(-c5ccc6c(c5)Oc5cccc7c5B6c5cc(-c6cccc([Si](c8ccccc8)(c8ccccc8)c8ccccc8)c6)ccc5O7)c4cc32)cc1 ; c1ccc(-n2c3ccccc3c3cc4c5ccccc5n(-c5ccc6c(c5)Oc5c(-c7cccc([Si](c8ccccc8)(c8ccccc8)c8ccccc8)c7)ccc7c5B6c5ccccc5O7)c4cc32)cc1]

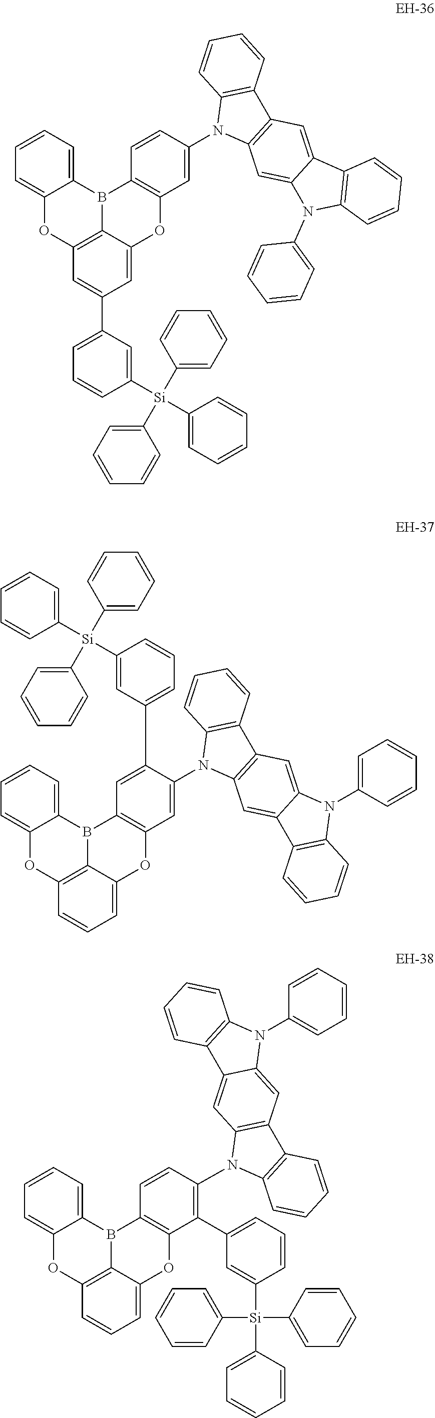 [SMILES: c1ccc(-n2c3ccccc3c3cc4c5ccccc5n(-c5ccc6c(c5)Oc5cc(-c7cccc([Si](c8ccccc8)(c8ccccc8)c8ccccc8)c7)cc7c5B6c5ccccc5O7)c4cc32)cc1 ; c1ccc(-n2c3ccccc3c3cc4c(cc32)c2ccccc2n4-c2cc3c(cc2-c2cccc([Si](c4ccccc4)(c4ccccc4)c4ccccc4)c2)B2c4ccccc4Oc4cccc(c42)O3)cc1 ; c1ccc(-n2c3ccccc3c3cc4c(cc32)c2ccccc2n4-c2ccc3c(c2-c2cccc([Si](c4ccccc4)(c4ccccc4)c4ccccc4)c2)Oc2cccc4c2B3c2ccccc2O4)cc1]

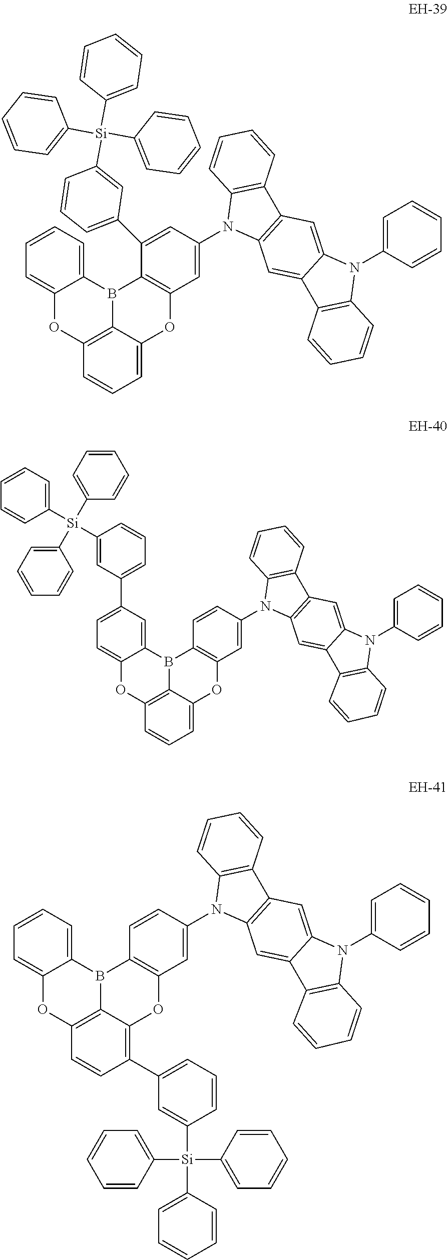 [SMILES: c1ccc(-n2c3ccccc3c3cc4c(cc32)c2ccccc2n4-c2cc3c(c(-c4cccc([Si](c5ccccc5)(c5ccccc5)c5ccccc5)c4)c2)B2c4ccccc4Oc4cccc(c42)O3)cc1 ; c1ccc(-n2c3ccccc3c3cc4c(cc32)c2ccccc2n4-c2ccc3c(c2)Oc2cccc4c2B3c2cc(-c3cccc([Si](c5ccccc5)(c5ccccc5)c5ccccc5)c3)ccc2O4)cc1 ; c1ccc(-n2c3ccccc3c3cc4c(cc32)c2ccccc2n4-c2ccc3c(c2)Oc2c(-c4cccc([Si](c5ccccc5)(c5ccccc5)c5ccccc5)c4)ccc4c2B3c2ccccc2O4)cc1]

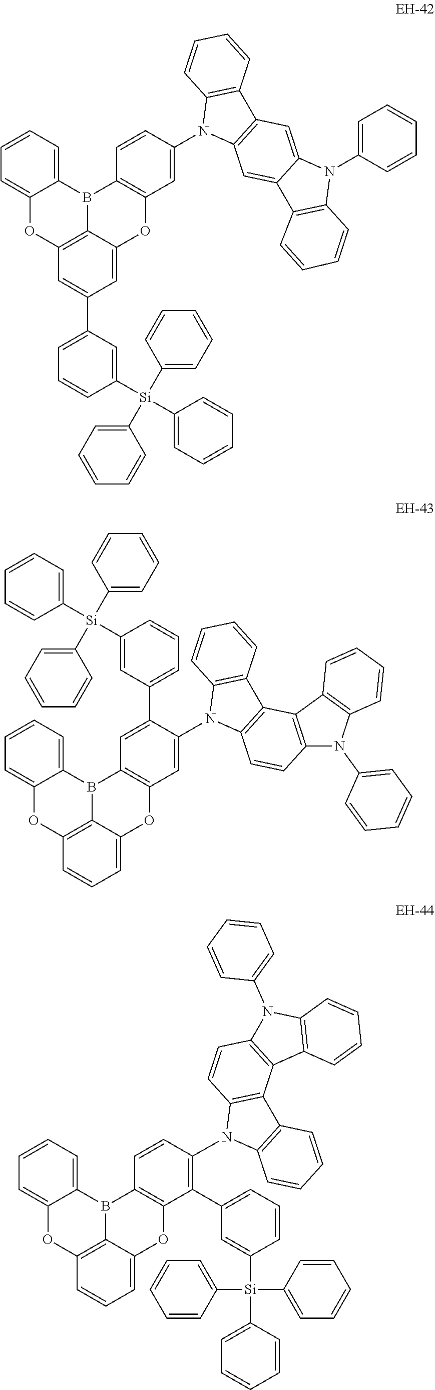 [SMILES: c1ccc(-n2c3ccccc3c3cc4c(cc32)c2ccccc2n4-c2ccc3c(c2)Oc2cc(-c4cccc([Si](c5ccccc5)(c5ccccc5)c5ccccc5)c4)cc4c2B3c2ccccc2O4)cc1 ; c1ccc(-n2c3ccccc3c3c4c5ccccc5n(-c5cc6c(cc5-c5cccc([Si](c7ccccc7)(c7ccccc7)c7ccccc7)c5)B5c7ccccc7Oc7cccc(c75)O6)c4ccc32)cc1 ; c1ccc(-n2c3ccccc3c3c4c5ccccc5n(-c5ccc6c(c5-c5cccc([Si](c7ccccc7)(c7ccccc7)c7ccccc7)c5)Oc5cccc7c5B6c5ccccc5O7)c4ccc32)cc1]

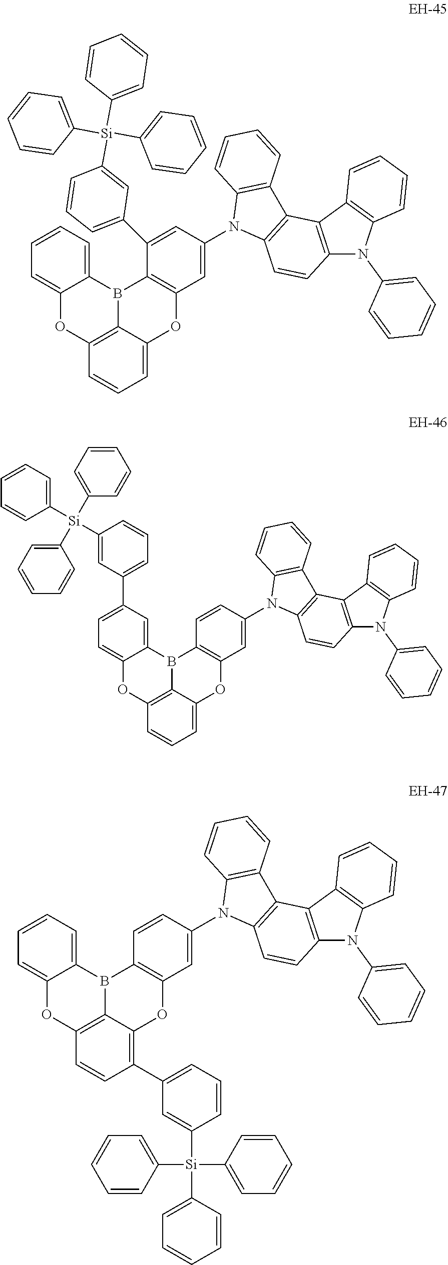 [SMILES: c1ccc(-n2c3ccccc3c3c4c5ccccc5n(-c5cc6c(c(-c7cccc([Si](c8ccccc8)(c8ccccc8)c8ccccc8)c7)c5)B5c7ccccc7Oc7cccc(c75)O6)c4ccc32)cc1 ; c1ccc(-n2c3ccccc3c3c4c5ccccc5n(-c5ccc6c(c5)Oc5cccc7c5B6c5cc(-c6cccc([Si](c8ccccc8)(c8ccccc8)c8ccccc8)c6)ccc5O7)c4ccc32)cc1 ; c1ccc(-n2c3ccccc3c3c4c5ccccc5n(-c5ccc6c(c5)Oc5c(-c7cccc([Si](c8ccccc8)(c8ccccc8)c8ccccc8)c7)ccc7c5B6c5ccccc5O7)c4ccc32)cc1]

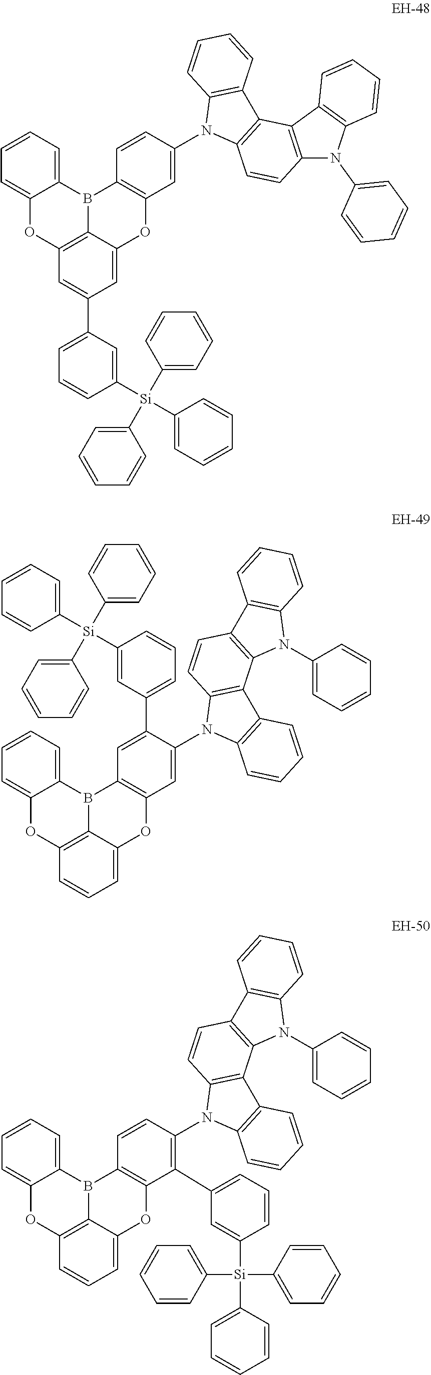 [SMILES: c1ccc(-n2c3ccccc3c3c4c5ccccc5n(-c5ccc6c(c5)Oc5cc(-c7cccc([Si](c8ccccc8)(c8ccccc8)c8ccccc8)c7)cc7c5B6c5ccccc5O7)c4ccc32)cc1 ; c1ccc(-n2c3ccccc3c3ccc4c(c5ccccc5n4-c4cc5c(cc4-c4cccc([Si](c6ccccc6)(c6ccccc6)c6ccccc6)c4)B4c6ccccc6Oc6cccc(c64)O5)c32)cc1 ; c1ccc(-n2c3ccccc3c3ccc4c(c5ccccc5n4-c4ccc5c(c4-c4cccc([Si](c6ccccc6)(c6ccccc6)c6ccccc6)c4)Oc4cccc6c4B5c4ccccc4O6)c32)cc1]

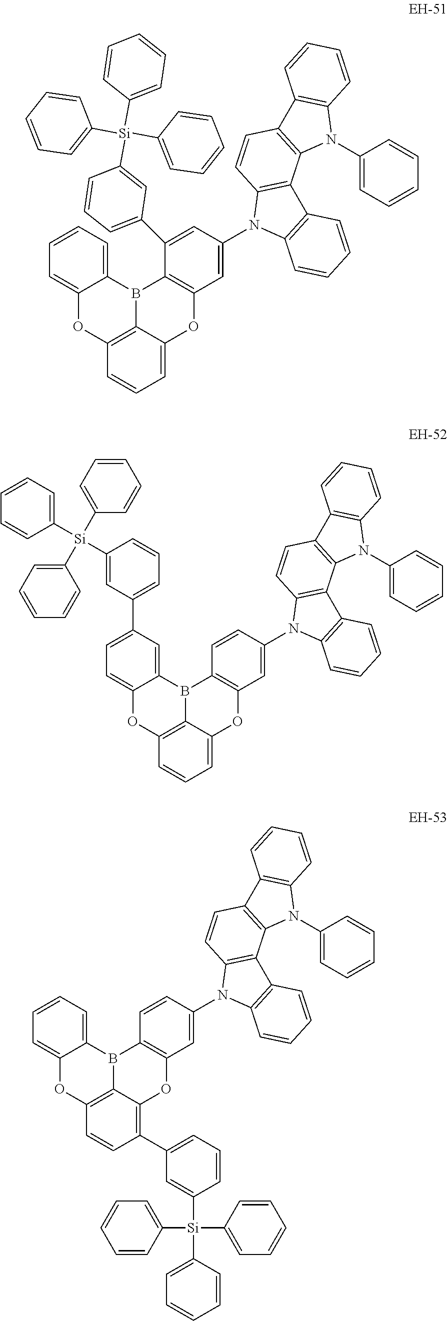 [SMILES: c1ccc(-n2c3ccccc3c3ccc4c(c5ccccc5n4-c4cc5c(c(-c6cccc([Si](c7ccccc7)(c7ccccc7)c7ccccc7)c6)c4)B4c6ccccc6Oc6cccc(c64)O5)c32)cc1 ; c1ccc(-n2c3ccccc3c3ccc4c(c5ccccc5n4-c4ccc5c(c4)Oc4cccc6c4B5c4cc(-c5cccc([Si](c7ccccc7)(c7ccccc7)c7ccccc7)c5)ccc4O6)c32)cc1 ; c1ccc(-n2c3ccccc3c3ccc4c(c5ccccc5n4-c4ccc5c(c4)Oc4c(-c6cccc([Si](c7ccccc7)(c7ccccc7)c7ccccc7)c6)ccc6c4B5c4ccccc4O6)c32)cc1]

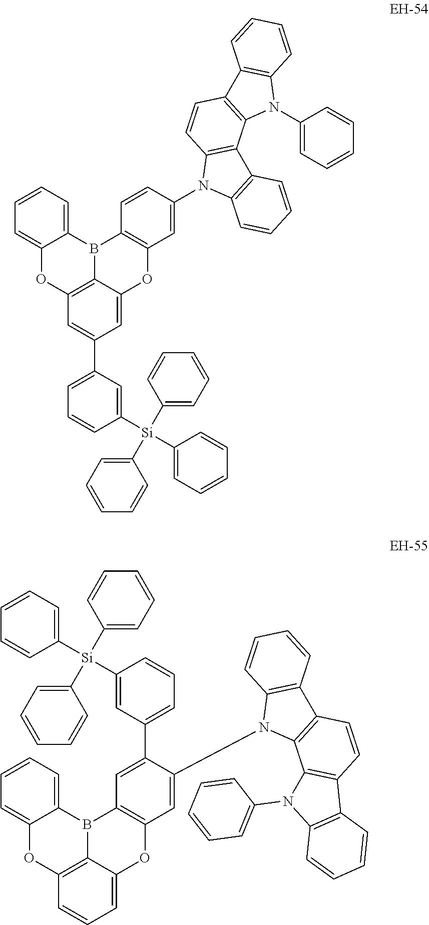 [SMILES: c1ccc(-n2c3ccccc3c3ccc4c(c5ccccc5n4-c4ccc5c(c4)Oc4cc(-c6cccc([Si](c7ccccc7)(c7ccccc7)c7ccccc7)c6)cc6c4B5c4ccccc4O6)c32)cc1 ; c1ccc(-n2c3ccccc3c3ccc4c5ccccc5n(-c5cc6c(cc5-c5cccc([Si](c7ccccc7)(c7ccccc7)c7ccccc7)c5)B5c7ccccc7Oc7cccc(c75)O6)c4c32)cc1]

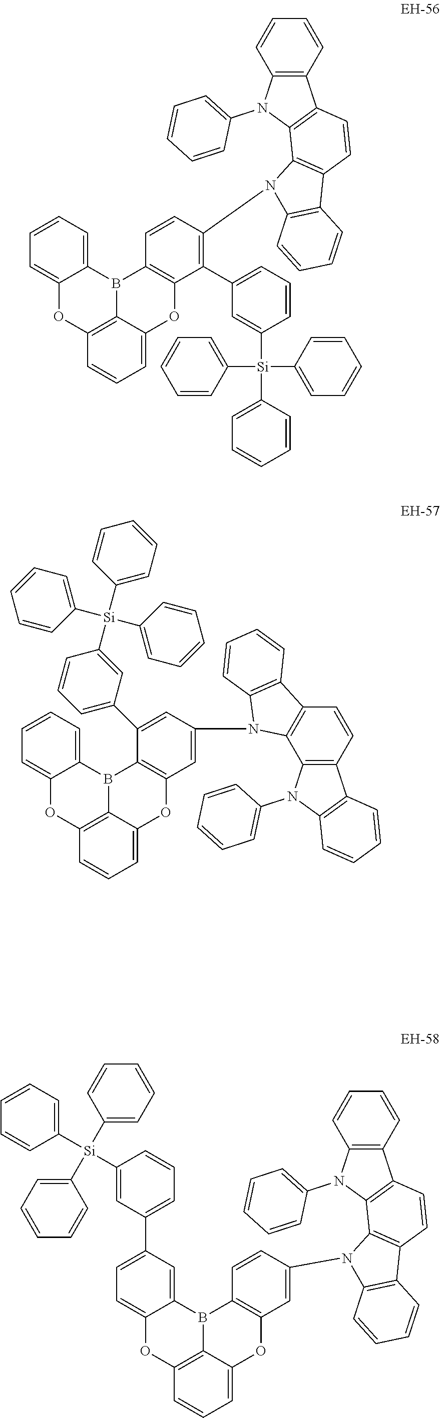 [SMILES: c1ccc(-n2c3ccccc3c3ccc4c5ccccc5n(-c5ccc6c(c5-c5cccc([Si](c7ccccc7)(c7ccccc7)c7ccccc7)c5)Oc5cccc7c5B6c5ccccc5O7)c4c32)cc1 ; c1ccc(-n2c3ccccc3c3ccc4c5ccccc5n(-c5cc6c(c(-c7cccc([Si](c8ccccc8)(c8ccccc8)c8ccccc8)c7)c5)B5c7ccccc7Oc7cccc(c75)O6)c4c32)cc1 ; c1ccc(-n2c3ccccc3c3ccc4c5ccccc5n(-c5ccc6c(c5)Oc5cccc7c5B6c5cc(-c6cccc([Si](c8ccccc8)(c8ccccc8)c8ccccc8)c6)ccc5O7)c4c32)cc1]

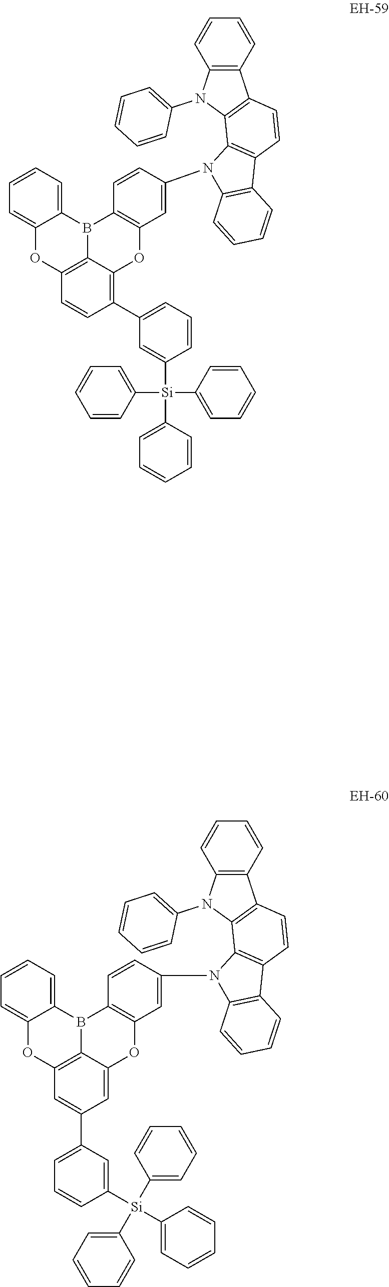 [SMILES: c1ccc(-n2c3ccccc3c3ccc4c5ccccc5n(-c5ccc6c(c5)Oc5c(-c7cccc([Si](c8ccccc8)(c8ccccc8)c8ccccc8)c7)ccc7c5B6c5ccccc5O7)c4c32)cc1 ; c1ccc(-n2c3ccccc3c3ccc4c5ccccc5n(-c5ccc6c(c5)Oc5cc(-c7cccc([Si](c8ccccc8)(c8ccccc8)c8ccccc8)c7)cc7c5B6c5ccccc5O7)c4c32)cc1]

The first compound 242a can have a lowest unoccupied molecular orbital (LUMO) energy level being in a range −2.60 eV to −2.50 eV and a highest occupied molecular orbital (HOMO) energy level being in a range −5.65 eV to −5.55 eV. In the first compound 242a, a difference between a singlet energy level and a triplet energy level can be 0.3 eV or less, e.g., 0.15 eV to 0.25 eV.

The second compound 244a is represented by Formula 3.

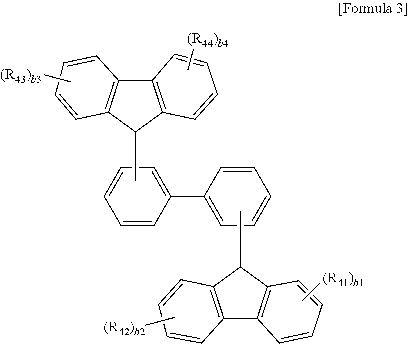

In Formula 3, each of b1, b2, b3 and b4 is independently an integer of 0 to 4,
when b1 is 2 or more, two or more R₄₁ are same or different, when b2 is 2 or more, two or more R₄₂ are same or different, when b3 is 2 or more, two or more R₄₃ are same or different, when b4 is 2 or more, two or more R₄₄ are same or different, and
each of R₄₁ to R₄₄ is independently selected from the group consisting of deuterium, halogen, cyano, a substituted or unsubstituted C1 to C20 alkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group.

In an aspect of the present disclosure, each of R₄₁ to R₄₄ can be independently selected from the group consisting of a substituted or unsubstituted C1 to C20 alkyl group, e.g., methyl, a substituted or unsubstituted C6 to C30 aryl group, e.g., phenyl, and a substituted or unsubstituted C3 to C30 heteroaryl group, e.g., carbazolyl.

In an aspect of the present disclosure, each of b1 to b4 can be independently 0 or 1.

In Formula 3, a position of a carbazole moiety can be specified. For example, Formula 3 can be represented by Formula 3a or Formula 3b.

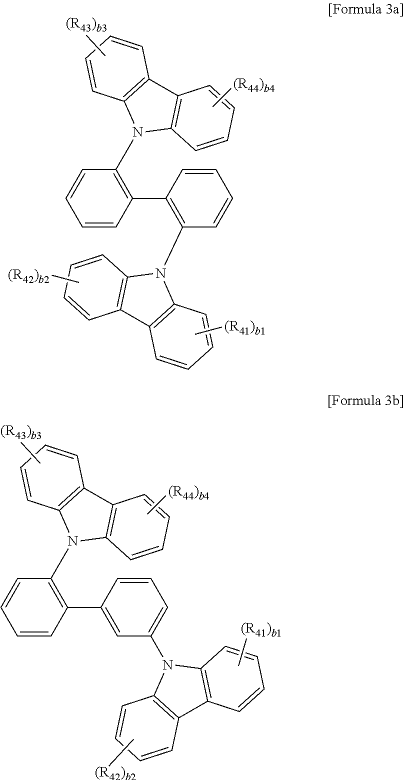

In each of Formulas 3a and 3b, the definitions of R₄₁, R₄₂, R₄₃, R₄₄, b1, b2, b3 and b4 are same as those in Formula 3.

For example, the second compound 244a can be one of the compounds in Formula 4.

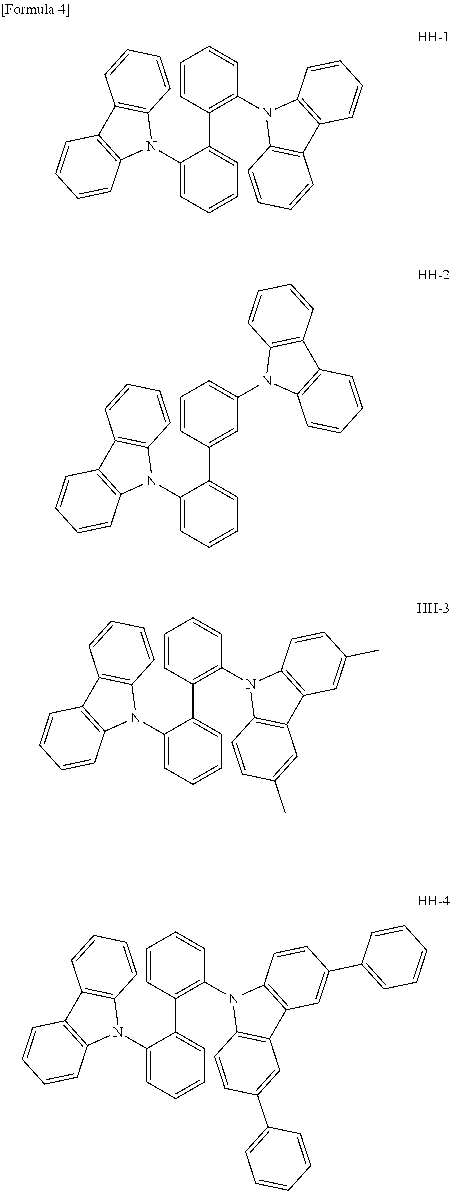 [SMILES: c1ccc(-n2c3ccccc3c3ccccc32)c(-c2ccccc2-n2c3ccccc3c3ccccc32)c1 ; c1cc(-c2ccccc2-n2c3ccccc3c3ccccc32)cc(-n2c3ccccc3c3ccccc32)c1 ; Cc1ccc2c(c1)c1cc(C)ccc1n2-c1ccccc1-c1ccccc1-n1c2ccccc2c2ccccc21 ; c1ccc(-c2ccc3c(c2)c2cc(-c4ccccc4)ccc2n3-c2ccccc2-c2ccccc2-n2c3ccccc3c3ccccc32)cc1]

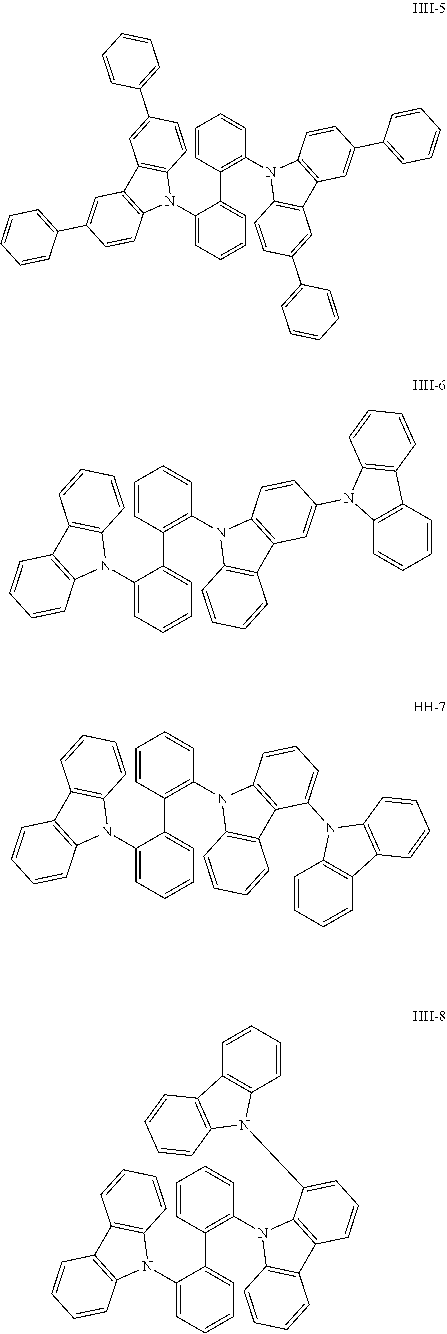 [SMILES: c1ccc(-c2ccc3c(c2)c2cc(-c4ccccc4)ccc2n3-c2ccccc2-c2ccccc2-n2c3ccc(-c4ccccc4)cc3c3cc(-c4ccccc4)ccc32)cc1 ; c1ccc(-n2c3ccccc3c3ccccc32)c(-c2ccccc2-n2c3ccccc3c3cc(-n4c5ccccc5c5ccccc54)ccc32)c1 ; c1ccc(-n2c3ccccc3c3ccccc32)c(-c2ccccc2-n2c3ccccc3c3c(-n4c5ccccc5c5ccccc54)cccc32)c1 ; c1ccc(-n2c3ccccc3c3ccccc32)c(-c2ccccc2-n2c3ccccc3c3cccc(-n4c5ccccc5c5ccccc54)c32)c1]

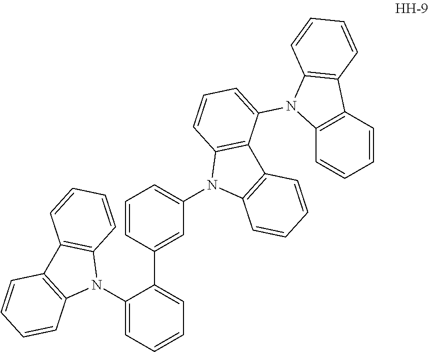 [SMILES: c1cc(-c2ccccc2-n2c3ccccc3c3ccccc32)cc(-n2c3ccccc3c3c(-n4c5ccccc5c5ccccc54)cccc32)c1]

The second compound 244a can have a LUMO energy level being in a range −2.45 eV to −2.40 eV and a HOMO energy level being in a range −5.90 eV to −5.75 eV.

The third compound 246a is represented by Formula 5.

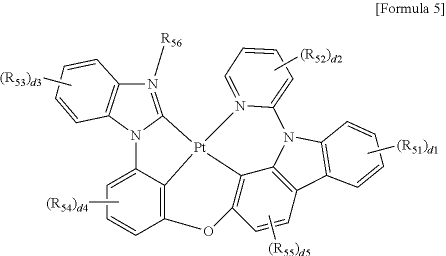

In Formula 5,
each of d1, d2 and d3 is independently an integer of 0 to 4, d4 is an integer of 0 to 3, d5 is an integer of 0 to 2,
when d1 is 2 or more, two or more R₅₁ are same or different, when d2 is 2 or more, two or more R₅₂ are same or different, when d3 is 2 or more, two or more R₅₃ are same or different, when d4 is 2 or more, two or more R₅₄ are same or different, when d5 is 2, two R₅₅ are same or different,
each of R₅₁ to R₅₅ is independently selected from the group consisting of deuterium, halogen, cyano, a substituted or unsubstituted C1 to C20 alkyl group, a substituted or unsubstituted C3 to C30 cycloalkyl group, a substituted or unsubstituted C1 to C20 alkylsilyl group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, and
R₅₆ is selected from the group consisting of hydrogen, deuterium, halogen, cyano, a substituted or unsubstituted C1 to C20 alkyl group, a substituted or unsubstituted C3 to C30 cycloalkyl group, a substituted or unsubstituted C1 to C20 alkylsilyl group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group.

In an aspect of the present disclosure, each of R₅₁ to R₅₆ can be independently selected from the group consisting of a substituted or unsubstituted C1 to C20 alkyl group, e.g., methyl or tert-butyl, a substituted or unsubstituted C3 to C20 cycloalkyl, e.g., an adamantanyl unsubstituted or substituted with a phenyl, and a substituted or unsubstituted C6 to C30 aryl group, e.g., phenyl unsubstituted or substituted with C1 to C20 alkyl group. In an aspect of the present disclosure, at least one of d1 to d5 can be a positive integer.

For example, the third compound 246a can be one of the compounds in Formula 6.

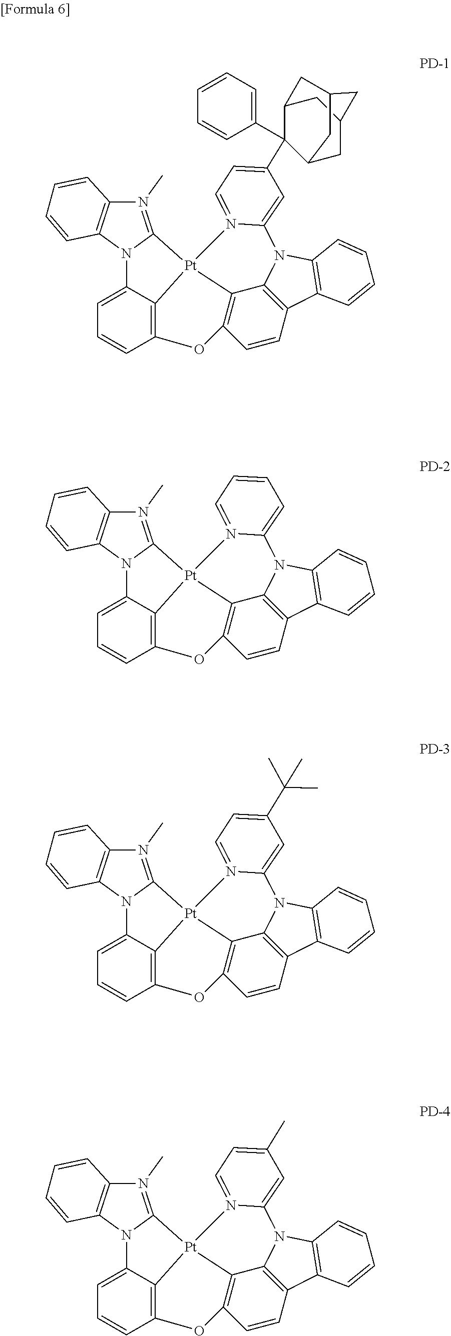

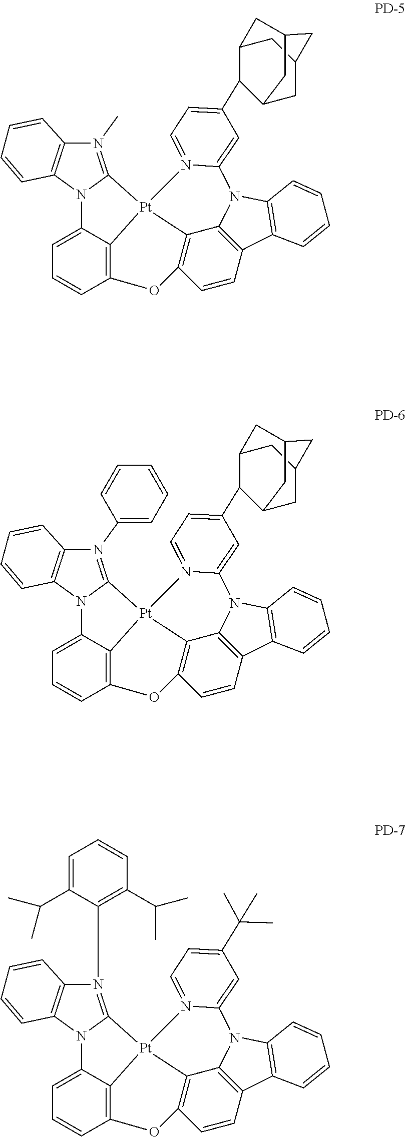

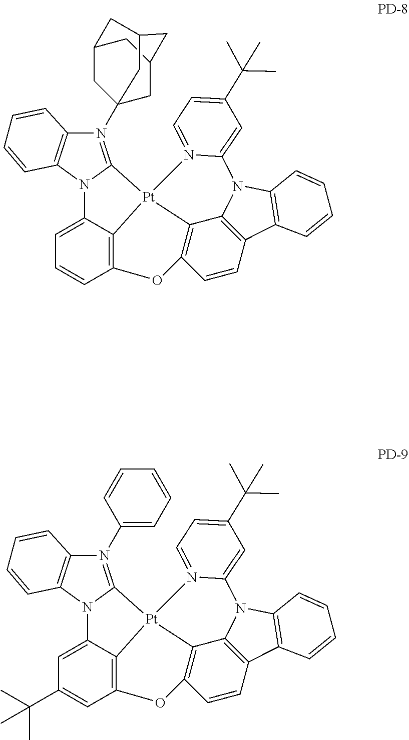

The third compound 246a can have a LUMO energy level being in a range of −2.65 eV to −2.55 eV and a HOMO energy level being in a range of −5.55 eV to −5.45 eV.

A maximum emission wavelength of a mixture of the first and second compounds 242a and 244a can be shorter than a maximum emission wavelength of the first compound 242a and longer than a maximum emission wavelength of the second compound 244a.

In the first compound 242a represented by Formula 1, a difference (e.g., a gap) between a singlet energy level and a triplet energy level can be 0.3 eV or less. As a result, the first compound 242a can have a delayed fluorescent property so that a non-emissive triplet exciton can be converted into a singlet exciton. Accordingly, the emitting efficiency of the OLED D1 and the organic light emitting display device 100 including the OLED D1 can be improved.

In addition, since the EML 240A includes the first compound 242a as an n-type host and the second compound 244a as a p-type host, the exciton generation efficiency in the EML 240A and an exciton transfer efficiency into the third compound 246a can be improved. Accordingly, the emitting efficiency of the OLED D1 including the first, second and third compounds 242a, 244a and 246a and the organic light emitting display device 100 including the OLED D1 can be improved.

Moreover, since the first compound 242a represented by formula 1 includes a tetraarylsilane structure represented by Formula 1-1, a boron atom can be protected. Accordingly, the lifespan of the OLED D1 including the first compound 242a and the organic light emitting display device 100 including the OLED D1 can be improved.

Further, since a complex formation between the first compound 242a represented by formula 1 and the third compound 246a represented by formula 5 can be prevented by a tetraarylsilane structure, a concentration of the third compound 246a in the EML 240A can be increased. Accordingly, the emitting efficiency of the OLED D1 including the first and third compounds 242a and 246a and the organic light emitting display device 100 including the OLED D1 can be further improved.

Referring to FIG. 4, which is a schematic energy band diagram in an EML of an OLED according to the second embodiment of the present disclosure, a LUMO energy level of the first compound 242a is lower than that of the second compound 244a and higher than that of the third compound 246a. A difference “ΔLUMO_1” between a LUMO energy level of the first compound 242a and a LUMO energy level of the third compound 246a can be smaller than a difference “ΔLUMO_2” between a LUMO energy level of the first compound 242a and a LUMO energy level of the second compound 244a.

For example, difference “ΔLUMO_1” between a LUMO energy level of the first compound 242a and a LUMO energy level of the third compound 246a can be in a range of 0.03 eV to 0.08 eV, and a difference “ΔLUMO_2” between a LUMO energy level of the first compound 242a and a LUMO energy level of the second compound 244a can be in a range of 0.10 eV to 0.15 eV.

A HOMO energy level of the first compound 242a is higher than that of the second compound 244a and lower than that of the third compound 246a. A difference between a HOMO energy level of the first compound 242a and a HOMO energy level of the third compound 246a can be smaller than a difference between a HOMO energy level of the first compound 242a and a HOMO energy level of the second compound 244a. For example, a difference between a HOMO energy level of the first compound 242a and a HOMO energy level of the third compound 246a can be in a range of 0.1 eV to 0.3 eV

Since the first compound 242a represented by Formula 1 has a LUMO energy level higher than that of the third compound 246a, an electron trap in the first compound 242a can be suppressed. Accordingly, the driving voltage of the OLED D1 and the organic light emitting display device 100 including the OLED D1 can be reduced.

In the EML 240A, a weight % of each of the first and second compounds 242a and 244a can be greater than that of the third compound 246a. A weight % of the first compound 242a and a weight % of the second compound 244a can be same or different.

The first compound 242a can have a weight % of 25 to 50, the second compound 244a can have a weight % of 25 to 50, and the third compound 246a can have a weight % of 5 to 25. In an aspect of the present disclosure, a weight % of the first compound 242a and a weight % of the second compound 244a can be same, and the third compound 246a can have a weight % of 8, 12, 16 or 20.

In the red pixel region, the OLED includes a red EML. The red EML can include a red host and a red dopant. In the green pixel region, the OLED includes a green EML. The green EML can include a green host and a green dopant. The red dopant can be one of a fluorescent compound, a phosphorescent compound and a delayed fluorescent compound, and the green dopant can be one of a fluorescent compound, a phosphorescent compound and a delayed fluorescent compound.

As described above, in the blue pixel region, the EML 240A of the OLED D1 includes the first compound 242a represented by Formula 1, the second compound 244a represented by Formula 3 and the third compound 246a represented by Formula 5.

The first compound 242a represented by Formula 1 can have a delayed fluorescent property so that the emitting efficiency of the OLED D1 and the organic light emitting display device 100 including the OLED D1 can be improved.

In addition, since the first compound 242a represented by formula 1 includes a tetraarylsilane structure represented by Formula 1-1, a boron atom can be protected. Accordingly, the lifespan of the OLED D1 and the organic light emitting display device 100 including the OLED D1 can be improved.

Moreover, since a complex formation between the first compound 242a represented by formula 1 and the third compound 246a represented by formula 5 can be prevented by a tetraarylsilane structure, a concentration of the third compound 246a in the EML 240A can be increased. Accordingly, the emitting efficiency of the OLED D1 and the organic light emitting display device 100 including the OLED D1 can be further improved.

Furthermore, since the first compound 242a represented by Formula 1 has a LUMO energy level higher than that of the third compound 246a, an electron trap in the first compound 242a can be suppressed. Accordingly, the driving voltage of the OLED D1 and the organic light emitting display device 100 including the OLED D1 can be reduced.

Namely, the OLED D1 according to the present disclosure and the organic light emitting display device 100 including the OLED D1 have an advantage in at least one of the driving voltage, the emitting efficiency and the lifespan.

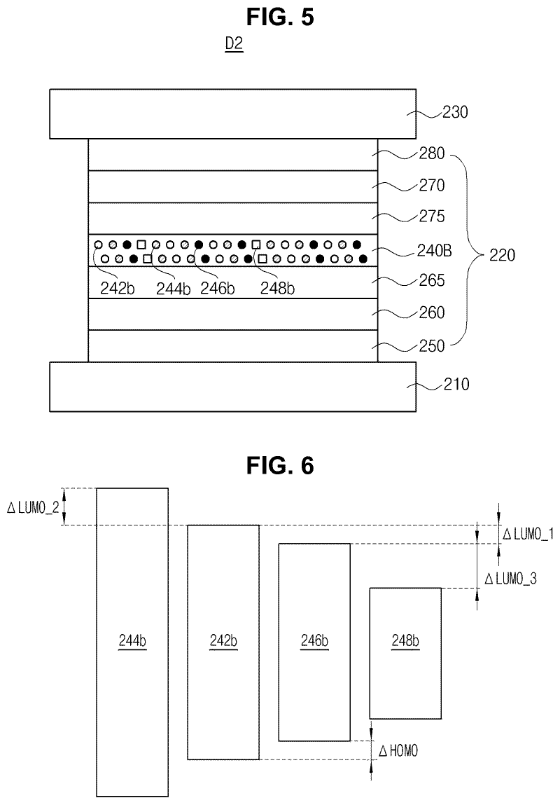

FIG. 5 is a schematic cross-sectional view of an OLED according to a third embodiment of the present disclosure.

As shown in FIG. 5, the OLED D2 includes first and second electrodes 210 and 230, which face each other, and an organic light emitting layer 220 therebetween. The organic light emitting layer 220 includes an emitting material layer (EML) 240B, e.g., a blue EML. The OLED D2 can further include a capping layer on the second electrode 230 to enhance a light extraction efficiency.

The organic light emitting display device 100 (of FIG. 2) can include a red pixel region, a green pixel region and a blue pixel region, and the OLED D2 can be positioned in the blue pixel region.

The first electrode 210 can be an anode, and the second electrode 230 can be a cathode. One of the first and second electrodes 210 and 230 can be a reflective electrode, and the other one of the first and second electrodes 210 and 230 can be a transparent (or a semi-transparent) electrode. In the bottom-emission type OLED D2, the first electrode 210 can have a single-layered structure of ITO, and the second electrode 230 can be formed of Al. The first electrode 210 can have a thickness of 10 nm to 100 nm, e.g., 40 nm to 60 nm, and the second electrode 230 can have a thickness of 100 nm to 300 nm, e.g., 150 nm to 250 nm.

The organic light emitting layer 220 can further include at least one of a hole transporting layer (HTL) 260 between the first electrode 210 and the EML 240B and an electron transporting layer (ETL) 270 between the second electrode 230 and the EML 240B.

In addition, the organic light emitting layer 220 can further include at least one of a hole injection layer (HIL) 250 between the first electrode 210 and the HTL 260 and an electron injection layer (EIL) 280 between the second electrode 230 and the ETL 270.

Moreover, the organic light emitting layer 220 can further include at least one of an electron blocking layer (EBL) 265 between the HTL 260 and the EML 240B and a hole blocking layer (HBL) 275 between the EML 240B and the ETL 270.

The HIL 250 can include the above hole injection material and can have a thickness of 1 nm to 20 nm, e.g., 5 nm to 15 nm.

The HTL 260 can include the above hole transporting material and can have a thickness of 30 nm to 60 nm, e.g., 40 nm to 50 nm.

The ETL 270 can include the above electron transporting material and can have a thickness of 10 nm to 50 nm, e.g., 20 nm to 40 nm.

The EIL 280 can include the above electron injection material and can have a thickness of 0.lnm to 10 nm, e.g., lnm to 5 nm.

The EBL 265 can include the above electron blocking material and can have a thickness of 5 nm to 20 nm, e.g., 5 nm to 15 nm.

The HBL 275 can include the above hole blocking material and can have a thickness of 5 nm to 20 nm, e.g., 5 nm to 15 nm.

The EML 240B can have a thickness of 10 nm to 100 nm, e.g., 10 nm to 50 nm, preferably 20 nm to 40 nm. The EML 240B can include a first compound 242b, a second compound 244b, a third compound 246b and a fluorescent compound 248b. The first compound 242b can be an n-type host, the second compound 244b can be a p-type host, the third compound 246b can be an auxiliary host or an auxiliary dopant, and the fluorescent compound 248b can be a dopant (e.g., an emitter).

The first compound 242b is represented by Formula 1 and can be one of the compounds in Formula 2. The second compound 244b is represented by Formula 3 and can be one of the compounds in Formula 4. The third compound 246b is represented by Formula 5 and can be one of the compounds in Formula 6.

The fluorescent compound 248b is represented by Formula 7.

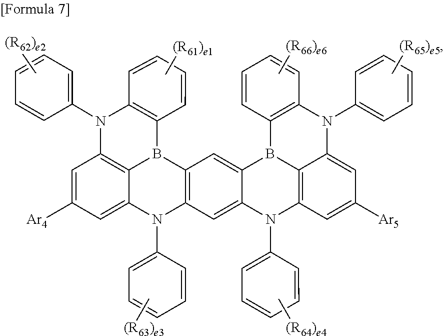

In Formula 7,
each of e1 and e6 is independently an integer of 0 to 4, each of e2 to e5 is independently an integer of 0 to 5,
when e1 is 2 or more, two or more R₆₁ are same or different, when e2 is 2 or more, two or more R₆₂ are same or different, when e3 is 2 or more, two or more R₆₃ are same or different, when e4 is 2 or more, two or more R₆₄ are same or different, when e5 is 2 or more, two or more R₆₅ are same or different, when e6 is 2 or more, two or more R₆₆ are same or different,
each of R₆₁ to R₆₆ is independently selected from the group consisting of deuterium, a substituted or unsubstituted C1 to C20 alkyl group, a substituted or unsubstituted C1 to C20 alkoxy group, a substituted or unsubstituted C6 to C30 arylsilyl group, a substituted or unsubstituted C6 to C30 arylamino group, a substituted or unsubstituted C6 to C30 aryl group and a substituted or unsubstituted C3 to C30 heteroaryl group, and
each of Ar₄ and Ar₅ is independently selected from the group consisting of a substituted or unsubstituted C6 to C30 arylamino group, a substituted or unsubstituted C6 to C30 aryl group and a substituted or unsubstituted C3 to C30 heteroaryl group.

In an aspect of the present disclosure, each of Ar₄ and Ar₅ can be independently selected from the group consisting of a substituted or unsubstituted C6 to C30 arylamino group, e.g., diphenylamino, and a substituted or unsubstituted C3 to C30 heteroaryl group, e.g., carbazolyl.

In an aspect of the present disclosure, each of Ar₄ and Ar₅ can be independently selected from a substituted or unsubstituted C6 to C30 arylamino group, e.g., diphenylamino.

In an aspect of the present disclosure, each of Ar₄ and Ar₅ can be independently selected from a substituted or unsubstituted C3 to C30 heteroaryl group, e.g., carbazolyl.

For example, the fluorescent compound 248b can be one of the compounds in Formula 8.

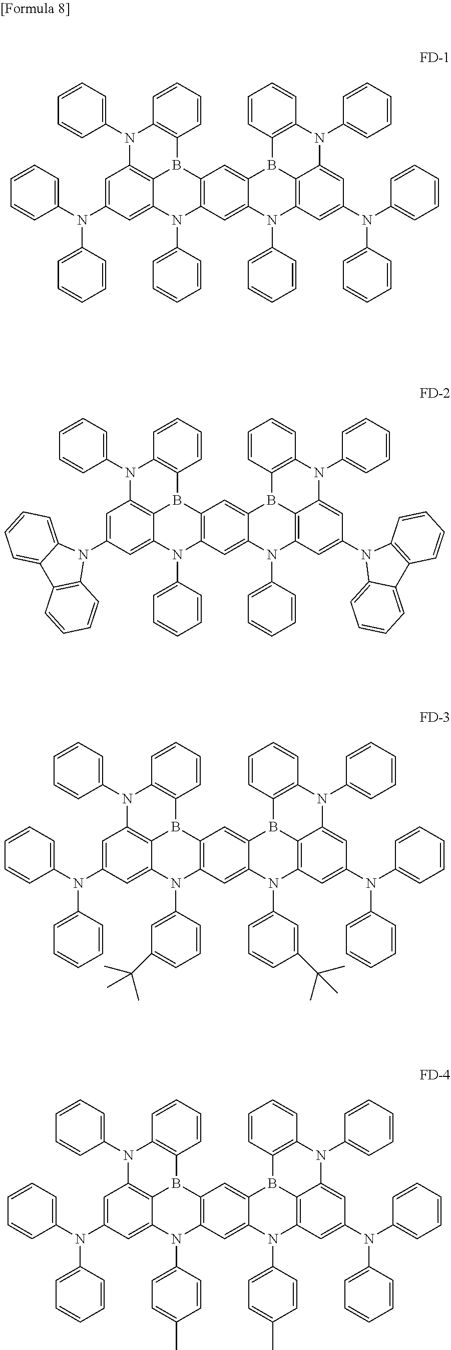

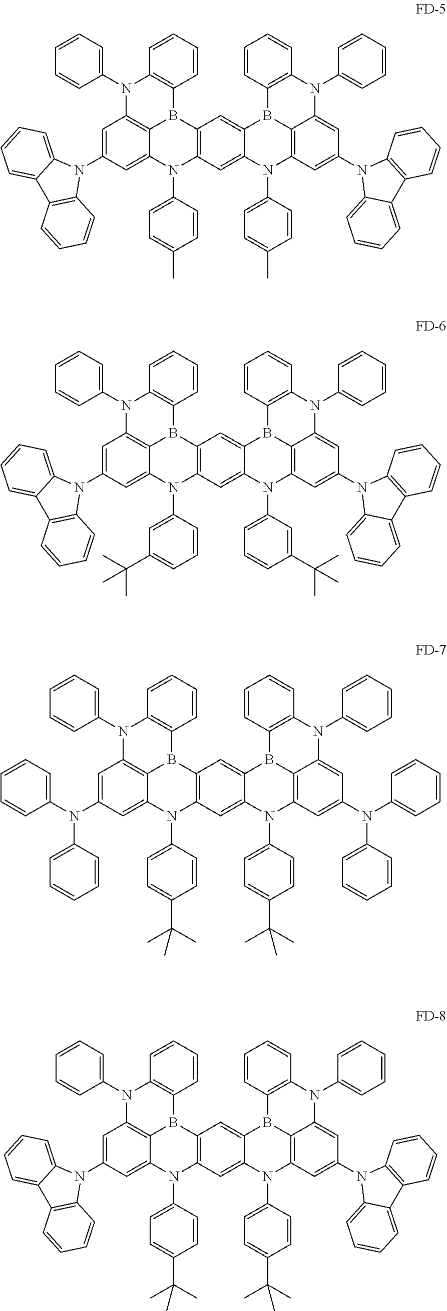

The fluorescent compound 248b can have a LUMO energy level being in a range −2.85 eV to −2.75 eV and a HOMO energy level being in a range −5.50 eV to −5.40 eV. In the fluorescent compound 248b, a difference between a singlet energy level and a triplet energy level can be 0.3 eV or less, e.g., 0.01 eV to 0.025 eV. A difference between a singlet energy level and a triplet energy level of the fluorescent compound 248b can be smaller than a difference between a singlet energy level and a triplet energy level of the first compound 242b.

A maximum emission wavelength of a mixture of the first and second compounds 242b and 244b can be shorter than a maximum emission wavelength of the first compound 242b and longer than a maximum emission wavelength of the second compound 244b.

In each of the first compound 242b represented by Formula 1 and the fluorescent compound 248b represented by Formula 7, a difference between the singlet energy level and the triplet energy level can be 0.3 eV or less. As a result, each of the first and fluorescent compounds 242b and 248b has a delayed fluorescent property so that a non-emissive triplet exciton can be converted into a singlet exciton. Accordingly, the emitting efficiency of the OLED D2 and the organic light emitting display device 100 including the OLED D2 can be improved.

In addition, since the EML 240B includes the first compound 242b as an n-type host and the second compound 244b as a p-type host, the exciton generation efficiency in the EML 240B and an exciton transfer efficiency into the third compound 246b and/or the fluorescent compound 248b can be improved. Accordingly, the emitting efficiency of the OLED D2 including the first, second, third and fluorescent compounds 242b, 244b, 246b and 248b and the organic light emitting display device 100 including the OLED D2 can be improved.

Moreover, since the first compound 242b represented by formula 1 includes a tetraarylsilane structure represented by Formula 1-1, a boron atom can be protected. Accordingly, the lifespan of the OLED D2 including the first compound 242b and the organic light emitting display device 100 including the OLED D2 can be improved.

Further, since a complex formation between the first compound 242b represented by formula 1 and the third compound 246b represented by formula 5 can be prevented by a tetraarylsilane structure, a concentration of the third compound 246b in the EML 240B can be increased. Accordingly, the emitting efficiency of the OLED D2 including the first and third compounds 242b and 246b and the organic light emitting display device 100 including the OLED D2 can be further improved.

Referring to FIG. 6, which is a schematic energy band diagram in an EML of an OLED according to the third embodiment of the present disclosure, a LUMO energy level of the first compound 242b is lower than that of the second compound 244b and higher than that of the third compound 246b. In addition, a LUMO energy level of the third compound 246b is higher than that of the fluorescent compound 248b.

A difference “ΔLUMO_1” between a LUMO energy level of the first compound 242b and a LUMO energy level of the third compound 246b can be smaller than a difference “ΔLUMO_2” between a LUMO energy level of the first compound 242b and a LUMO energy level of the second compound 244b. In addition, a difference “ΔLUMO_3” between a LUMO energy level of the third compound 246b and a LUMO energy level of the fluorescent compound 248b can be equal to or greater than a difference “ΔLUMO_2” between a LUMO energy level of the first compound 242b and a LUMO energy level of the second compound 244b.

For example, difference “ΔLUMO_1” between a LUMO energy level of the first compound 242b and a LUMO energy level of the third compound 246b can be in a range of 0.03 eV to 0.08 eV, a difference “ΔLUMO_2” between a LUMO energy level of the first compound 242b and a LUMO energy level of the second compound 244b can be in a range of 0.10 eV to 0.15 eV, and a difference “ΔLUMO_3” between a LUMO energy level of the third compound 246b and a LUMO energy level of the fluorescent compound 248b can be in a range of 0.13 eV to 0.25 eV.

A HOMO energy level of the first compound 242b is higher than that of the second compound 244b and lower than that of the third compound 246b. In addition, a HOMO energy level of the third compound 246b can be lower than that of the fluorescent compound 248b.

A difference between a HOMO energy level of the first compound 242b and a HOMO energy level of the third compound 246b can be smaller than a difference between a HOMO energy level of the first compound 242b and a HOMO energy level of the second compound 244b. For example, a difference “AHOMO” between a HOMO energy level of the first compound 242b and a HOMO energy level of the third compound 246b can be in a range of 0.1 eV to 0.3 eV.

Since the first compound 242b represented by Formula 1 has a LUMO energy level higher than that of each of the third and fluorescent compounds 246b and 248b, an electron trap in the first compound 242b can be suppressed. Accordingly, the driving voltage of the OLED D2 and the organic light emitting display device 100 including the OLED D2 can be reduced.

In the EML 240B, a weight % of each of the first and second compounds 242b and 244b can be greater than that of each of the third and fluorescent compounds 246b and 248b. In addition, a weight % of the third compound 246b can be greater than that of the fluorescent compound 248b. A weight % of the first compound 242b and a weight % of the second compound 244b can be same or different.

The first compound 242b can have a weight % of 25 to 50, and the second compound 244b can have a weight % of 25 to 50. The third compound 246b can have a weight % of 5 to 25, and the fluorescent compound 248b can have a weight % of 0.1 to 3. In an aspect of the present disclosure, a weight % of the first compound 242b and a weight % of the second compound 244b can be same, the third compound 246b can have a weight % of 8, 12, 16 or 20, and the fluorescent compound 248b can have a weight % of 1.

In the red pixel region, the OLED includes a red EML. The red EML can include a red host and a red dopant. In the green pixel region, the OLED includes a green EML. The green EML can include a green host and a green dopant. The red dopant can be one of a fluorescent compound, a phosphorescent compound and a delayed fluorescent compound, and the green dopant can be one of a fluorescent compound, a phosphorescent compound and a delayed fluorescent compound.

As described above, in the blue pixel region, the EML 240B of the OLED D2 includes the first compound 242b represented by Formula 1, the second compound 244b represented by Formula 3, the third compound 246b represented by Formula 5, and the fluorescent compound 248b represented by Formula 7.

Each of the first compound 242b represented by Formula 1 and the fluorescent compound 248b represented by Formula 7 can have a delayed fluorescent property so that the emitting efficiency of the OLED D2 and the organic light emitting display device 100 including the OLED D2 can be improved.

In addition, since the first compound 242b represented by formula 1 includes a tetraarylsilane structure represented by Formula 1-1, a boron atom can be protected. Accordingly, the lifespan of the OLED D2 and the organic light emitting display device 100 including the OLED D2 can be improved.

Moreover, since a complex formation between the first compound 242b represented by formula 1 and the third compound 246b represented by formula 5 can be prevented by a tetraarylsilane structure, a concentration of the third compound 246b in the EML 240B can be increased. Accordingly, the emitting efficiency of the OLED D2 and the organic light emitting display device 100 including the OLED D2 can be further improved.

Furthermore, since the first compound 242b represented by Formula 1 has a LUMO energy level higher than that of each of the third and fluorescent compounds 246b and 248b, an electron trap in the first compound 242b can be suppressed. Accordingly, the driving voltage of the OLED D2 and the organic light emitting display device 100 including the OLED D2 can be reduced.

Namely, the OLED D2 according to the present disclosure and the organic light emitting display device 100 including the OLED D2 have an advantage in at least one of the driving voltage, the emitting efficiency and the lifespan.

The EML 240A in FIG. 3 includes the first, second and third compounds 242a, 244a and 246a, and the EML 240B in FIG. 5 includes the first, second, third and fluorescent compounds 242b, 244b, 246b and 248b. Alternatively, the EML 240B can include the first, second and fluorescent compounds 242b, 244b and 248b without the third compound 246b represented by Formula 5.

### [OLED]

An anode (ITO, 50 nm), an HIL (Formula 9, 7 nm), an HTL (Formula 10, 45 nm), an EBL (Formula 11, 10 nm), an EML (30 nm), an HBL (Formula 12, 10 nm), an ETL (Formula 13, 30 nm), an EIL (LiF, 1 nm) and a cathode (Al, 100 nm) are sequentially deposited to form a blue OLED.

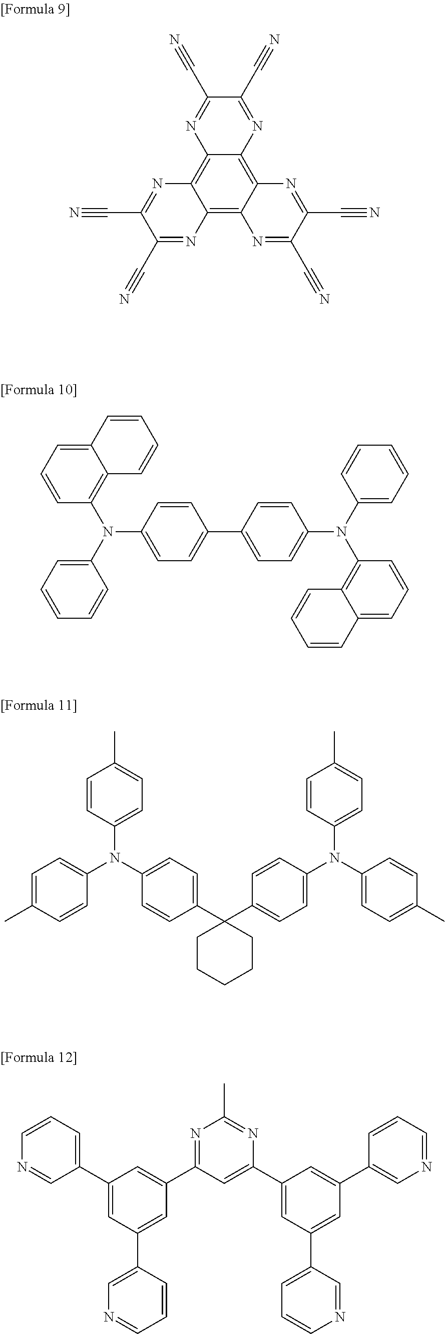

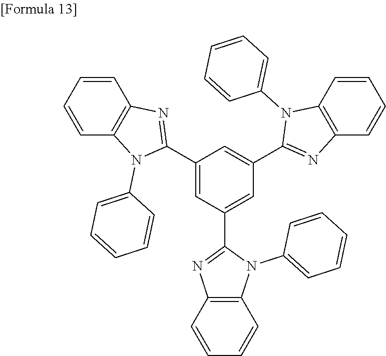 [SMILES: c1ccc(-n2c(-c3cc(-c4nc5ccccc5n4-c4ccccc4)cc(-c4nc5ccccc5n4-c4ccccc4)c3)nc3ccccc32)cc1]

### 1. COMPARATIVE EXAMPLES

### (1) Comparative Example 1 (Ref1)

The compound HH-1 (44 wt %) in Formula 4, the compound EH-B1 (44 wt %) in Formula 14 and the compound PD-1 (12 wt %) in Formula 6 were used to form the EML.

### (2) Comparative Example 2 (Ref2)

The compound HH-1 (42 wt %) in Formula 4, the compound EH-B1 (42 wt %) in Formula 14 and the compound PD-1 (16 wt %) in Formula 6 were used to form the EML.

### (3) Comparative Example 3 (Ref3)

The compound HH-1 (44 wt %) in Formula 4, the compound EH-B2 (44 wt %) in Formula 14 and the compound PD-1 (12 wt %) in Formula 6 were used to form the EML.

### (4) Comparative Example 4 (Ref4)

The compound HH-1 (42 wt %) in Formula 4, the compound EH-B2 (42 wt %) in Formula 14 and the compound PD-1 (16 wt %) in Formula 6 were used to form the EML.

### (5) Comparative Example 5 (Ref5)

The compound HH-1 (44 wt %) in Formula 4, the compound EH-B3 (44 wt %) in Formula 14 and the compound PD-1 (12 wt %) in Formula 6 were used to form the EML.

### (6) Comparative Example 6 (Ref6)

The compound HH-1 (44 wt %) in Formula 4, the compound EH-B4 (44 wt %) in Formula 14 and the compound PD-1 (12 wt %) in Formula 6 were used to form the EML.

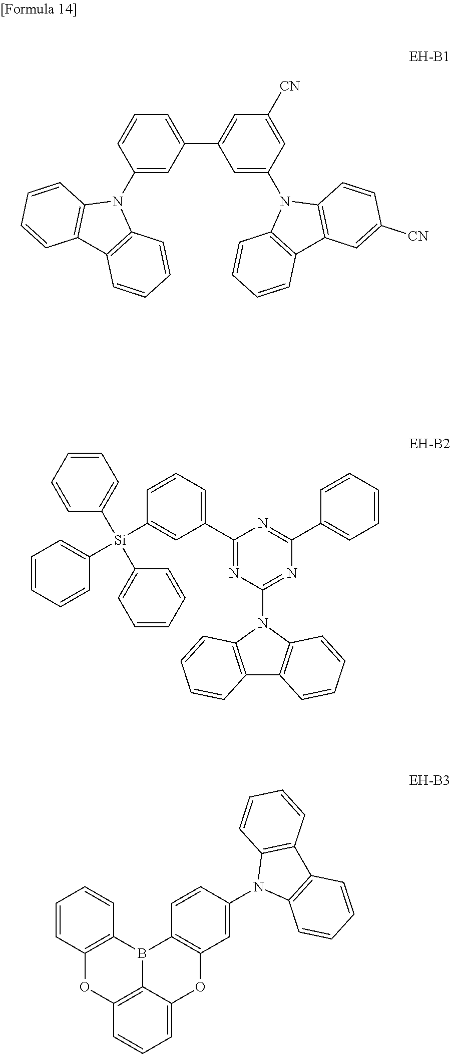 [SMILES: N#Cc1cc(-c2cccc(-n3c4ccccc4c4ccccc43)c2)cc(-n2c3ccccc3c3cc(C#N)ccc32)c1 ; c1ccc(-c2nc(-c3cccc([Si](c4ccccc4)(c4ccccc4)c4ccccc4)c3)nc(-n3c4ccccc4c4ccccc43)n2)cc1 ; c1ccc2c(c1)Oc1cccc3c1B2c1ccc(-n2c4ccccc4c4ccccc42)cc1O3]

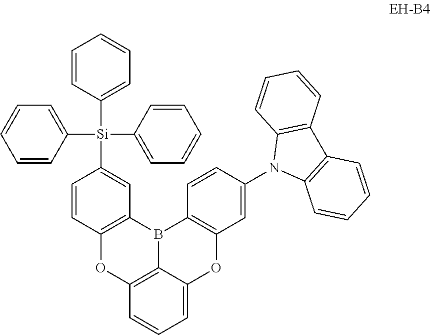 [SMILES: c1ccc([Si](c2ccccc2)(c2ccccc2)c2ccc3c(c2)B2c4ccc(-n5c6ccccc6c6ccccc65)cc4Oc4cccc(c42)O3)cc1]

### 2. EXAMPLES

### (1) Example 1 (Ex1)

The compound HH-1 (46 wt %) in Formula 4, the compound EH-1 (46 wt %) in Formula 2 and the compound PD-1 (8 wt %) in Formula 6 were used to form the EML.

### (2) Example 2 (Ex2)

The compound HH-1 (44 wt %) in Formula 4, the compound EH-1 (44 wt %) in Formula 2 and the compound PD-1 (12 wt %) in Formula 6 were used to form the EML.

### (3) Example 3 (Ex3)

The compound HH-1 (42 wt %) in Formula 4, the compound EH-1 (42 wt %) in Formula 2 and the compound PD-1 (16 wt %) in Formula 6 were used to form the EML.

### (4) Example 4 (Ex4)

The compound HH-1 (40 wt %) in Formula 4, the compound EH-1 (40 wt %) in Formula 2 and the compound PD-1 (20 wt %) in Formula 6 were used to form the EML.

### (5) Example 5 (Ex5)

The compound HH-1 (46 wt %) in Formula 4, the compound EH-2 (46 wt %) in Formula 2 and the compound PD-1 (8 wt %) in Formula 6 were used to form the EML.

### (6) Example 6 (Ex6)

The compound HH-1 (44 wt %) in Formula 4, the compound EH-2 (44 wt %) in Formula 2 and the compound PD-1 (12 wt %) in Formula 6 were used to form the EML.

### (7) Example 7 (Ex7)

The compound HH-1 (42 wt %) in Formula 4, the compound EH-2 (42 wt %) in Formula 2 and the compound PD-1 (16 wt %) in Formula 6 were used to form the EML.

### (8) Example 8 (Ex8)

The compound HH-1 (40 wt %) in Formula 4, the compound EH-2 (40 wt %) in Formula 2 and the compound PD-1 (20 wt %) in Formula 6 were used to form the EML.

A LUMO energy level, a HOMO energy level and a difference (ΔE_{ST}) between a singlet energy level and a triplet energy level of the compounds used in Comparative Examples 1 to 6 and Examples 1 to 8 were measured and listed in Table 1.

The emitting properties, i.e., a driving voltage (V), an external quantum efficiency (EQE), a color coordinate index (CIEy) and a lifespan (LT(95%)), of the OLED in Comparative Examples 1 to 6 and Examples 1 to 8 were measured at 8.6 mA/cm² and listed in Tables 2 and 3. In Tables 2 and 3, the lifespan is a relative value with respect to Comparative Example 1.

TABLE 1

| | LUMO (eV) | HOMO (eV) | ΔE_{ST} (eV) |
|---|---|---|---|
| HH-1 | −2.42 | −5.82 | — |
| EH-1 | −2.56 | −5.61 | 0.17 |
| EH-2 | −2.54 | −5.6 | 0.19 |
| EH-B1 | −3.01 | −6.11 | 0.45 |
| EH-B2 | −2.69 | −6.05 | 0.35 |
| EH-B3 | −2.62 | −5.88 | 0.2 |
| EH-B4 | −2.61 | −5.76 | 0.2 |
| PD-1 | −2.6 | −5.5 | — |

TABLE 2

| | n-host | V | EQE (%) | CIEy | LT (95%) |
|---|---|---|---|---|---|
| Ref1 | EH-B1 | 4.0 | 12.5 | 0.201 | 100 |
| Ref2 | EH-B1 | 4.1 | 10.6 | 0.286 | 60 |
| Ref3 | EH-B2 | 3.8 | 14.5 | 0.188 | 84 |
| Ref4 | EH-B2 | 4.1 | 12.2 | 0.256 | 40 |
| Ref5 | EH-B3 | 3.9 | 18.3 | 0.164 | 46 |
| Ref6 | EH-B4 | 4 | 16.2 | 0.165 | 55 |

TABLE 3

| | n-host | V | EQE (%) | CIEy | LT (95%) |
|---|---|---|---|---|---|
| Ex1 | EH-1 | 3.9 | 19.3 | 0.156 | 130 |
| Ex2 | EH-1 | 3.8 | 19.4 | 0.159 | 145 |
| Ex3 | EH-1 | 3.7 | 18.4 | 0.159 | 146 |
| Ex4 | EH-1 | 3.8 | 18.6 | 0.159 | 160 |
| Ex5 | EH-2 | 3.7 | 17.1 | 0.139 | 120 |
| Ex6 | EH-2 | 3.6 | 17.1 | 0.143 | 137 |
| Ex7 | EH-2 | 3.5 | 15.7 | 0.144 | 138 |
| Ex8 | EH-2 | 3.5 | 15.8 | 0.145 | 143 |

As shown in Tables 2 and 3, in comparison to the OLED of Comparative Examples 1 to 6, the OLED of Examples 1 to 8 has advantages in at least one of the driving voltage, the emitting efficiency, the color purity and the lifespan.

Referring to Table 1, since each of the compounds EH-B1, EH-B2, EH-B3 and EH-B4 used in the OLED of Comparative Examples 1 to 6 has a LUMO energy level being lower than that of the phosphorescent dopant, i.e., the compound PD-1, the electron is trapped into the n-type host, i.e., the compounds EH-B1, EH-B2, EH-B3 and EH-B4, so that the driving voltage of the OLED of Comparative Examples 1 to 6 is increased. In addition, since a difference (ΔE_{ST}) between a singlet energy level and a triplet energy level in each of the compounds EH-B1 and EH-B2 is relatively large, each of the compounds EH-B1 and EH-B2 does not provide a delayed fluorescent property so that the emitting efficiency of the OLED of Comparative Examples 1 to 4 is decreased. Moreover, since the n-type host, i.e., the compounds EH-B1, EH-B2, EH-B3 and EH-B4, and the phosphorescent dopant, i.e., the compound PD-1, form a complex, the emitting efficiency of the OLED of Comparative Examples 1 to 6 is decreased.

On the other hand, since each of the n-type host, i.e., the compound EH-1 or EH-2, used in the OLED of Examples 1 to 8 has a LUMO energy level being higher than that of the phosphorescent dopant, i.e., the compound PD-1, an electron trap in the n-type host can be suppressed or prevented so that the driving voltage of the OLED of Examples 1 to 8 is decreased. In addition, since a difference (ΔE_{ST}) between a singlet energy level and a triplet energy level in the n-type host, i.e., the compound EH-1 or EH-2, is small, the n-type host, i.e., the compound EH-1 or EH-2, provides a delayed fluorescent property so that the emitting efficiency and the lifespan of the OLED of Examples 1 to 8 are increased. Moreover, a complex generation between the n-type host, i.e., the compound EH-1 or EH-2, and the phosphorescent dopant, i.e., the compound PD-1, can be suppressed or prevented, the emitting efficiency of the OLED of Examples 1 to 8 is further increased. Furthermore, since a boron atom in the n-type host represented by Formula 1, i.e., the compound EH-1 or EH-2, can be protected by a tetraarylsilane moiety, the lifespan of the OLED of Examples 1 to 8 is further increased.

### 3. COMPARATIVE EXAMPLES

### (1) Comparative Example 7 (Ref7)

The compound HH-1 (43.5 wt %) in Formula 4, the compound EH-B1 (43.5 wt %) in Formula 14, the compound PD-1 (12 wt %) in Formula 6 and the compound FD-1 (1 wt %) in Formula 8 were used to form the EML.

### (2) Comparative Example 8 (Ref8)

The compound HH-1 (41.5 wt %) in Formula 4, the compound EH-B1 (41.5 wt %) in Formula 14, the compound PD-1 (16 wt %) in Formula 6 and the compound FD-1 (1 wt %) in Formula 8 were used to form the EML.

### (3) Comparative Example 9 (Ref9)

The compound HH-1 (43.5 wt %) in Formula 4, the compound EH-B1 (43.5 wt %) in Formula 14, the compound PD-1 (12 wt %) in Formula 6 and the compound FD-2 (1 wt %) in Formula 8 were used to form the EML.

### (4) Comparative Example 10 (Ref10)

The compound HH-1 (43.5 wt %) in Formula 4, the compound EH-B1 (43.5 wt %) in Formula 14, the compound PD-1 (12 wt %) in Formula 6 and the compound FD-3 (1 wt %) in Formula 8 were used to form the EML.

### (5) Comparative Example 11 (Ref11)

The compound HH-1 (43.5 wt %) in Formula 4, the compound EH-B2 (43.5 wt %) in Formula 14, the compound PD-1 (12 wt %) in Formula 6 and the compound FD-1 (1 wt %) in Formula 8 were used to form the EML.

### (6) Comparative Example 12 (Ref12)

The compound HH-1 (41.5 wt %) in Formula 4, the compound EH-B2 (41.5 wt %) in Formula 14, the compound PD-1 (16 wt %) in Formula 6 and the compound FD-1 (1 wt %) in Formula 8 were used to form the EML.

### (7) Comparative Example 13 (Ref13)

The compound HH-1 (43.5 wt %) in Formula 4, the compound EH-B2 (43.5 wt %) in Formula 14, the compound PD-1 (12 wt %) in Formula 6 and the compound FD-2 (1 wt %) in Formula 8 were used to form the EML.

### (8) Comparative Example 14 (Ref14)

The compound HH-1 (43.5 wt %) in Formula 4, the compound EH-B2 (43.5 wt %) in Formula 14, the compound PD-1 (12 wt %) in Formula 6 and the compound FD-3 (1 wt %) in Formula 8 were used to form the EML.

### (9) Comparative Example 15 (Ref15)

The compound HH-1 (41.5 wt %) in Formula 4, the compound EH-B3 (41.5 wt %) in Formula 14, the compound PD-1 (16 wt %) in Formula 6 and the compound FD-1 (1 wt %) in Formula 8 were used to form the EML.

### (10) Comparative Example 16 (Ref16)

The compound HH-1 (43.5 wt %) in Formula 4, the compound EH-B3 (43.5 wt %) in Formula 14, the compound PD-1 (12 wt %) in Formula 6 and the compound FD-2 (1 wt %) in Formula 8 were used to form the EML.

### (11) Comparative Example 17 (Ref17)

The compound HH-1 (43.5 wt %) in Formula 4, the compound EH-B3 (43.5 wt %) in Formula 14, the compound PD-1 (12 wt %) in Formula 6 and the compound FD-3 (1 wt %) in Formula 8 were used to form the EML.

### (12) Comparative Example 18 (Ref18)

The compound HH-1 (41.5 wt %) in Formula 4, the compound EH-B4 (41.5 wt %) in Formula 14, the compound PD-1 (16 wt %) in Formula 6 and the compound FD-1 (1 wt %) in Formula 8 were used to form the EML.

### (13) Comparative Example 19 (Ref19)

The compound HH-1 (43.5 wt %) in Formula 4, the compound EH-B4 (43.5 wt %) in Formula 14, the compound PD-1 (12 wt %) in Formula 6 and the compound FD-2 (1 wt %) in Formula 8 were used to form the EML.

### (14) Comparative Example 20 (Ref20)

The compound HH-1 (43.5 wt %) in Formula 4, the compound EH-B4 (43.5 wt %) in Formula 14, the compound PD-1 (12 wt %) in Formula 6 and the compound FD-3 (1 wt %) in Formula 8 were used to form the EML.

### 4. EXAMPLES

### (1) Example 9 (Ex9)

The compound HH-1 (45.5 wt %) in Formula 4, the compound EH-1 (45.5 wt %) in Formula 2, the compound PD-1 (8 wt %) in Formula 6, and the compound FD-1 (1 wt %) in Formula 8 were used to form the EML.

### (2) Example 10 (Ex10)

The compound HH-1 (43.5 wt %) in Formula 4, the compound EH-1 (43.5 wt %) in Formula 2, the compound PD-1 (12 wt %) in Formula 6, and the compound FD-1 (1 wt %) in Formula 8 were used to form the EML.

### (3) Example 11 (Ex11)

The compound HH-1 (41.5 wt %) in Formula 4, the compound EH-1 (41.5 wt %) in Formula 2, the compound PD-1 (16 wt %) in Formula 6, and the compound FD-1 (1 wt %) in Formula 8 were used to form the EML.

### (4) Example 12 (Ex12)

The compound HH-1 (39.5 wt %) in Formula 4, the compound EH-1 (39.5 wt %) in Formula 2, the compound PD-1 (20 wt %) in Formula 6, and the compound FD-1 (1 wt %) in Formula 8 were used to form the EML.

### (5) Example 13 (Ex13)

The compound HH-1 (41.5 wt %) in Formula 4, the compound EH-1 (41.5 wt %) in Formula 2, the compound PD-1 (16 wt %) in Formula 6, and the compound FD-2 (1 wt %) in Formula 8 were used to form the EML.

### (6) Example 14 (Ex14)

The compound HH-1 (39.5 wt %) in Formula 4, the compound EH-1 (39.5 wt %) in Formula 2, the compound PD-1 (20 wt %) in Formula 6, and the compound FD-2 (1 wt %) in Formula 8 were used to form the EML.

### (7) Example 15 (Ex15)

The compound HH-1 (41.5 wt %) in Formula 4, the compound EH-1 (41.5 wt %) in Formula 2, the compound PD-1 (16 wt %) in Formula 6, and the compound FD-3 (1 wt %) in Formula 8 were used to form the EML.

### (8) Example 16 (Ex16)

The compound HH-1 (39.5 wt %) in Formula 4, the compound EH-1 (39.5 wt %) in Formula 2, the compound PD-1 (20 wt %) in Formula 6, and the compound FD-3 (1 wt %) in Formula 8 were used to form the EML.

### (9) Example 17 (Ex17)

The compound HH-1 (45.5 wt %) in Formula 4, the compound EH-2 (45.5 wt %) in Formula 2, the compound PD-1 (8 wt %) in Formula 6, and the compound FD-1 (1 wt %) in Formula 8 were used to form the EML.

### (10) Example 18 (Ex18)

The compound HH-1 (43.5 wt %) in Formula 4, the compound EH-2 (43.5 wt %) in Formula 2, the compound PD-1 (12 wt %) in Formula 6, and the compound FD-1 (1 wt %) in Formula 8 were used to form the EML.

### (11) Example 19 (Ex19)

The compound HH-1 (41.5 wt %) in Formula 4, the compound EH-2 (41.5 wt %) in Formula 2, the compound PD-1 (16 wt %) in Formula 6, and the compound FD-1 (1 wt %) in Formula 8 were used to form the EML.

### (12) Example 20 (Ex20)

The compound HH-1 (39.5 wt %) in Formula 4, the compound EH-2 (39.5 wt %) in Formula 2, the compound PD-1 (20 wt %) in Formula 6, and the compound FD-1 (1 wt %) in Formula 8 were used to form the EML.

### (13) Example 21 (Ex21)

The compound HH-1 (41.5 wt %) in Formula 4, the compound EH-2 (41.5 wt %) in Formula 2, the compound PD-1 (16 wt %) in Formula 6, and the compound FD-2 (1 wt %) in Formula 8 were used to form the EML.

### (14) Example 22 (Ex22)

The compound HH-1 (39.5 wt %) in Formula 4, the compound EH-2 (39.5 wt %) in Formula 2, the compound PD-1 (20 wt %) in Formula 6, and the compound FD-2 (1 wt %) in Formula 8 were used to form the EML.

### (14) Example 23 (Ex23)

The compound HH-1 (41.5 wt %) in Formula 4, the compound EH-2 (41.5 wt %) in Formula 2, the compound PD-1 (16 wt %) in Formula 6, and the compound FD-3 (1 wt %) in Formula 8 were used to form the EML.

### (16) Example 24 (Ex24)

The compound HH-1 (39.5 wt %) in Formula 4, the compound EH-2 (39.5 wt %) in Formula 2, the compound PD-1 (20 wt %) in Formula 6, and the compound FD-3 (1 wt %) in Formula 8 were used to form the EML.

A LUMO energy level, a HOMO energy level and a difference (ΔE_{ST}) between a singlet energy level and a triplet energy level of the compounds used in Comparative Examples 7 to 20 and Examples 9 to 24 were measured and listed in Table 4.

The emitting properties, i.e., a driving voltage (V), an external quantum efficiency (EQE), a color coordinate index (CIEy) and a lifespan (LT(95%)), of the OLED in Comparative Examples 7 to 20 and Examples 9 to 24 were measured at 8.6 mA/cm² and listed in Tables 5 to 8. In Tables 5 to 8, the lifespan is a relative value with respect to Comparative Example 1.

TABLE 4

| | LUMO (eV) | HOMO (eV) | ΔE_{ST} (eV) |
|---|---|---|---|
| HH-1 | −2.42 | −5.82 | — |
| EH-1 | −2.56 | −5.61 | 0.17 |
| EH-2 | −2.54 | −5.6 | 0.19 |
| EH-B1 | −3.01 | −6.11 | 0.45 |
| EH-B2 | −2.69 | −6.05 | 0.35 |
| EH-B3 | −2.62 | −5.88 | 0.2 |
| EH-B4 | −2.61 | −5.76 | 0.2 |
| PD-1 | −2.6 | −5.5 | — |
| FD-1 | −2.8 | −5.4 | 0.017 |
| FD-2 | −2.8 | −5.5 | 0.019 |
| FD-3 | −2.8 | −5.4 | 0.018 |

TABLE 5

| | | | | | | LT |
|---|---|---|---|---|---|---|
| | n-host | FD | V | EQE (%) | CIEy | (95%) |
| Ref7 | EH-B1 | FD-1 | 4.41 | 16.2 | 0.184 | 40 |
| Ref8 | EH-B1 | FD-1 | 4.32 | 14.1 | 0.196 | 41 |
| Ref9 | EH-B1 | FD-2 | 4.42 | 15.2 | 0.203 | 20 |
| Ref10 | EH-B1 | FD-3 | 4.38 | 14.3 | 0.198 | 32 |
| Ref11 | EH-B2 | FD-1 | 4.25 | 17.3 | 0.164 | 80 |
| Ref12 | EH-B2 | FD-1 | 4.37 | 18.1 | 0.165 | 39 |
| Ref13 | EH-B2 | FD-2 | 4.45 | 18 | 0.201 | 50 |
| Ref14 | EH-B2 | FD-3 | 4.42 | 18.5 | 0.19 | 43 |

TABLE 6

| | n-host | FD | V | EQE (%) | CIEy | LT (95%) |
|---|---|---|---|---|---|---|
| Ref15 | EH-B3 | FD-1 | 4.2 | 18.2 | 0.162 | 30 |
| Ref16 | EH-B3 | FD-2 | 4.32 | 17.6 | 0.168 | 44 |
| Ref17 | EH-B3 | FD-3 | 4.11 | 17.5 | 0.162 | 36 |
| Ref18 | EH-B4 | FD-1 | 4.2 | 17.3 | 0.164 | 41 |
| Ref19 | EH-B4 | FD-2 | 4.3 | 16.8 | 0.166 | 27 |
| Ref20 | EH-B4 | FD-3 | 4.13 | 17.5 | 0.164 | 35 |

TABLE 7

| | n-host | FD | V | EQE (%) | CIEy | LT (95%) |
|---|---|---|---|---|---|---|
| Ex9 | EH-1 | FD-1 | 3.54 | 24.7 | 0.156 | 142 |
| Ex10 | EH-1 | FD-1 | 3.52 | 24.1 | 0.157 | 150 |
| Ex11 | EH-1 | FD-1 | 3.47 | 24 | 0.156 | 151 |
| Ex12 | EH-1 | FD-1 | 3.41 | 24.1 | 0.155 | 168 |
| Ex13 | EH-1 | FD-2 | 3.42 | 24.3 | 0.158 | 165 |
| Ex14 | EH-1 | FD-2 | 3.38 | 25.6 | 0.159 | 180 |
| Ex15 | EH-1 | FD-3 | 3.41 | 24.8 | 0.156 | 168 |
| Ex16 | EH-1 | FD-3 | 3.45 | 25.1 | 0.157 | 178 |

TABLE 8

| | n-host | FD | V | EQE (%) | CIEy | LT (95%) |
|---|---|---|---|---|---|---|
| Ex17 | EH-2 | FD-1 | 3.41 | 23.5 | 0.155 | 123 |
| Ex18 | EH-2 | FD-1 | 3.45 | 23.4 | 0.155 | 140 |
| Ex19 | EH-2 | FD-1 | 3.37 | 23.1 | 0.156 | 146 |
| Ex20 | EH-2 | FD-1 | 3.37 | 23 | 0.157 | 153 |
| Ex21 | EH-2 | FD-2 | 3.45 | 24.3 | 0.158 | 167 |
| Ex22 | EH-2 | FD-2 | 3.44 | 24.5 | 0.159 | 175 |
| Ex23 | EH-2 | FD-3 | 3.42 | 23.8 | 0.155 | 170 |
| Ex24 | EH-2 | FD-3 | 3.4 | 24.2 | 0.156 | 174 |

As shown in Tables 5 and 8, in comparison to the OLED of Comparative Examples 7 to 20, the OLED of Examples 9 to 24 has advantages in the driving voltage, the emitting efficiency, the color purity and the lifespan.

Referring to Table 4, since each of the compounds EH-B1, EH-B2, EH-B3 and EH-B4 used in the OLED of Comparative Examples 7 to 20 has a LUMO energy level being lower than the phosphorescent dopant, i.e., the compound PD-1, and/or the fluorescent dopant, i.e., the compounds FD-1, FD-2 and FD-3, the electron is trapped into the n-type host, i.e., the compounds EH-B1, EH-B2, EH-B3 and EH-B4, so that the driving voltage of the OLED of Comparative Examples 7 to 20 is increased. In addition, since a difference (ΔE_{ST}) between a singlet energy level and a triplet energy level in each of the compounds EH-B1 and EH-B2 is relatively large, each of the compounds EH-B1 and EH-B2 does not provide a delayed fluorescent property so that the emitting efficiency of the OLED of Comparative Examples 7 to 14 is decreased. Moreover, since the n-type host, i.e., the compounds EH-B1, EH-B2, EH-B3 and EH-B4, and the phosphorescent dopant, i.e., the compound PD-1, form a complex, the emitting efficiency of the OLED of Comparative Examples 7 to 20 is decreased.

On the other hand, since each of the n-type host, i.e., the compound EH-1 or EH-2, used in the OLED of Examples 9 to 24 has a LUMO energy level being higher than that of each of the phosphorescent dopant, i.e., the compound PD-1, and the fluorescent dopant, i.e., the compounds FD-1, FD-2 and FD-3, an electron trap in the n-type host can be suppressed or prevented so that the driving voltage of the OLED of Examples 9 to 24 is decreased. In addition, since a difference (ΔE_{ST}) between a singlet energy level and a triplet energy level in the n-type host, i.e., the compound EH-1 or EH-2, is small, the n-type host, i.e., the compound EH-1 or EH-2, provides a delayed fluorescent property so that the emitting efficiency and the lifespan of the OLED of Examples 9 to 24 are increased. Moreover, a complex generation between the n-type host, i.e., the compound EH-1 or EH-2, and the phosphorescent dopant, i.e., the compound PD-1, can be suppressed or prevented, the emitting efficiency of the OLED of Examples 9 to 24 is further increased. Furthermore, since a boron atom in the n-type host represented by Formula 1, i.e., the compound EH-1 or EH-2, can be protected by a tetraarylsilane moiety, the lifespan of the OLED of Examples 9 to 24 is further increased.

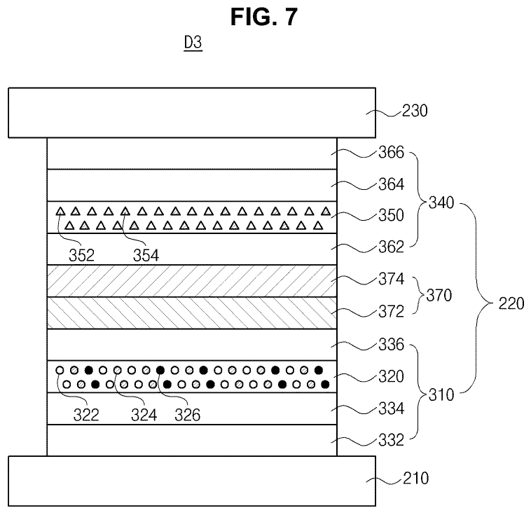

FIG. 7 is a schematic cross-sectional view of an OLED according to a fourth embodiment of the present disclosure.

As illustrated in FIG. 7, the OLED D3 includes first and second electrodes 210 and 230 facing each other and an organic light emitting layer 220 therebetween. The organic light emitting layer 220 includes a first emitting part 310 including a first blue EML 320 and a second emitting part 340 including a second blue EML 350. The organic light emitting layer 220 can include a CGL 370 between the first and second emitting parts 310 and 340. The OLED D3 can further include a capping layer on the second electrode 230 to enhance a light extraction efficiency.

The organic light emitting display device 100 can include a red pixel region, a green pixel region and a blue pixel region, and the OLED D3 can be positioned in the blue pixel region.

The first electrode 210 can be an anode, and the second electrode 230 can be a cathode. One of the first and second electrodes 210 and 230 can be a reflective electrode, and the other one of the first and second electrodes 210 and 230 can be a transparent (or a semi-transparent) electrode. For example, the first electrode 210 can have a single-layered structure of ITO, and the second electrode 230 can be formed of Al.

The first emitting part 310 can further include at least one of a first HTL 334 under the first blue EML 320 and a first ETL 336 over the first blue EML 320.

In addition, the first emitting part 310 can further include an HIL 332 between the first electrode 210 and the first HTL 334.

Moreover, the first emitting part 310 can further include at least one of a first EBL between the first HTL 334 and the first blue EML 320 and a first HBL between the first blue EML 320 and the first ETL 336.

The second emitting part 340 can further include at least one of a second HTL 362 under the second blue EML 350 and a second ETL 364 over the second blue EML 350.

In addition, the second emitting part 340 can further include an EIL 366 between the second electrode 230 and the second ETL 364.

Moreover, the second emitting part 340 can further include at least one of a second EBL between the second HTL 362 and the second blue EML 350 and a second HBL between the second blue EML 350 and the second ETL 364.

For example, the HIL 332 can include the above hole injection material and can have a thickness of 1 nm to 20 nm, e.g., 5 nm to 15 nm.

Each of the first and second HTLs 334 and 362 can include the above hole transporting material and can have a thickness of 30 nm to 60 nm, e.g., 40 nm to 50 nm.

Each of the first and second ETLs 336 and 364 can include the above electron transporting material and can have a thickness of 10 nm to 50 nm, e.g., 20 nm to 40 nm.

The EIL 366 can include the above electron injection material and can have a thickness of 0.1 nm to 10 nm, e.g., 1 nm to 5 nm.

Each of the first and second EBLs can include the above electron blocking material and can have a thickness of 5 nm to 20 nm, e.g., 5 nm to 15 nm.

Each of the first and second HBLs can include the above hole blocking material and can have a thickness of 5 nm to 20 nm, e.g., 5 nm to 15 nm.

The CGL 370 is positioned between the first and second emitting parts 310 and 340. Namely, the first and second emitting parts 310 and 340 are connected to each other through the CGL 370. The CGL 370 can be a PN-junction CGL of an N-type CGL 372 and a P-type CGL 374.

The N-type CGL 372 is positioned between the first ETL 336 and the second HTL 362, and the P-type CGL 374 is positioned between the N-type CGL 372 and the second HTL 362.

The N-type CGL 372 provides an electron into the first blue EML 320 of the first emitting part 310, and the P-type CGL 374 provides a hole into the second blue EML 350 of the second emitting part 340.

The N-type CGL 372 can be an organic layer doped with an alkali metal, e.g., Li, Na, K and Cs, and/or an alkali earth metal, e.g., Mg, Sr, Ba and Ra. For example, the N-type CGL 372 can be formed of an N-type charge generation material including a host being the organic material, e.g., 4,7-dipheny-1,10-phenanthroline (Bphen) and MTDATA, and a dopant being an alkali metal and/or an alkali earth metal, and the dopant can be doped with a weight % of 0.01 to 30.

The P-type CGL 374 can be formed of a P-type charge generation material including an inorganic material, e.g., tungsten oxide (WOₓ), molybdenum oxide (MoOₓ), beryllium oxide (Be₂O₃) or vanadium oxide (V₂O₅), an organic material, e.g., NPD, HAT-CN, F4TCNQ, TPD, TNB, TCTA, N,N′-dioctyl-3,4,9,10-perylenedicarboximide (PTCDI-C8) or their combination.

The first blue EML 320 can have a thickness in a range of 10 nm to 100 nm, e.g., 10 nm to 50 nm, preferably 20 nm to 40 nm.

The first blue EML 320 can include a first compound 322, a second compound 324 and a third compound 326. The first compound 322 can act as a first host, e.g., an n-type host, the second compound 324 can act as a second host, e.g., a p-type host, and the third compound 326 can act as a dopant.

The first compound 322 is represented by Formula 1 and can be one of the compounds in Formula 2. The second compound 324 is represented by Formula 3 and can be one of the compounds in Formula 4. The third compound 326 is represented by Formula 5 and can be one of the compounds in Formula 6.

In the first blue EML 320, a weight % of each of the first and second compounds 322 and 324 can be greater than that of the third compound 326. A weight % of the first compound 322 and a weight % of the second compound 324 can be same or different.

The first compound 322 can have a weight % of 25 to 50, the second compound 324 can have a weight % of 25 to 50, and the third compound 326 can have a weight % of 5 to 25. In an aspect of the present disclosure, a weight % of the first compound 322 and a weight % of the second compound 324 can be same, and the third compound 326 can have a weight % of 8, 12, 16 or 20.

In an aspect of the present disclosure, the first blue EML 320 can include a first compound 322, a second compound 324, a third compound 326 and a fluorescent compound. The first compound 322 can act as a first host, e.g., an n-type host, and the second compound 324 can act as a second host, e.g., a p-type host. The third compound 326 can act as an auxiliary host or an auxiliary dopant, and the fluorescent compound can act as a dopant.

The first compound 322 is represented by Formula 1 and can be one of the compounds in Formula 2. The second compound 324 is represented by Formula 3 and can be one of the compounds in Formula 4. The third compound 326 is represented by Formula 5 and can be one of the compounds in Formula 6. The fluorescent compound is represented by Formula 7 and can be one of the compounds in Formula 8.

In the first blue EML 320, a weight % of each of the first and second compounds 322 and 324 can be greater than that of each of the third compound 326 and the fluorescent compound. In addition, a weight % of the third compound 326 can be greater than that of the fluorescent compound. A weight % of the first compound 322 and a weight % of the second compound 324 can be same or different.

The first compound 322 can have a weight % of 25 to 50, and the second compound 324 can have a weight % of 25 to 50. The third compound 326 can have a weight % of 5 to 25, and the fluorescent compound can have a weight % of 0.1 to 3. In an aspect of the present disclosure, a weight % of the first compound 322 and a weight % of the second compound 324 can be same, the third compound 326 can have a weight % of 8, 12, 16 or 20, and the fluorescent compound can have a weight % of 1.

The second blue EML 350 includes a compound 352 as a blue host and a compound 354 as a blue dopant. For example, the compound 354 can be one of a blue fluorescent dopant, a blue phosphorescent dopant and a blue delayed fluorescent dopant. The second blue EML 350 can have a thickness in a range of 10 nm to 100 nm, e.g., 20 nm to 40 nm.

For example, the compound 352 can be selected from the group consisting of mCP, 9-(3-(9H-carbazol-9-yl)phenyl)-9H-carbazole-3-carbonitrile (mCP-CN), mCBP, CBP-CN, 9-(3-(9H-Carbazol-9-yl)phenyl)-3-(diphenylphosphoryl)-9H-carbazole (mCPPO1), 3,5-Di(9H-carbazol-9-yl)biphenyl (Ph-mCP), TSPO1, 9-(3′-(9H-carbazol-9-yl)-[1,1′-biphenyl]-3-yl)-9H-pyrido[2,3-b]indole (CzBPCb), bis(2-methylphenyl)diphenylsilane (UGH-1), 1,4-bis(triphenylsilyl)benzene (UGH-2), 1,3-bis(triphenylsilyl)benzene (UGH-3), 9,9-spirobifluoren-2-yl-diphenyl-phosphine oxide (SPPO1), and 9,9′-(5-(triphenylsilyl)-1,3-phenylene)bis(9H-carbazole) (SimCP).

For example, the compound 354 can be selected from the group consisting of perylene, 4,4′-bis[4-(di-p-tolylamino)styryl]biphenyl (DPAVBi), 4-(di-p-tolylamino)-4-4′-[(di-p-tolylamino)styryl]stilbene (DPAVB), 4,4′-bis[4-(diphenylamino)styryl]biphenyl (BDAVBi), 2,7-bis(4-diphenylamino)styryl-9,9-spirofluorene (spiro-DPVBi), 1,4-bis[2-[4-[N,N-di(p-tolyl)amino]phenyl]vinyl]benzene (DSB), 1-4-di-[4-(N,N-diphenyl)amino]styryl-benzene (DSA), 2,5,8,11-tetra-tert-butylperylene (TBPe), (bis(2-hydroxylphenyl)-pyridine)beryllium (Bepp2) and 9-(9-Phenylcarbazole-3-yl)-10-(naphthalene-1-yl)anthracene (PCAN).

In the blue pixel region, the organic light emitting layer 220 of the OLED D3 includes the first blue EML 320 and the second blue EML 350 to have a tandem structure.

In this case, the first blue EML 320 can include the first compound 322 represented by Formula 1, the second compound 324 represented by Formula 3 and the third compound 326 represented by Formula 5.

In the first compound 322 represented by Formula 1, a difference between a singlet energy level and a triplet energy level can be 0.3 eV or less. As a result, the first compound 322 can have a delayed fluorescent property so that a non-emissive triplet exciton can be converted into a singlet exciton. Accordingly, the emitting efficiency of the OLED D3 and the organic light emitting display device 100 including the OLED D3 can be improved.

In addition, since the first blue EML 320 includes the first compound 322 as an n-type host and the second compound 324 as a p-type host, the exciton generation efficiency in the first blue EML 320 and an exciton transfer efficiency into the third compound 326 can be improved. Accordingly, the emitting efficiency of the OLED D3 including the first, second and third compounds 322, 324 and 326 and the organic light emitting display device 100 including the OLED D3 can be improved.

Moreover, since the first compound 322 represented by formula 1 includes a tetraarylsilane structure represented by Formula 1-1, a boron atom can be protected. Accordingly, the lifespan of the OLED D3 including the first compound 322 and the organic light emitting display device 100 including the OLED D3 can be improved.

Further, since a complex formation between the first compound 322 represented by formula 1 and the third compound 326 represented by formula 5 can be prevented by a tetraarylsilane structure, a concentration of the third compound 326 in the first blue EML 320 can be increased. Accordingly, the emitting efficiency of the OLED D3 including the first and third compounds 322 and 326 and the organic light emitting display device 100 including the OLED D3 can be further improved.

Furthermore, since the first compound 322 represented by Formula 1 has a LUMO energy level higher than that of the third compound 326, an electron trap in the first compound 322 can be suppressed. Accordingly, the driving voltage of the OLED D3 and the organic light emitting display device 100 including the OLED D3 can be reduced.

In an aspect of the present disclosure, the first blue EML 320 can include the first compound 322 represented by Formula 1, the second compound represented by Formula 3, the third compound represented by Formula 5 and the fluorescent compound represented by Formula 7.

In each of the first compound 322 represented by Formula 1 and the fluorescent compound represented by Formula 7, a difference between a singlet energy level and a triplet energy level can be 0.3 eV or less. As a result, each of the first compound 322 and the fluorescent compound can have a delayed fluorescent property so that a non-emissive triplet exciton can be converted into a singlet exciton. Accordingly, the emitting efficiency of the OLED D3 and the organic light emitting display device 100 including the OLED D3 can be improved.

In addition, since the first blue EML 320 includes the first compound 322 as an n-type host and the second compound 324 as a p-type host, the exciton generation efficiency in the first blue EML 320 and an exciton transfer efficiency into the third compound 326 and/or the fluorescent compound can be improved. Accordingly, the emitting efficiency of the OLED D3 including the first, second and third compounds 322, 324 and 326 and the fluorescent compound and the organic light emitting display device 100 including the OLED D3 can be improved.

Moreover, since the first compound 322 represented by formula 1 includes a tetraarylsilane structure represented by Formula 1-1, a boron atom can be protected. Accordingly, the lifespan of the OLED D3 including the first compound 322 and the organic light emitting display device 100 including the OLED D3 can be improved.

Further, since a complex formation between the first compound 322 represented by formula 1 and the third compound 326 represented by formula 5 can be prevented by a tetraarylsilane structure, a concentration of the third compound 326 in the first blue EML 320 can be increased. Accordingly, the emitting efficiency of the OLED D3 including the first and third compounds 322 and 326 and the organic light emitting display device 100 including the OLED D3 can be further improved.

Furthermore, since the first compound 322 represented by Formula 1 has a LUMO energy level higher than that of each of the third compound 326 and the fluorescent compound, an electron trap in the first compound 322 can be suppressed. Accordingly, the driving voltage of the OLED D3 and the organic light emitting display device 100 including the OLED D3 can be reduced.

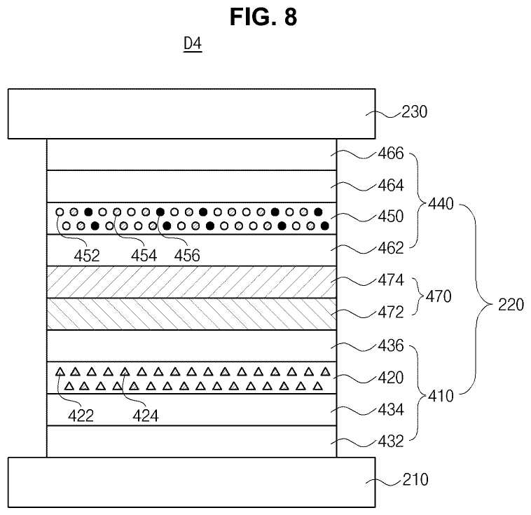

FIG. 8 is a schematic cross-sectional view of an OLED according to a fifth embodiment of the present disclosure.

As illustrated in FIG. 8, the OLED D4 includes first and second electrodes 210 and 230 facing each other and an organic light emitting layer 220 therebetween. The organic light emitting layer 220 includes a first emitting part 410 including a first blue EML 420 and a second emitting part 440 including a second blue EML 450. The organic light emitting layer 220 can include a CGL 470 between the first and second emitting parts 410 and 440. The OLED D4 can further include a capping layer on the second electrode 230 to enhance a light extraction efficiency.

The organic light emitting display device 100 can include a red pixel region, a green pixel region and a blue pixel region, and the OLED D4 can be positioned in the blue pixel region.

The first electrode 210 can be an anode, and the second electrode 230 can be a cathode. One of the first and second electrodes 210 and 230 can be a reflective electrode, and the other one of the first and second electrodes 210 and 230 can be a transparent (or a semi-transparent) electrode. For example, the first electrode 210 can have a single-layered structure of ITO, and the second electrode 230 can be formed of Al.

The first emitting part 410 can further include at least one of a first HTL 434 under the first blue EML 420 and a first ETL 436 over the first blue EML 420.

In addition, the first emitting part 410 can further include an HIL 432 between the first electrode 210 and the first HTL 434.

Moreover, the first emitting part 410 can further include at least one of a first EBL between the first HTL 434 and the first blue EML 420 and a first HBL between the first blue EML 420 and the first ETL 436.

The second emitting part 440 can further include at least one of a second HTL 462 under the second blue EML 450 and a second ETL 464 over the second blue EML 450.

In addition, the second emitting part 440 can further include an EIL 466 between the second electrode 230 and the second ETL 464.

Moreover, the second emitting part 440 can further include at least one of a second EBL between the second HTL 462 and the second blue EML 450 and a second HBL between the second blue EML 450 and the second ETL 464.

For example, the HIL 432 can include the above hole injection material and can have a thickness of 1 nm to 20 nm, e.g., 5 nm to 15 nm.

Each of the first and second HTLs 434 and 462 can include the above hole transporting material and can have a thickness of 30 nm to 60 nm, e.g., 40 nm to 50 nm.

Each of the first and second ETLs 436 and 464 can include the above electron transporting material and can have a thickness of 10 nm to 50 nm, e.g., 20 nm to 40 nm.

The EIL 466 can include the above electron injection material and can have a thickness of 0.1 nm to 10 nm, e.g., 1 nm to 5 nm.

Each of the first and second EBLs can include the above electron blocking material and can have a thickness of 5 nm to 20 nm, e.g., 5 nm to 15 nm.

Each of the first and second HBLs can include the above hole blocking material and can have a thickness of 5 nm to 20 nm, e.g., 5 nm to 15 nm.

The CGL 470 is positioned between the first and second emitting parts 410 and 440. Namely, the first and second emitting parts 410 and 440 are connected to each other through the CGL 470. The CGL 470 can be a PN-junction CGL of an N-type CGL 472 and a P-type CGL 474.

The N-type CGL 472 is positioned between the first ETL 436 and the second HTL 462, and the P-type CGL 474 is positioned between the N-type CGL 472 and the second HTL 462.

The N-type CGL 472 provides an electron into the first blue EML 420 of the first emitting part 410, and the P-type CGL 474 provides a hole into the second blue EML 450 of the second emitting part 440.

The N-type CGL 472 can be an organic layer doped with an alkali metal, e.g., Li, Na, K and Cs, and/or an alkali earth metal, e.g., Mg, Sr, Ba and Ra. For example, the N-type CGL 472 can be formed of an N-type charge generation material including a host being the organic material, e.g., 4,7-dipheny-1,10-phenanthroline (Bphen) and MTDATA, and a dopant being an alkali metal and/or an alkali earth metal, and the dopant can be doped with a weight % of 0.01 to 30.

The P-type CGL 474 can be formed of a P-type charge generation material including an inorganic material, e.g., tungsten oxide (WOₓ), molybdenum oxide (MoOₓ), beryllium oxide (Be₂O₃) or vanadium oxide (V₂O₅), an organic material, e.g., NPD, HAT-CN, F4TCNQ, TPD, TNB, TCTA, N,N′-dioctyl-3,4,9,10-perylenedicarboximide (PTCDI-C8) or their combination.

The first blue EML 420 includes a compound 422 as a blue host and a compound 424 as a blue dopant. For example, the compound 424 can be one of a blue fluorescent dopant, a blue phosphorescent dopant and a blue delayed fluorescent dopant. The first blue EML 420 can have a thickness in a range of 10 nm to 100 nm, e.g., 20 nm to 40 nm.

For example, the blue host can be one of the above blue host materials, and the blue dopant can be one of the above blue dopant materials.

The second blue EML 450 can have a thickness in a range of 10 nm to 100 nm, e.g., 10 nm to 50 nm, preferably 20 nm to 40 nm.

The second blue EML 450 can include a first compound 452, a second compound 454 and a third compound 456. The first compound 452 can act as a first host, e.g., an n-type host, the second compound 454 can act as a second host, e.g., a p-type host, and the third compound 456 can act as a dopant.

The first compound 452 is represented by Formula 1 and can be one of the compounds in Formula 2. The second compound 454 is represented by Formula 3 and can be one of the compounds in Formula 4. The third compound 456 is represented by Formula 5 and can be one of the compounds in Formula 6.

In the second blue EML 450, a weight % of each of the first and second compounds 452 and 454 can be greater than that of the third compound 456. A weight % of the first compound 452 and a weight % of the second compound 454 can be same or different.

The first compound 452 can have a weight % of 25 to 50, the second compound 454 can have a weight % of 25 to 50, and the third compound 456 can have a weight % of 5 to 25. In an aspect of the present disclosure, a weight % of the first compound 452 and a weight % of the second compound 454 can be same, and the third compound 456 can have a weight % of 8, 12, 16 or 20.

In an aspect of the present disclosure, the second blue EML 450 can include a first compound 452, a second compound 454, a third compound 456 and a fluorescent compound. The first compound 452 can act as a first host, e.g., an n-type host, and the second compound 454 can act as a second host, e.g., a p-type host. The third compound 456 can act as an auxiliary host or an auxiliary dopant, and the fluorescent compound can act as a dopant.

The first compound 452 is represented by Formula 1 and can be one of the compounds in Formula 2. The second compound 454 is represented by Formula 3 and can be one of the compounds in Formula 4. The third compound 456 is represented by Formula 5 and can be one of the compounds in Formula 6. The fluorescent compound is represented by Formula 7 and can be one of the compounds in Formula 8.

In the second blue EML 450, a weight % of each of the first and second compounds 452 and 454 can be greater than that of each of the third compound 456 and the fluorescent compound. In addition, a weight % of the third compound 456 can be greater than that of the fluorescent compound. A weight % of the first compound 452 and a weight % of the second compound 454 can be same or different.

The first compound 452 can have a weight % of 25 to 50, and the second compound 454 can have a weight % of 25 to 50. The third compound 456 can have a weight % of 5 to 25, and the fluorescent compound can have a weight % of 0.1 to 3. In an aspect of the present disclosure, a weight % of the first compound 452 and a weight % of the second compound 454 can be same, the third compound 456 can have a weight % of 8, 12, 16 or 20, and the fluorescent compound can have a weight % of 1.

In the blue pixel region, the organic light emitting layer 220 of the OLED D4 includes the first blue EML 420 and the second blue EML 450 to have a tandem structure.

In this case, the second blue EML 450 can include the first compound 452 represented by Formula 1, the second compound 454 represented by Formula 3 and the third compound 456 represented by Formula 5.

In the first compound 452 represented by Formula 1, a difference between a singlet energy level and a triplet energy level can be 0.3 eV or less. As a result, the first compound 452 can have a delayed fluorescent property so that a non-emissive triplet exciton can be converted into a singlet exciton. Accordingly, the emitting efficiency of the OLED D4 and the organic light emitting display device 100 including the OLED D4 can be improved.

In addition, since the second blue EML 450 includes the first compound 452 as an n-type host and the second compound 454 as a p-type host, the exciton generation efficiency in the second blue EML 450 and an exciton transfer efficiency into the third compound 456 can be improved. Accordingly, the emitting efficiency of the OLED D4 including the first, second and third compounds 452, 454 and 456 and the organic light emitting display device 100 including the OLED D4 can be improved.

Moreover, since the first compound 452 represented by formula 1 includes a tetraarylsilane structure represented by Formula 1-1, a boron atom can be protected. Accordingly, the lifespan of the OLED D4 including the first compound 452 and the organic light emitting display device 100 including the OLED D4 can be improved.

Further, since a complex formation between the first compound 452 represented by formula 1 and the third compound 456 represented by formula 5 can be prevented by a tetraarylsilane structure, a concentration of the third compound 456 in the second blue EML 450 can be increased. Accordingly, the emitting efficiency of the OLED D4 including the first and third compounds 452 and 456 and the organic light emitting display device 100 including the OLED D4 can be further improved.

Furthermore, since the first compound 452 represented by Formula 1 has a LUMO energy level higher than the third compound 456, an electron trap in the first compound 452 can be suppressed. Accordingly, the driving voltage of the OLED D4 and the organic light emitting display device 100 including the OLED D4 can be reduced.

In an aspect of the present disclosure, the second blue EML 450 can include the first compound 452 represented by Formula 1, the second compound represented by Formula 3, the third compound represented by Formula 5 and the fluorescent compound represented by Formula 7.

In each of the first compound 452 represented by Formula 1 and the fluorescent compound represented by Formula 7, a difference between a singlet energy level and a triplet energy level can be 0.3 eV or less. As a result, each of the first compound 452 and the fluorescent compound can have a delayed fluorescent property so that a non-emissive triplet exciton can be converted into a singlet exciton. Accordingly, the emitting efficiency of the OLED D4 and the organic light emitting display device 100 including the OLED D4 can be improved.

In addition, since the second blue EML 450 includes the first compound 452 as an n-type host and the second compound 454 as a p-type host, the exciton generation efficiency in the second blue EML 450 and an exciton transfer efficiency into the third compound 456 and/or the fluorescent compound can be improved. Accordingly, the emitting efficiency of the OLED D4 including the first, second and third compounds 452, 454 and 456 and the fluorescent compound and the organic light emitting display device 100 including the OLED D4 can be improved.

Moreover, since the first compound 452 represented by formula 1 includes a tetraarylsilane structure represented by Formula 1-1, a boron atom can be protected. Accordingly, the lifespan of the OLED D4 including the first compound 452 and the organic light emitting display device 100 including the OLED D4 can be improved.

Further, since a complex formation between the first compound 452 represented by formula 1 and the third compound 456 represented by formula 5 can be prevented by a tetraarylsilane structure, a concentration of the third compound 456 in the second blue EML 450 can be increased. Accordingly, the emitting efficiency of the OLED D4 including the first and third compounds 452 and 456 and the organic light emitting display device 100 including the OLED D4 can be further improved.

Furthermore, since the first compound 452 represented by Formula 1 has a LUMO energy level higher than that of each of the third compound 456 and the fluorescent compound, an electron trap in the first compound 452 can be suppressed. Accordingly, the driving voltage of the OLED D4 and the organic light emitting display device 100 including the OLED D4 can be reduced.

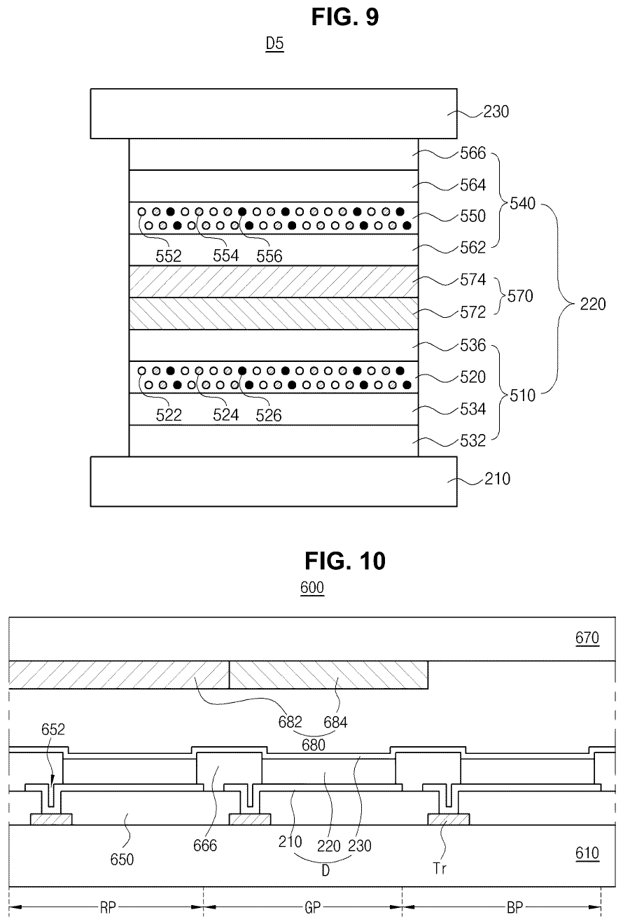

FIG. 9 is a schematic cross-sectional view of an OLED according to a sixth embodiment of the present disclosure.

As illustrated in FIG. 9, the OLED D5 includes first and second electrodes 210 and 230 facing each other and an organic light emitting layer 220 therebetween. The organic light emitting layer 220 includes a first emitting part 510 including a first blue EML 520 and a second emitting part 540 including a second blue EML 550. The organic light emitting layer 220 can include a CGL 570 between the first and second emitting parts 510 and 540. The OLED D5 can further include a capping layer on the second electrode 230 to enhance a light extraction efficiency.

The organic light emitting display device 100 can include a red pixel region, a green pixel region and a blue pixel region, and the OLED D5 can be positioned in the blue pixel region.

The first electrode 210 can be an anode, and the second electrode 230 can be a cathode. One of the first and second electrodes 210 and 230 can be a reflective electrode, and the other one of the first and second electrodes 210 and 230 can be a transparent (or a semi-transparent) electrode. For example, the first electrode 210 can have a single-layered structure of ITO, and the second electrode 230 can be formed of Al.

The first emitting part 510 can further include at least one of a first HTL 534 under the first blue EML 520 and a first ETL 536 over the first blue EML 520.

In addition, the first emitting part 510 can further include an HIL 532 between the first electrode 210 and the first HTL 534.

Moreover, the first emitting part 510 can further include at least one of a first EBL between the first HTL 534 and the first blue EML 520 and a first HBL between the first blue EML 520 and the first ETL 536.

The second emitting part 540 can further include at least one of a second HTL 562 under the second blue EML 550 and a second ETL 564 over the second blue EML 550.

In addition, the second emitting part 540 can further include an EIL 566 between the second electrode 230 and the second ETL 564.

Moreover, the second emitting part 540 can further include at least one of a second EBL between the second HTL 562 and the second blue EML 550 and a second HBL between the second blue EML 550 and the second ETL 564.

For example, the HIL 532 can include the above hole injection material and can have a thickness of 1 nm to 20 nm, e.g., 5 nm to 15 nm.

Each of the first and second HTLs 534 and 562 can include the above hole transporting material and can have a thickness of 30 nm to 60 nm, e.g., 40 nm to 50 nm.

Each of the first and second ETLs 536 and 564 can include the above electron transporting material and can have a thickness of 10 nm to 50 nm, e.g., 20 nm to 40 nm.

The EIL 566 can include the above electron injection material and can have a thickness of 0.1 nm to 10 nm, e.g., 1 nm to 5 nm.

Each of the first and second EBLs can include the above electron blocking material and can have a thickness of 5 nm to 20 nm, e.g., 5 nm to 15 nm.

Each of the first and second HBLs can include the above hole blocking material and can have a thickness of 5 nm to 20 nm, e.g., 5 nm to 15 nm.

The CGL 570 is positioned between the first and second emitting parts 510 and 540. Namely, the first and second emitting parts 510 and 540 are connected to each other through the CGL 570. The CGL 570 can be a PN-junction CGL of an N-type CGL 572 and a P-type CGL 574.

The N-type CGL 572 is positioned between the first ETL 536 and the second HTL 562, and the P-type CGL 574 is positioned between the N-type CGL 572 and the second HTL 562.

The N-type CGL 572 provides an electron into the first blue EML 520 of the first emitting part 510, and the P-type CGL 574 provides a hole into the second blue EML 550 of the second emitting part 540.

The N-type CGL 572 can be an organic layer doped with an alkali metal, e.g., Li, Na, K and Cs, and/or an alkali earth metal, e.g., Mg, Sr, Ba and Ra. For example, the N-type CGL 572 can be formed of an N-type charge generation material including a host being the organic material, e.g., 4,7-dipheny-1,10-phenanthroline (Bphen) and MTDATA, and a dopant being an alkali metal and/or an alkali earth metal, and the dopant can be doped with a weight % of 0.01 to 30.

The P-type CGL 574 can be formed of a P-type charge generation material including an inorganic material, e.g., tungsten oxide (WOₓ), molybdenum oxide (MoOₓ), beryllium oxide (Be₂O₃) or vanadium oxide (V₂O₅), an organic material, e.g., NPD, HAT-CN, F4TCNQ, TPD, TNB, TCTA, N,N′-dioctyl-3,4,9,10-perylenedicarboximide (PTCDI-C8) or their combination.

The first blue EML 520 can have a thickness in a range of 10 nm to 100 nm, e.g., 10 nm to 50 nm, preferably 20 nm to 40 nm.

The first blue EML 520 can include a first compound 522, a second compound 524 and a third compound 526. The first compound 522 can act as a first host, e.g., an n-type host, the second compound 524 can act as a second host, e.g., a p-type host, and the third compound 526 can act as a dopant.

The first compound 522 is represented by Formula 1 and can be one of the compounds in Formula 2. The second compound 524 is represented by Formula 3 and can be one of the compounds in Formula 4. The third compound 526 is represented by Formula 5 and can be one of the compounds in Formula 6.

In the first blue EML 520, a weight % of each of the first and second compounds 522 and 524 can be greater than that of the third compound 526. A weight % of the first compound 522 and a weight % of the second compound 524 can be same or different.

The first compound 522 can have a weight % of 25 to 50, the second compound 524 can have a weight % of 25 to 50, and the third compound 526 can have a weight % of 5 to 25. In an aspect of the present disclosure, a weight % of the first compound 522 and a weight % of the second compound 524 can be same, and the third compound 526 can have a weight % of 8, 12, 16 or 20.

In an aspect of the present disclosure, the first blue EML 520 can include a first compound 522, a second compound 524, a third compound 526 and a first fluorescent compound. The first compound 522 can act as a first host, e.g., an n-type host, and the second compound 524 can act as a second host, e.g., a p-type host. The third compound 526 can act as an auxiliary host or an auxiliary dopant, and the first fluorescent compound can act as a dopant.

The first compound 522 is represented by Formula 1 and can be one of the compounds in Formula 2. The second compound 524 is represented by Formula 3 and can be one of the compounds in Formula 4. The third compound 526 is represented by Formula 5 and can be one of the compounds in Formula 6. The first fluorescent compound is represented by Formula 7 and can be one of the compounds in Formula 8.

In the first blue EML 520, a weight % of each of the first and second compounds 522 and 524 can be greater than that of each of the third compound 526 and the first fluorescent compound. In addition, a weight % of the third compound 526 can be greater than that of the first fluorescent compound. A weight % of the first compound 522 and a weight % of the second compound 524 can be same or different.

The first compound 522 can have a weight % of 25 to 50, and the second compound 524 can have a weight % of 25 to 50. The third compound 526 can have a weight % of 5 to 25, and the first fluorescent compound can have a weight % of 0.1 to 3. In an aspect of the present disclosure, a weight % of the first compound 522 and a weight % of the second compound 524 can be same, the third compound 526 can have a weight % of 8, 12, 16 or 20, and the first fluorescent compound can have a weight % of 1.

The second blue EML 550 can have a thickness in a range of 10 nm to 100 nm, e.g., 10 nm to 50 nm, preferably 20 nm to 40 nm.

The second blue EML 550 can include a fourth compound 552, a fifth compound 554 and a sixth compound 556. The fourth compound 552 can act as a first host, e.g., an n-type host, the fifth compound 554 can act as a second host, e.g., a p-type host, and the sixth compound 556 can act as a dopant.

The fourth compound 552 is represented by Formula 1 and can be one of the compounds in Formula 2. The fifth compound 554 is represented by Formula 3 and can be one of the compounds in Formula 4. The sixth compound 556 is represented by Formula 5 and can be one of the compounds in Formula 6.

In the second blue EML 550, a weight % of each of the fourth and fifth compounds 552 and 554 can be greater than that of the sixth compound 556. A weight % of the fourth compound 552 and a weight % of the fifth compound 554 can be same or different.

The fourth compound 552 can have a weight % of 25 to 50, the fifth compound 554 can have a weight % of 25 to 50, and the sixth compound 556 can have a weight % of 5 to 25. In an aspect of the present disclosure, a weight % of the fourth compound 552 and a weight % of the fifth compound 554 can be same, and the sixth compound 556 can have a weight % of 8, 12, 16 or 20.

In an aspect of the present disclosure, the second blue EML 550 can include a fourth compound 552, a fifth compound 554, a sixth compound 556 and a second fluorescent compound. The fourth compound 552 can act as a first host, e.g., an n-type host, and the fifth compound 554 can act as a second host, e.g., a p-type host. The sixth compound 556 can act as an auxiliary host or an auxiliary dopant, and the second fluorescent compound can act as a dopant.

The fourth compound 552 is represented by Formula 1 and can be one of the compounds in Formula 2. The fifth compound 554 is represented by Formula 3 and can be one of the compounds in Formula 4. The sixth compound 556 is represented by Formula 5 and can be one of the compounds in Formula 6. The second fluorescent compound is represented by Formula 7 and can be one of the compounds in Formula 8.

In the second blue EML 550, a weight % of each of the fourth and fifth compounds 552 and 554 can be greater than that of each of the sixth compound 556 and the second fluorescent compound. In addition, a weight % of the sixth compound 556 can be greater than that of the second fluorescent compound. A weight % of the fourth compound 552 and a weight % of the fifth compound 554 can be same or different.

The fourth compound 552 can have a weight % of 25 to 50, and the fifth compound 554 can have a weight % of 25 to 50. The sixth compound 556 can have a weight % of 5 to 25, and the second fluorescent compound can have a weight % of 0.1 to 3. In an aspect of the present disclosure, a weight % of the fourth compound 552 and a weight % of the fifth compound 554 can be same, the sixth compound 556 can have a weight % of 8, 12, 16 or 20, and the second fluorescent compound can have a weight % of 1.

The first compound 522 in the first blue EML 520 and the fourth compound 552 in the second blue EML 550 can be same or different. The second compound 524 in the first blue EML 520 and the fifth compound 554 in the second blue EML 550 can be same or different. The third compound 526 in the first blue EML 520 and the sixth compound 556 in the second blue EML 550 can be same or different. The first fluorescent compound in the first blue EML 520 and the second fluorescent compound in the second blue EML 550 can be same or different.

A weight % of the first compound 522 in the first blue EML 520 and a weight % of the fourth compound 552 in the second blue EML 550 can be same or different. A weight % of the second compound 524 in the first blue EML 520 and a weight % of the fifth compound 554 in the second blue EML 550 can be same or different. A weight % of the third compound 526 in the first blue EML 520 and a weight % of the sixth compound 556 in the second blue EML 550 can be same or different. A weight % of the first fluorescent compound in the first blue EML 520 and a weight % of the second fluorescent compound in the second blue EML 550 can be same or different.

In the blue pixel region, the organic light emitting layer 220 of the OLED D5 includes the first blue EML 520 and the second blue EML 550 to have a tandem structure.

In this case, the first blue EML 520 can include the first compound 522 represented by Formula 1, the second compound 524 represented by Formula 3 and the third compound 526 represented by Formula 5, and the second blue EML 550 can include the fourth compound 552 represented by Formula 1, the fifth compound 554 represented by Formula 3 and the sixth compound 556 represented by Formula 5.

In each of the first compound 522 and the fourth compound 552 represented by Formula 1, a difference between a singlet energy level and a triplet energy level can be 0.3 eV or less. As a result, each of the first compound 522 and the fourth compound 552 can have a delayed fluorescent property so that a non-emissive triplet exciton can be converted into a singlet exciton. Accordingly, the emitting efficiency of the OLED D5 and the organic light emitting display device 100 including the OLED D5 can be improved.

Since the first blue EML 520 includes the first compound 522 as an n-type host and the second compound 524 as a p-type host, the exciton generation efficiency in the first blue EML 520 and an exciton transfer efficiency into the third compound 526 can be improved. Since the second blue EML 550 includes the fourth compound 552 as an n-type host and the fifth compound 554 as a p-type host, the exciton generation efficiency in the second blue EML 550 and an exciton transfer efficiency into the sixth compound 556 can be improved. Accordingly, the emitting efficiency of the OLED D5, where the first blue EML 520 includes the first, second and third compounds 522, 524 and 526 and the second blue EML 550 includes the fourth, fifth and sixth compounds 552, 554 and 556 and the organic light emitting display device 100 including the OLED D5 can be improved.

Moreover, since each of the first compound 522 and the fourth compound 552 represented by formula 1 includes a tetraarylsilane structure represented by Formula 1-1, a boron atom can be protected. Accordingly, the lifespan of the OLED D5 including the first compound 522 and the fourth compound 552 and the organic light emitting display device 100 including the OLED D5 can be improved.

Further, since a complex formation between the first compound 522 represented by formula 1 and the third compound 526 represented by formula 5 and a complex formation between the fourth compound 552 represented by formula 1 and the sixth compound 556 represented by formula 5 can be prevented by a tetraarylsilane structure, a concentration of the third compound 526 in the first blue EML 520 and a concentration of the sixth compound 556 in the second blue EML 550 can be increased. Accordingly, the emitting efficiency of the OLED D5 and the organic light emitting display device 100 including the OLED D5 can be further improved.

Furthermore, since each of the first compound 522 and the fourth compound 552 represented by Formula 1 has a LUMO energy level higher than that of the third compound 526 and the sixth compound 556, respectively, an electron trap in the first compound 522 and the fourth compound 552 can be suppressed. Accordingly, the driving voltage of the OLED D5 and the organic light emitting display device 100 including the OLED D5 can be reduced.

In an aspect of the present disclosure, the first blue EML 520 can include the first compound 522 represented by Formula 1, the second compound 524 represented by Formula 3, the third compound 526 represented by Formula 5 and the first fluorescent compound represented by Formula 7, and the second blue EML 550 can include the fourth compound 552 represented by Formula 1, the fifth compound 554 represented by Formula 3, the sixth compound 556 represented by Formula 5 and the second fluorescent compound represented by Formula 7.

In each of the first compound 522 and the fourth compound 552 represented by Formula 1 and the first and second fluorescent compounds represented by Formula 7, a difference between a singlet energy level and a triplet energy level can be 0.3 eV or less. As a result, each of the first compound 522 and the fourth compound 552 and the first and second fluorescent compounds can have a delayed fluorescent property so that a non-emissive triplet exciton can be converted into a singlet exciton. Accordingly, the emitting efficiency of the OLED D5 and the organic light emitting display device 100 including the OLED D5 can be improved.

Since the first blue EML 520 includes the first compound 522 as an n-type host and the second compound 524 as a p-type host, the exciton generation efficiency in the first blue EML 520 and an exciton transfer efficiency into the third compound 526 and/or the first fluorescent compound can be improved. In addition, since the second blue EML 550 includes the fourth compound 552 as an n-type host and the fifth compound 554 as a p-type host, the exciton generation efficiency in the second blue EML 550 and an exciton transfer efficiency into the sixth compound 556 and/or the second fluorescent compound can be improved. Accordingly, the emitting efficiency of the OLED D5 and the organic light emitting display device 100 including the OLED D5 can be improved.

Moreover, since each of the first and fourth compounds 522 and 552 represented by formula 1 includes a tetraarylsilane structure represented by Formula 1-1, a boron atom can be protected. Accordingly, the lifespan of the OLED D5 and the organic light emitting display device 100 including the OLED D5 can be improved.

Further, since a complex formation between the first compound 522 represented by formula 1 and the third compound 526 represented by formula 5 and a complex formation between the fourth compound 552 represented by formula 1 and the sixth compound 556 represented by formula 5 can be prevented by a tetraarylsilane structure, a concentration of the third compound 526 in the first blue EML 520 and a concentration of the sixth compound 556 in the second blue EML 550 can be increased. Accordingly, the emitting efficiency of the OLED D5 and the organic light emitting display device 100 including the OLED D5 can be further improved.

Furthermore, since the first and fourth compounds 522 and 552 represented by Formula 1 has a LUMO energy level higher than that of the third and sixth compounds 526 and 556 and the fluorescent compound, respectively, an electron trap in the first and fourth compounds 522 and 552 can be suppressed. Accordingly, the driving voltage of the OLED D5 and the organic light emitting display device 100 including the OLED D5 can be reduced.

FIG. 10 is a schematic cross-sectional view illustrating an organic light emitting display device according to a seventh embodiment of the present disclosure.

As illustrated in FIG. 10, the organic light emitting display device 600 includes a first substrate 610, where a red pixel region RP, a green pixel region GP and a blue pixel region BP are defined, a second substrate 670 facing the first substrate 610, an OLED D, which is positioned between the first and second substrates 610 and 670 and provides white emission, and a color conversion layer 680 between the OLED D and the second substrate 670.

Optionally, a color filter can be formed between the second substrate 670 and each color conversion layer 680.

Each of the first and second substrates 610 and 670 can be a glass substrate or a flexible substrate. For example, the flexible substrate can be a polyimide (PI) substrate, a polyethersulfone (PES) substrate, a polyethylenenaphthalate (PEN) substrate, a polyethylene terephthalate (PET) substrate or a polycarbonate (PC) substrate.

A TFT Tr, which corresponds to each of the red, green and blue pixel regions RP, GP and BP, is formed on the first substrate 610, and a planarization layer 650, which has a drain contact hole 652 exposing an electrode, e.g., a drain electrode, of the TFT Tr is formed to cover the TFT Tr.

The OLED D including a first electrode 210, an organic light emitting layer 220 and a second electrode 230 is formed on the planarization layer 650. In this instance, the first electrode 210 can be connected to the drain electrode of the TFT Tr through the drain contact hole 652.

The first electrode 210 can be an anode, and the second electrode 230 can be a cathode. One of the first and second electrodes 210 and 230 can be a reflective electrode, and the other one of the first and second electrodes 210 and 230 can be a transparent (or a semi-transparent) electrode. For example, the first electrode 210 can have a single-layered structure of ITO, and the second electrode 230 can be formed of Al.

A bank layer 666 is formed on the planarization layer 650 to cover an edge of the first electrode 210. Namely, the bank layer 666 is positioned at a boundary of the pixel region and exposes a center of the first electrode 210 in the pixel region. Since the OLED D emits blue light in each of the red, green and blue pixel regions RP, GP and BP, the organic light emitting layer 220 can be integrally formed as a common layer in the red, green and blue pixel regions RP, GP and BP without separation. The bank layer 666 can be formed to prevent a current leakage at an edge of the first electrode 210 and can be omitted.

The OLED D emits a blue light and can have a structure shown in FIGS. 3, 5 and 7 to 9. Namely, the OLED D is formed in each of the red, green and blue pixel regions RP, GP and BP and provides the blue light.

For example, referring to FIG. 3, the organic light emitting layer 220 of the OLED D includes the blue EML 240A, and the blue EML 240A include the first compound 242a represented by Formula 1, the second compound 244a represented by Formula 3 and the third compound 246a represented by Formula 5.

The first compound 242a can have a delayed fluorescent property so that the emitting efficiency of the OLED D and the organic light emitting display device 600 including the OLED D can be improved.

In addition, since the first compound 242a represented by formula 1 includes a tetraarylsilane structure represented by Formula 1-1, a boron atom can be protected. Accordingly, the lifespan of the OLED D and the organic light emitting display device 600 including the OLED D can be improved.

Moreover, since a complex formation between the first compound 242a represented by formula 1 and the third compound 246a represented by formula 5 can be prevented by a tetraarylsilane structure, a concentration of the third compound 246a in the blue EML 240A can be increased. Accordingly, the emitting efficiency of the OLED D and the organic light emitting display device 600 including the OLED D can be further improved.

Furthermore, since the first compound 242a represented by Formula 1 has a LUMO energy level higher than that of the third compound 246a, an electron trap in the first compound 242a can be suppressed. Accordingly, the driving voltage of the OLED D and the organic light emitting display device 600 including the OLED D can be reduced.

In an aspect of the present disclosure, as shown in FIG. 5, the organic light emitting layer 220 of the OLED D includes the blue EML 240B, and the blue EML 240B include the first compound 242b represented by Formula 1, the second compound 244b represented by Formula 3, the third compound 246b represented by Formula 5 and the fluorescent compound 248b represented by Formula 7.

Each of the first compound 242b represented by Formula 1 and the fluorescent compound 248b represented by Formula 7 can have a delayed fluorescent property so that the emitting efficiency of the OLED D and the organic light emitting display device 600 including the OLED D can be improved.

In addition, since the first compound 242b represented by formula 1 includes a tetraarylsilane structure represented by Formula 1-1, a boron atom can be protected. Accordingly, the lifespan of the OLED D and the organic light emitting display device 600 including the OLED D can be improved.

Moreover, since a complex formation between the first compound 242b represented by formula 1 and the third compound 246b represented by formula 5 can be prevented by a tetraarylsilane structure, a concentration of the third compound 246b in the EML 240B can be increased. Accordingly, the emitting efficiency of the OLED D and the organic light emitting display device 600 including the OLED D can be further improved.

Furthermore, since the first compound 242b represented by Formula 1 has a LUMO energy level higher than that of each of the third and fluorescent compounds 246b and 248b, an electron trap in the first compound 242b can be suppressed. Accordingly, the driving voltage of the OLED D and the organic light emitting display device 600 including the OLED D can be reduced.

The color conversion layer 680 includes a first color conversion layer 682 corresponding to the red pixel region RP and a second color conversion layer 684 corresponding to the green pixel region GP. For example, the color conversion layer 680 can include an inorganic color conversion material such as a quantum dot. The color conversion layer is not presented in the blue pixel region BP so that the OLED D in the blue pixel region BP can directly face the second substrate 670.

The blue light from the OLED D is converted into the red light by the first color conversion layer 682 in the red pixel region RP, and the blue light from the OLED D is converted into the green light by the second color conversion layer 684 in the green pixel region GP.

Accordingly, the organic light emitting display device 600 can display a full-color image.

When the light from the OLED D passes through the first substrate 610 to display an image, the color conversion layer 680 can be disposed between the OLED D and the first substrate 610.

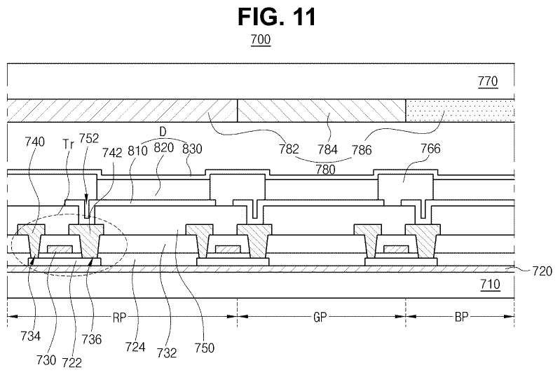

FIG. 11 is a schematic cross-sectional view illustrating an organic light emitting display device according to an eighth embodiment of the present disclosure.

As illustrated in FIG. 11, the organic light emitting display device 700 includes a first substrate 710, where a red pixel region RP, a green pixel region GP and a blue pixel region BP are defined, a second substrate 770 facing the first substrate 710, an OLED D, which is positioned between the first and second substrates 710 and 770 and provides white emission, and a color filter layer 780 between the OLED D and the second substrate 770.

Each of the first and second substrates 710 and 770 can be a glass substrate or a flexible substrate. For example, the flexible substrate can be a polyimide (PI) substrate, a polyethersulfone (PES) substrate, a polyethylenenaphthalate (PEN) substrate, a polyethylene terephthalate (PET) substrate or a polycarbonate (PC) substrate.

A buffer layer 720 is formed on the first substrate 710, and the TFT Tr corresponding to each of the red, green and blue pixel regions RP, GP and BP is formed on the buffer layer 720. The buffer layer 720 can be omitted.

A semiconductor layer 722 is formed on the buffer layer 720. The semiconductor layer 722 can include an oxide semiconductor material or polycrystalline silicon.

A gate insulating layer 724 is formed on the semiconductor layer 722. The gate insulating layer 724 can be formed of an inorganic insulating material such as silicon oxide or silicon nitride.

A gate electrode 730, which is formed of a conductive material, e.g., metal, is formed on the gate insulating layer 724 to correspond to a center of the semiconductor layer 722.

An interlayer insulating layer 732, which is formed of an insulating material, is formed on the gate electrode 730. The interlayer insulating layer 732 can be formed of an inorganic insulating material, e.g., silicon oxide or silicon nitride, or an organic insulating material, e.g., benzocyclobutene or photo-acryl.

The interlayer insulating layer 732 includes first and second contact holes 734 and 736 exposing both sides of the semiconductor layer 722. The first and second contact holes 734 and 736 are positioned at both sides of the gate electrode 730 to be spaced apart from the gate electrode 730.

A source electrode 740 and a drain electrode 742, which are formed of a conductive material, e.g., metal, are formed on the interlayer insulating layer 732.

The source electrode 740 and the drain electrode 742 are spaced apart from each other with respect to the gate electrode 730 and respectively contact both sides of the semiconductor layer 722 through the first and second contact holes 734 and 736.

The semiconductor layer 722, the gate electrode 730, the source electrode 740 and the drain electrode 742 constitute the TFT Tr. The TFT Tr serves as a driving element. Namely, the TFT Tr can correspond to the driving TFT Td (of FIG. 1).

Optionally, the gate line and the data line cross each other to define the pixel, and the switching TFT is formed to be connected to the gate and data lines. The switching TFT is connected to the TFT Tr as the driving element.

In addition, the power line, which can be formed to be parallel to and spaced apart from one of the gate and data lines, and the storage capacitor for maintaining the voltage of the gate electrode of the TFT Tr in one frame can be further formed.

A planarization layer 750, which includes a drain contact hole 752 exposing the drain electrode 742 of the TFT Tr, is formed to cover the TFT Tr.

A first electrode 810, which is connected to the drain electrode 742 of the TFT Tr through the drain contact hole 752, is separately formed in each pixel region and on the planarization layer 750. The first electrode 810 can be an anode and can be formed of a conductive material having a relatively high work function. For example, the first electrode 810 can include a transparent conductive oxide layer formed of a transparent conductive oxide (TCO).

For example, the transparent conductive oxide material layer of the first electrode 810 can be formed of one of indium-tin-oxide (ITO), indium-zinc-oxide (IZO), indium-tin-zinc-oxide (ITZO), tin oxide (SnO), zinc oxide (ZnO), indium-copper-oxide (ICO) and aluminum-zinc-oxide (Al:ZnO, AZO).

The first electrode 810 can further include a reflective layer to have a double-layered structure or a triple-layered structure. Namely, the first electrode 810 can be a reflective electrode.

For example, the reflective layer can be formed of one of silver (Ag), an alloy of Ag and one of palladium (Pd), copper (Cu), indium (In) and neodymium (Nd), and aluminum-palladium-copper (APC) alloy. For example, the first electrode 810 can have a double-layered structure of Ag/ITO or APC/ITO or a triple-layered structure of ITO/Ag/ITO or ITO/APC/ITO.

A bank layer 766 is formed on the planarization layer 750 to cover an edge of the first electrode 810. Namely, the bank layer 766 is positioned at a boundary of the pixel region and exposes a center of the first electrode 810 in the pixel region. Since the OLED D emits blue light in each of the red, green and blue pixel regions RP, GP and BP, an organic light emitting layer 820 can be integrally formed as a common layer in the red, green and blue pixel regions RP, GP and BP without separation. The bank layer 766 can be formed to prevent a current leakage at an edge of the first electrode 810 and can be omitted.

The organic light emitting layer 820 is formed on the first electrode 810.

A second electrode 830 is formed over the first substrate 710 where the organic light emitting layer 820 is formed.

In the organic light emitting display device 700, since the light emitted from the organic light emitting layer 820 is incident to the color filter layer 780 through the second electrode 830, the second electrode 830 has a thin profile for transmitting the light.

The first electrode 810, the organic light emitting layer 820 and the second electrode 830 constitute the OLED D.

The color filter layer 780 is disposed over the OLED D and includes a red color filter 782, a green color filter 784 and a blue color filter 786 respectively corresponding to the red pixel region RP, the green pixel region GP and the blue pixel region BP. The red color filter 782 includes at least one of a red dye and a red pigment, the green color filter 784 includes at least one of a green dye and a green pigment, and the blue color filter 786 includes at least one of a blue dye and a blue pigment.

The color filter layer 780 can be attached to the OLED D using an adhesive layer. Alternatively, the color filter layer 780 can be formed directly on the OLED D.

An encapsulation layer (or an encapsulation film) can be formed to prevent penetration of moisture into the OLED D. For example, the encapsulation layer can include a first inorganic insulating layer, an organic insulating layer and a second inorganic insulating layer sequentially stacked, but it is not limited thereto. The encapsulation layer can be omitted.

In the bottom-emission type organic light emitting display device 700, a metal plate can be disposed over the second electrode 830. The metal plate can be attached to the OLED D using an adhesive layer.

A polarization plate for reducing an ambient light reflection can be disposed over the top-emission type OLED D. For example, the polarization plate can be a circular polarization plate.

In the OLED D of FIG. 11, the first electrode 810 and the second electrode 830 are a reflective electrode and a transparent (or semitransparent) electrode, respectively, and the color filter layer 780 is disposed over the OLED D.

Alternatively, the first electrode 810 and the second electrode 830 can be a transparent (or semitransparent) electrode and a reflective electrode, respectively, and the color filter layer 780 can be disposed between the OLED D and the first substrate 710. In this case, first electrode 810 can have a single-layered structure of the transparent conductive oxide layer.

A color conversion layer can be formed between the OLED D and the color filter layer 780. The color conversion layer can include a red color conversion layer, a green color conversion layer and a blue color conversion layer respectively corresponding to the red, green and blue pixel regions RP, GP and BP. The white light from the OLED D is converted into the red light, the green light and the blue light by the red, green and blue color conversion layer, respectively.

The color conversion layer can be included instead of the color filter layer 780.

As described above, in the organic light emitting display device 700, the OLED D in the red, green and blue pixel regions RP, GP and BP emits the white light, and the white light from the OLED D passes through the red color filter 782, the green color filter 784 and the blue color filter 786. As a result, the red light, the green light and the blue light are provided from the red pixel region RP, the green pixel region GP and the blue pixel region BP, respectively.

In FIG. 11, the OLED D emitting the white light is used for a display device. Alternatively, the OLED D can be formed on an entire surface of a substrate without at least one of the driving element and the color filter layer to be used for a lightening device. The display device and the lightening device each including the OLED D of the present disclosure can be referred to as an organic light emitting device.

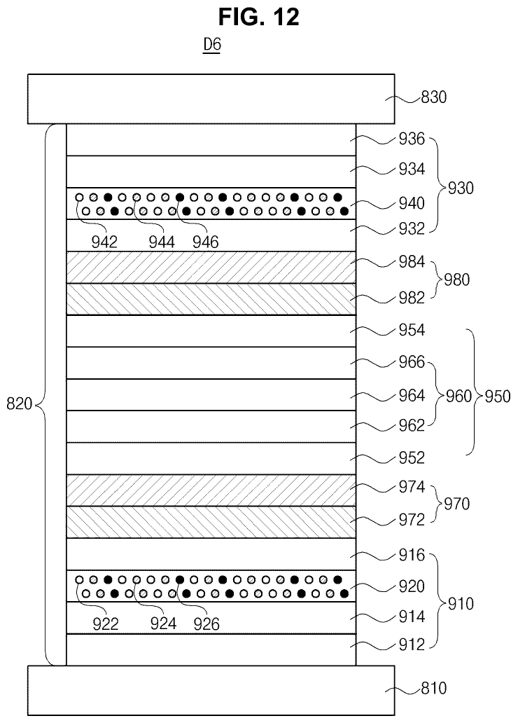

FIG. 12 is a schematic cross-sectional view of an OLED according to a ninth embodiment of the present disclosure.

As illustrated in FIG. 12, the OLED D6 includes first and second electrodes 810 and 830, which face each other, and an organic light emitting layer 820 therebetween. The organic light emitting layer 820 includes a first emitting part 910 including a first blue EML 920, e.g., a first blue EML, a second emitting part 930 including a second blue EML 940, e.g., a second blue EML, and a third emitting part 950 including a third EML 960. The organic light emitting layer 820 can further includes a first CGL 970 between the first and third emitting parts 910 and 950 and a second CGL 980 between the second and third emitting parts 930 and 950. The OLED D6 can further include a capping layer on the second electrode 830 to enhance a light extraction efficiency.

The organic light emitting display device 700 can include a red pixel region, a green pixel region and a blue pixel region, and the OLED D6 can be positioned in the red, green and blue pixel regions RP, GP and BP and emits blue light.

The first electrode 810 can be an anode, and the second electrode 830 can be a cathode. One of the first and second electrodes 810 and 830 can be a reflective electrode, and the other one of the first and second electrodes 810 and 830 can be a transparent (or a semi-transparent) electrode. For example, the first electrode 810 can have a single-layered structure of ITO, and the second electrode 830 can be formed of Al.

The first emitting part 910 can further include at least one of a first HTL 914 under the first blue EML 920 and a first ETL 916 over the first blue EML 920.

In addition, the first emitting part 910 can further include an HIL 912 between the first electrode 810 and the first HTL 914.

Moreover, the first emitting part 910 can further include at least one of a first EBL between the first HTL 914 and the first blue EML 920 and a first HBL between the first blue EML 920 and the first ETL 916.

The second emitting part 930 can further include at least one of a second HTL 932 under the second blue EML 940 and a second ETL 934 over the second blue EML 940.

In addition, the second emitting part 930 can further include an EIL 936 between the second electrode 830 and the second ETL 934.

Moreover, the second emitting part 930 can further include at least one of a second EBL between the second HTL 932 and the second blue EML 940 and a second HBL between the second blue EML 940 and the second ETL 934.

In the third emitting part 950, the third EML 960 can include a red EML 962, a yellow-green EML 964 and a green EML 966. In this case, the yellow-green EML 964 is disposed between the red and green EMLs 962 and 966. Alternatively, the yellow-green EML 964 can be omitted, and the third EML 960 can have a double-layered structure including the red and green EMLs 962 and 966.

The red EML 962 includes a red host and a red dopant, the green EML 966 includes a green host and a green dopant, and the yellow-green EML 964 includes a yellow-green host and a yellow-green dopant. Each of the red dopant, the green dopant and the yellow-green dopant can be one of a fluorescent compound, a phosphorescent compound and a delayed fluorescent compound.

For example, the red host can be selected from the group consisting of mCP-CN, CBP, mCBP, mCP, DPEPO, 2,8-bis(diphenylphosphoryl)dibenzothiophene (PPT), 1,3,5-tri[(3-pyridyl)-phen-3-yl]benzene (TmPyPB), 2,6-di(9H-carbazol-9-yl)pyridine (PYD-2Cz), 2,8-di(9H-carbazol-9-yl)dibenzothiophene (DCzDBT), 3′,5′-di(carbazol-9-yl)-[1,1′-biphenyl]-3,5-dicarbonitrile (DCzTPA), 4′-(9H-carbazol-9-yl)biphenyl-3,5-dicarbonitrile(4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, 9,9′-diphenyl-9H,9′H-3,3′-bicarbazole (BCzPh), 1,3,5-tris(carbazole-9-yl)benzene (TCP), TCTA, 4,4′-bis(carbazole-9-yl)-2,2′-dimethylbiphenyl (CDBP), 2,7-bis(carbazole-9-yl)-9,9-dimethylfluorene (DMFL-CBP), 2,2′,7,7′-tetrakis(carbazole-9-yl)-9,9-spiorofluorene (Spiro-CBP), and 3,6-bis(carbazole-9-yl)-9-(2-ethyl-hexyl)-9H-carbazole (TCzl), but it is not limited thereto.

The red dopant can be selected from the group consisting of [bis(2-(4,6-dimethyl)phenylquinoline)](2,2,6,6-tetramethylheptane-3,5-dionate)iridium(III), bis[2-(4-n-hexylphenyl)quinoline](acetylacetonate)iridium(III) (Hex-Ir(phq)2(acac)), tris[2-(4-n-hexylphenyl)quinoline]iridium(III) (Hex-Ir(phq)3), tris[2-phenyl-4-methylquinoline]iridium(III) (lr(Mphq)3), bis(2-phenylquinoline)(2,2,6,6-tetramethylheptene-3,5-dionate)iridium(III) (lr(dpm)PQ2), bis(phenylisoquinoline)(2,2,6,6-tetramethylheptene-3,5-dionate)iridium(III) (Ir(dpm)(piq)2), bis[(4-n-hexylphenyl)isoquinoline](acetylacetonate)iridium(III) (Hex-Ir(piq)2(acac)), tris[2-(4-n-hexylphenyl)quinoline]iridium(III) (Hex-Ir(piq)3), tris(2-(3-methylphenyl)-7-methyl-quinolato)iridium (lr(dmpq)3), bis[2-(2-methylphenyl)-7-methyl-quinoline](acetylacetonate)iridium(III) (Ir(dmpq)2(acac)), bis[2-(3,5-dimethylphenyl)-4-methyl-quinoline](acetylacetonate)iridium(III) (Ir(mphmq)2(acac)), and tris(dibenzoylmethane)mono(1,10-phenanthroline)europium(III) (Eu(dbm)3(phen)), but it is not limited thereto.

Each of the green host and the yellow-green host can be independently selected from the group consisting of mCP-CN, CBP, mCBP, mCP, DPEPO, 2,8-bis(diphenylphosphoryl)dibenzothiophene (PPT), TmPyPB, PYD-2Cz, 2,8-di(9H-carbazol-9-yl)dibenzothiophene (DCzDBT), 3′,5′-di(carbazol-9-yl)-[1,1′-biphenyl]-3,5-dicarbonitrile (DCzTPA), 4′-(9H-carbazol-9-yl)biphenyl-3,5-dicarbonitrile(4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, and 9-(9-phenyl-9H-carbazol-6-yl)-9H-carbazole (CCP), but it is not limited thereto.

The green dopant can be selected from the group consisting of [bis(2-phenylpyridine)](pyridyl-2-benzofuro[2,3-b]pyridine)iridium, tris[2-phenylpyridine]iridium(III) (Ir(ppy)3), fac-tris(2-phenylpyridine)iridium(III) (fac-Ir(ppy)3), bis(2-phenylpyridine)(acetylacetonate)iridium(III) (Ir(ppy)2(acac)), tris[2-(p-tolyl)pyridine]iridium(III) (Ir(mppy)3), bis(2-(naphthalene-2-yl)pyridine)(acetylacetonate)iridium(III) (Ir(npy)2acac), tris(2-phenyl-3-methyl-pyridine)iridium (Ir(3mppy)3), and fac-Tris(2-(3-p-xylyl)phenyl)pyridine iridium(III) (TEG), but it is not limited thereto.

The yellow-green dopant can be selected from the group consisting of 5,6,11,12-tetraphenylnaphthalene (Rubrene), 2,8-di-tert-butyl-5,11-bis(4-tert-butylphenyl)-6,12-diphenyltetracene (TBRb), bis(2-phenylbenzothiazolato)(acetylacetonate)irdium(III) (Ir(BT)2(acac)), bis(2-(9,9-diethytl-fluoren-2-yl)-1-phenyl-1H-benzo[d]imdiazolato)(acetylacetonate)iridium(III) (Ir(fbi)2(acac)), bis(2-phenylpyridine)(3-(pyridine-2-yl)-2H-chromen-2-onate)iridium(III) (fac-Ir(ppy)2Pc), bis(2-(2,4-difluorophenyl)quinoline)(picolinate)iridium(III) (FPQIrpic), and bis(4-phenylthieno[3,2-c]pyridinato-N,C2′) (acetylacetonate) iridium(III) (PO-01), but it is not limited thereto.

The third emitting part 950 can include at least one of a third HTL 952 under the third EML 960 and a third ETL 954 over the third EML 960.

In addition, the third emitting part 950 can further include at least one of a third EBL between the third HTL 952 and the third EML 960 and a third HBL between the third EML 960 and the third ETL 954.

For example, the HIL 912 can include the above hole injection material and can have a thickness of 1 nm to 20 nm, e.g., 5 nm to 15 nm.

Each of the first to third HTLs 914, 932 and 952 can include the above hole transporting material and can have a thickness of 30 nm to 60 nm, e.g., 40 nm to 50 nm.

Each of the first to third ETLs 916, 934 and 954 can include the above electron transporting material and can have a thickness of 10 nm to 50 nm, e.g., 20 nm to 40 nm.

The EIL 936 can include the above electron injection material and can have a thickness of 0.1 nm to 10 nm, e.g., 1 nm to 5 nm.

Each of the first to third EBLs can include the above electron blocking material and can have a thickness of 5 nm to 20 nm, e.g., 5 nm to 15 nm.

Each of the first to third HBLs can include the above hole blocking material and can have a thickness of 5 nm to 20 nm, e.g., 5 nm to 15 nm.

The first CGL 970 is positioned between the first and third emitting parts 910 and 950, and the second CGL 980 is positioned between the second and third emitting parts 930 and 950. Namely, the first and third emitting parts 910 and 950 can be connected to each other through the first CGL 970, and the second and third emitting parts 930 and 950 can be connected to each other through the second CGL 980. The first CGL 970 can be a P-N junction CGL of a first N-type CGL 972 and a first P-type CGL 974, and the second CGL 980 can be a P-N junction CGL of a second N-type CGL 982 and a second P-type CGL 984.

In the first CGL 970, the first N-type CGL 972 is positioned between the first ETL 916 and the third HTL 952, and the first P-type CGL 974 is positioned between the first N-type CGL 972 and the third HTL 952.

In the second CGL 980, the second N-type CGL 982 is positioned between the third ETL 954 and the second HTL 932, and the second P-type CGL 984 is positioned between the second N-type CGL 982 and the second HTL 932.

Each of the first and second N-type CGLs 972 and 982 can be an organic layer doped with an alkali metal, e.g., Li, Na, K and Cs, and/or an alkali earth metal, e.g., Mg, Sr, Ba and Ra. For example, each of the first and second N-type CGLs 972 and 982 can be formed of an N-type charge generation material including a host being the organic material, e.g., 4,7-dipheny-1,10-phenanthroline (Bphen) and MTDATA, and a dopant being an alkali metal and/or an alkali earth metal, and the dopant can be doped with a weight % of 0.01 to 30.

Each of the first and second P-type CGLs 974 and 984 can be formed of a P-type charge generation material including an inorganic material, e.g., tungsten oxide (WOₓ), molybdenum oxide (MoOₓ), beryllium oxide (Be₂O₃) or vanadium oxide (V₂O₅), an organic material, e.g., NPD, HAT-CN, F4TCNQ, TPD, TNB, TCTA, N,N′-dioctyl-3,4,9,10-perylenedicarboximide (PTCDI-C8) or their combination.

The first blue EML 920 can have a thickness in a range of 10 nm to 100 nm, e.g., 10 nm to 50 nm, preferably 20 nm to 40 nm.

The first blue EML 920 can include a first compound 922, a second compound 924 and a third compound 926. The first compound 922 can act as a first host, e.g., an n-type host, the second compound 924 can act as a second host, e.g., a p-type host, and the third compound 926 can act as a dopant.

The first compound 922 is represented by Formula 1 and can be one of the compounds in Formula 2. The second compound 924 is represented by Formula 3 and can be one of the compounds in Formula 4. The third compound 926 is represented by Formula 5 and can be one of the compounds in Formula 6.

In the first blue EML 920, a weight % of each of the first and second compounds 922 and 924 can be greater than that of the third compound 926. A weight % of the first compound 922 and a weight % of the second compound 924 can be same or different.

The first compound 922 can have a weight % of 25 to 50, the second compound 924 can have a weight % of 25 to 50, and the third compound 926 can have a weight % of 5 to 25. In an aspect of the present disclosure, a weight % of the first compound 922 and a weight % of the second compound 924 can be same, and the third compound 926 can have a weight % of 8, 12, 16 or 20.

In an aspect of the present disclosure, the first blue EML 920 can include a first compound 922, a second compound 924, a third compound 926 and a first fluorescent compound. The first compound 922 can act as a first host, e.g., an n-type host, and the second compound 924 can act as a second host, e.g., a p-type host. The third compound 926 can act as an auxiliary host or an auxiliary dopant, and the first fluorescent compound can act as a dopant.

The first compound 922 is represented by Formula 1 and can be one of the compounds in Formula 2. The second compound 924 is represented by Formula 3 and can be one of the compounds in Formula 4. The third compound 926 is represented by Formula 5 and can be one of the compounds in Formula 6. The first fluorescent compound is represented by Formula 7 and can be one of the compounds in Formula 8.

In the first blue EML 920, a weight % of each of the first and second compounds 922 and 924 can be greater than that of each of the third compound 926 and the first fluorescent compound. In addition, a weight % of the third compound 926 can be greater than that of the first fluorescent compound. A weight % of the first compound 922 and a weight % of the second compound 924 can be same or different.

The first compound 922 can have a weight % of 25 to 50, and the second compound 924 can have a weight % of 25 to 50. The third compound 926 can have a weight % of 5 to 25, and the first fluorescent compound can have a weight % of 0.1 to 3. In an aspect of the present disclosure, a weight % of the first compound 922 and a weight % of the second compound 924 can be same, the third compound 926 can have a weight % of 8, 12, 16 or 20, and the first fluorescent compound can have a weight % of 1.

The second blue EML 940 can have a thickness in a range of 10 nm to 100 nm, e.g., 10 nm to 50 nm, preferably 20 nm to 40 nm.

The second blue EML 940 can include a fourth compound 942, a fifth compound 944 and a sixth compound 946. The fourth compound 942 can act as a first host, e.g., an n-type host, the fifth compound 944 can act as a second host, e.g., a p-type host, and the sixth compound 946 can act as a dopant.

The fourth compound 942 is represented by Formula 1 and can be one of the compounds in Formula 2. The fifth compound 944 is represented by Formula 3 and can be one of the compounds in Formula 4. The sixth compound 946 is represented by Formula 5 and can be one of the compounds in Formula 6.

In the second blue EML 940, a weight % of each of the fourth and fifth compounds 942 and 944 can be greater than that of the sixth compound 946. A weight % of the fourth compound 942 and a weight % of the fifth compound 944 can be same or different.

The fourth compound 942 can have a weight % of 25 to 50, the fifth compound 944 can have a weight % of 25 to 50, and the sixth compound 946 can have a weight % of 5 to 25. In an aspect of the present disclosure, a weight % of the fourth compound 942 and a weight % of the fifth compound 944 can be same, and the sixth compound 946 can have a weight % of 8, 12, 16 or 20.

In an aspect of the present disclosure, the second blue EML 940 can include a fourth compound 942, a fifth compound 944, a sixth compound 946 and a second fluorescent compound. The fourth compound 942 can act as a first host, e.g., an n-type host, and the fifth compound 944 can act as a second host, e.g., a p-type host. The sixth compound 946 can act as an auxiliary host or an auxiliary dopant, and the second fluorescent compound can act as a dopant.

The fourth compound 942 is represented by Formula 1 and can be one of the compounds in Formula 2. The fifth compound 944 is represented by Formula 3 and can be one of the compounds in Formula 4. The sixth compound 946 is represented by Formula 5 and can be one of the compounds in Formula 6. The second fluorescent compound is represented by Formula 7 and can be one of the compounds in Formula 8.

In the second blue EML 940, a weight % of each of the fourth and fifth compounds 942 and 944 can be greater than that of each of the sixth compound 946 and the second fluorescent compound. In addition, a weight % of the sixth compound 946 can be greater than that of the second fluorescent compound. A weight % of the fourth compound 942 and a weight % of the fifth compound 944 can be same or different.

The fourth compound 942 can have a weight % of 25 to 50, and the fifth compound 944 can have a weight % of 25 to 50. The sixth compound 946 can have a weight % of 5 to 25, and the second fluorescent compound can have a weight % of 0.1 to 3. In an aspect of the present disclosure, a weight % of the fourth compound 942 and a weight % of the fifth compound 944 can be same, the sixth compound 946 can have a weight % of 8, 12, 16 or 20, and the second fluorescent compound can have a weight % of 1.

The first compound 922 in the first blue EML 920 and the fourth compound 942 in the second blue EML 940 can be same or different. The second compound 924 in the first blue EML 920 and the fifth compound 944 in the second blue EML 940 can be same or different. The third compound 926 in the first blue EML 920 and the sixth compound 946 in the second blue EML 940 can be same or different. The first fluorescent compound in the first blue EML 920 and the second fluorescent compound in the second blue EML 940 can be same or different.

A weight % of the first compound 922 in the first blue EML 920 and a weight % of the fourth compound 942 in the second blue EML 940 can be same or different. A weight % of the second compound 924 in the first blue EML 920 and a weight % of the fifth compound 944 in the second blue EML 940 can be same or different. A weight % of the third compound 926 in the first blue EML 920 and a weight % of the sixth compound 946 in the second blue EML 940 can be same or different. A weight % of the first fluorescent compound in the first blue EML 920 and a weight % of the second fluorescent compound in the second blue EML 940 can be same or different.

In FIG. 12, the first blue EML 920 includes the first compound 922 represented by Formula 1, the second compound 924 represented by Formula 3 and the third compound 926 represented by Formula 5 or includes the first compound 922 represented by Formula 1, the second compound 924 represented by Formula 3, the third compound 926 represented by Formula 5 and the first fluorescent compound represented by Formula 7, and the second blue EML 940 includes the fourth compound 942 represented by Formula 1, the fifth compound 944 represented by Formula 3 and the sixth compound 946 represented by Formula 5 or includes the fourth compound 942 represented by Formula 1, the fifth compound 944 represented by Formula 3, the sixth compound 946 represented by Formula 5 and the second fluorescent compound represented by Formula 7.

Alternatively, one of the first and second blue EMLs 920 and 940 can include the above blue host and the above blue dopant.

The organic light emitting layer 820 of the OLED D6 includes the first emitting part 910 including the first blue EML 920, the second emitting part 930 including the second blue EML 940 and the third emitting part 950 including the red, yellow-green and green EMLs 962, 964 and 966 so that the OLED D6 has a tandem structure.

In this case, the first blue EML 920 can include the first compound 922 represented by Formula 1, the second compound 924 represented by Formula 3 and the third compound 926 represented by Formula 5, and the second blue EML 940 can include the fourth compound 942 represented by Formula 1, the fifth compound 944 represented by Formula 3 and the sixth compound 946 represented by Formula 5.

In each of the first compound 922 and the fourth compound 942 represented by Formula 1, a difference between a singlet energy level and a triplet energy level can be 0.3 eV or less. As a result, each of the first compound 922 and the fourth compound 942 can have a delayed fluorescent property so that a non-emissive triplet exciton can be converted into a singlet exciton. Accordingly, the emitting efficiency of the OLED D6 and the organic light emitting display device 700 including the OLED D6 can be improved.

Since the first blue EML 920 includes the first compound 922 as an n-type host and the second compound 924 as a p-type host, the exciton generation efficiency in the first blue EML 920 and an exciton transfer efficiency into the third compound 926 can be improved. Since the second blue EML 940 includes the fourth compound 942 as an n-type host and the fifth compound 944 as a p-type host, the exciton generation efficiency in the second blue EML 940 and an exciton transfer efficiency into the sixth compound 946 can be improved. Accordingly, the emitting efficiency of the OLED D6, where the first blue EML 920 includes the first, second and third compounds 922, 924 and 926 and the second blue EML includes the fourth, fifth and sixth compounds 942, 944 and 946 and the organic light emitting display device 700 including the OLED D6 can be improved.

Moreover, since each of the first compound 922 and the fourth compound 942 represented by formula 1 includes a tetraarylsilane structure represented by Formula 1-1, a boron atom can be protected. Accordingly, the lifespan of the OLED D6 including the first compound 922 and the fourth compound 942 and the organic light emitting display device 700 including the OLED D6 can be improved.

Further, since a complex formation between the first compound 922 represented by formula 1 and the third compound 926 represented by formula 5 and a complex formation between the fourth compound 942 represented by formula 1 and the sixth compound 946 represented by formula 5 can be prevented by a tetraarylsilane structure, a concentration of the third compound 926 in the first blue EML 920 and a concentration of the sixth compound 946 in the second blue EML 940 can be increased. Accordingly, the emitting efficiency of the OLED D6 and the organic light emitting display device 700 including the OLED D6 can be further improved.

Furthermore, since the first compound 922 and the fourth compound 942 represented by Formula 1 has a LUMO energy level higher than the third compound 926 and the sixth compound 946, respectively, an electron trap in the first compound 922 and the fourth compound 942 can be suppressed. Accordingly, the driving voltage of the OLED D6 and the organic light emitting display device 700 including the OLED D6 can be reduced.

In an aspect of the present disclosure, the first blue EML 920 can include the first compound 922 represented by Formula 1, the second compound 924 represented by Formula 3, the third compound 926 represented by Formula 5 and the first fluorescent compound represented by Formula 7, and the second blue EML 940 can include the fourth compound 942 represented by Formula 1, the fifth compound 944 represented by Formula 3, the sixth compound 946 represented by Formula 5 and the second fluorescent compound represented by Formula 7.

In each of the first compound 922 and the fourth compound 942 represented by Formula 1 and the first and second fluorescent compounds represented by Formula 7, a difference between a singlet energy level and a triplet energy level can be 0.3 eV or less. As a result, each of the first compound 922 and the fourth compound 942 and the first and second fluorescent compounds can have a delayed fluorescent property so that a non-emissive triplet exciton can be converted into a singlet exciton. Accordingly, the emitting efficiency of the OLED D6 and the organic light emitting display device 700 including the OLED D6 can be improved.

Since the first blue EML 920 includes the first compound 922 as an n-type host and the second compound 924 as a p-type host, the exciton generation efficiency in the first blue EML 920 and an exciton transfer efficiency into the third compound 926 and/or the first fluorescent compound can be improved. In addition, since the second blue EML 940 includes the fourth compound 942 as an n-type host and the fifth compound 944 as a p-type host, the exciton generation efficiency in the second blue EML 940 and an exciton transfer efficiency into the sixth compound 946 and/or the second fluorescent compound can be improved. Accordingly, the emitting efficiency of the OLED D6 and the organic light emitting display device 700 including the OLED D6 can be improved.

Moreover, since each of the first and fourth compounds 922 and 942 represented by formula 1 includes a tetraarylsilane structure represented by Formula 1-1, a boron atom can be protected. Accordingly, the lifespan of the OLED D6 and the organic light emitting display device 700 including the OLED D6 can be improved.

Further, since a complex formation between the first compound 922 represented by formula 1 and the third compound 926 represented by formula 5 and a complex formation between the fourth compound 942 represented by formula 1 and the sixth compound 946 represented by formula 5 can be prevented by a tetraarylsilane structure, a concentration of the third compound 926 in the first blue EML 920 and a concentration of the sixth compound 946 in the second blue EML 940 can be increased. Accordingly, the emitting efficiency of the OLED D6 and the organic light emitting display device 700 including the OLED D6 can be further improved.

Furthermore, since the first and fourth compounds 922 and 942 represented by Formula 1 has a LUMO energy level higher than that of each of the third and sixth compounds 926 and 946 and the first and second fluorescent compounds, respectively, an electron trap in the first and fourth compounds 922 and 942 can be suppressed. Accordingly, the driving voltage of the OLED D6 and the organic light emitting display device 700 including the OLED D6 can be reduced.

It will be apparent to those skilled in the art that various modifications and variations can be made in the present disclosure without departing from the spirit or scope of the present disclosure. Thus, it is intended that the present disclosure cover the modifications and variations of this disclosure provided they come within the scope of the appended claims and their equivalents.

What is claimed is:

1. An organic light emitting diode, comprising:
a first electrode;
a second electrode facing the first electrode; and
a first blue emitting material layer including a first compound, a second compound and a third compound, and positioned between the first and second electrodes,
wherein the first compound is represented by Formula 1: 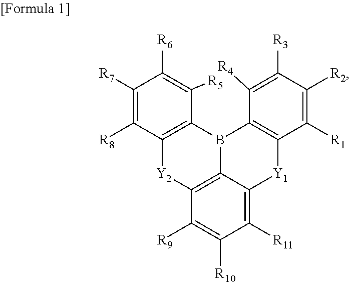
wherein in Formula 1,
at least one of R₁ to R₁₁ is represented by Formula 1-1, at least another one of R₁ to R₁₁ is represented by Formula 1-2,
each of the rest of R₁ to R₁₁ is independently selected from the group consisting of hydrogen, deuterium, halogen, cyano, a substituted or unsubstituted C1 to C20 alkyl group, a substituted or unsubstituted C3 to C30 cycloalkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group, or optionally, adjacent two of the rest of R₁ to R₁₁ are combined to form a ring,
each of Y₁ and Y₂ is independently selected from O or NR₁₂,
R₁₂ is selected from the group consisting of a substituted or unsubstituted C1 to C20 alkyl group, a substituted or unsubstituted C3 to C30 cycloalkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group, 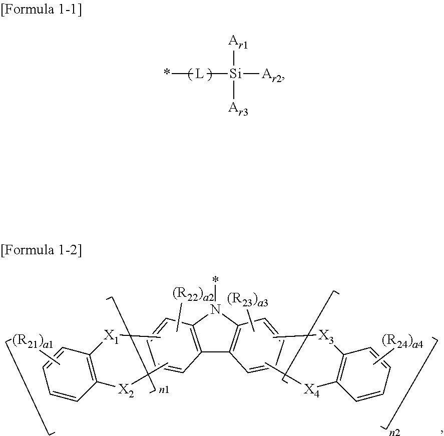
wherein in Formula 1-1,
L is selected from a substituted or unsubstituted C6 to C30 arylene group, and
each of Ar₁, Ar₂ and Ar₃ is independently selected from a substituted or unsubstituted C6 to C30 aryl group,
wherein in Formula 1-2,
each of a1 and a4 is independently an integer of 0 to 4, each of a2 and a3 is independently an integer of 0 to 2,
when a1 is 2 or more, two or more R₂₁ are same or different, when a2 is 2, two R₂₂ are same or different, when a3 is 2, two R₂₃ are same or different, when a4 is 2 or more, two or more R₂₄ are same or different,
each of R₂₁, R₂₂, R₂₃ and R₂₄ is independently selected from the group consisting of deuterium, halogen, cyano, a substituted or unsubstituted C1 to C20 alkyl group, a substituted or unsubstituted C3 to C30 cycloalkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group,
each of n1 and n2 is independently 0 or 1,
one of X₁ and X₂ is a single bond, the other one of X₁ and X₂ is selected from O, S, Se, NR₂₅ and C(R₂₅)₂, one of X₃ and X₄ is a single bond, the other one of X₃ and X₄ is selected from O, S, Se, NR₂₆ and C(R₂₆)₂, and
each of R₂₅ and R₂₆ is independently selected from the group consisting of hydrogen, deuterium, halogen, cyano, a substituted or unsubstituted C1 to C20 alkyl group, a substituted or unsubstituted C3 to C30 cycloalkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group, in each of Formulas 1-1 and 1-2, the mark “*” denotes a bonding site,
wherein the second compound is represented by Formula 3: 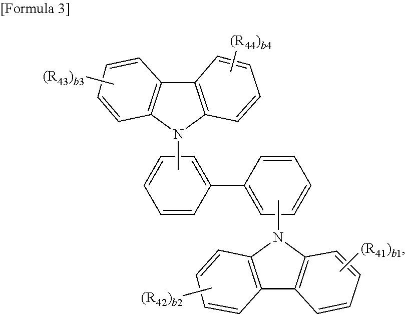
wherein in Formula 3, each of b1, b2, b3 and b4 is independently an integer of 0 to 4,
when b1 is 2 or more, two or more R₄₁ are same or different, when b2 is 2 or more, two or more R₄₂ are same or different, when b3 is 2 or more, two or more R₄₃ are same or different, when b4 is 2 or more, two or more R₄₄ are same or different, and
each of R₄₁ to R₄₄ is independently selected from the group consisting of deuterium, halogen, cyano, a substituted or unsubstituted C1 to C20 alkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group, and
wherein the third compound is represented by Formula 5: 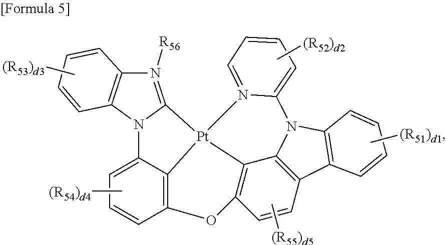
wherein in Formula 5,
each of d1, d2 and d3 is independently an integer of 0 to 4, d4 is an integer of 0 to 3, d5 is an integer of 0 to 2,
when d1 is 2 or more, two or more R₅₁ are same or different, when d2 is 2 or more, two or more R₅₂ are same or different, when d3 is 2 or more, two or more R₅₃ are same or different, when d4 is 2 or more, two or more R₅₄ are same or different, when d5 is 2, two R₅₅ are same or different,
each of R₅₁ to R₅₅ is independently selected from the group consisting of deuterium, halogen, cyano, a substituted or unsubstituted C1 to C20 alkyl group, a substituted or unsubstituted C3 to C30 cycloalkyl group, a substituted or unsubstituted C1 to C20 alkylsilyl group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, and
R₅₆ is selected from the group consisting of hydrogen, deuterium, halogen, cyano, a substituted or unsubstituted C1 to C20 alkyl group, a substituted or unsubstituted C3 to C30 cycloalkyl group, a substituted or unsubstituted C1 to C20 alkylsilyl group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group.

2. The organic light emitting diode according to claim 1, wherein Formula 1-1 is represented by Formula 1-1a: 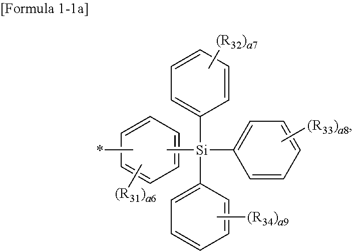
wherein in Formula 1-1a,
a6 is an integer of 0 to 4, each of a7, a8 and a9 is independently an integer of 0 to 5,
when a6 is 2 or more, two or more R₃₁ are same or different, when a7 is 2 or more, two or more R₃₂ are same or different, when a8 is 2 or more, two or more R₃₃ are same or different, when a9 is 2 or more, two or more R₃₄ are same or different, and
each of R₃₁, R₃₂, R₃₃ and R₃₄ is independently selected from the group consisting of deuterium, halogen, cyano, a substituted or unsubstituted C1 to C20 alkyl group, a substituted or unsubstituted C3 to C30 cycloalkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C6 to C30 aryl group and a substituted or unsubstituted C3 to C30 heteroaryl group.

3. The organic light emitting diode according to claim 1, wherein the first compound is one of compounds in Formula 2:

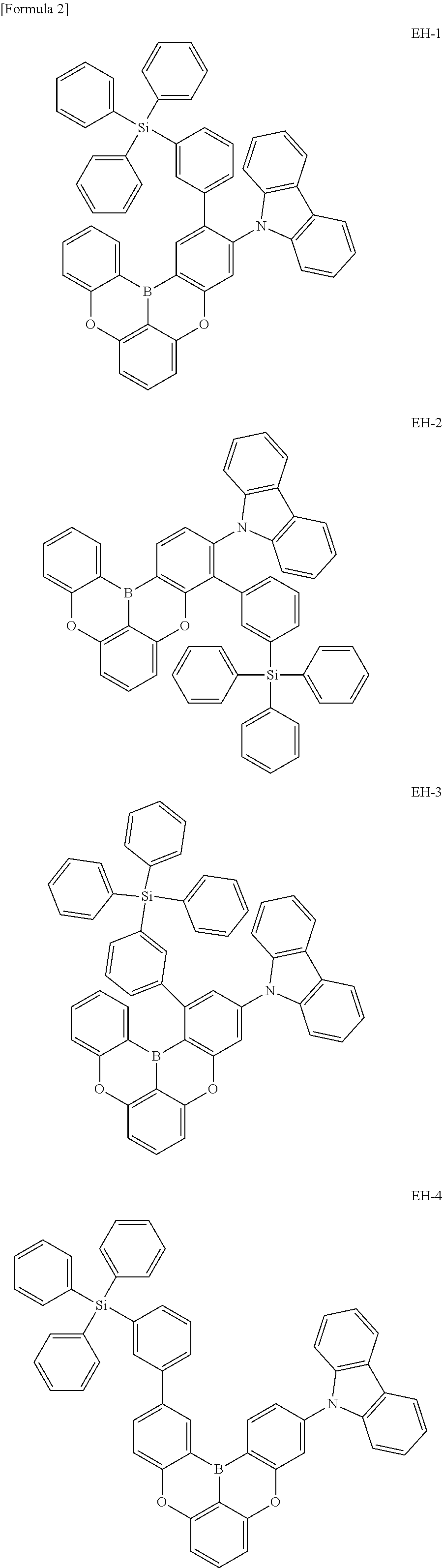 [SMILES: c1ccc([Si](c2ccccc2)(c2ccccc2)c2cccc(-c3cc4c(cc3-n3c5ccccc5c5ccccc53)Oc3cccc5c3B4c3ccccc3O5)c2)cc1 ; c1ccc([Si](c2ccccc2)(c2ccccc2)c2cccc(-c3c(-n4c5ccccc5c5ccccc54)ccc4c3Oc3cccc5c3B4c3ccccc3O5)c2)cc1 ; c1ccc([Si](c2ccccc2)(c2ccccc2)c2cccc(-c3cc(-n4c5ccccc5c5ccccc54)cc4c3B3c5ccccc5Oc5cccc(c53)O4)c2)cc1 ; c1ccc([Si](c2ccccc2)(c2ccccc2)c2cccc(-c3ccc4c(c3)B3c5ccc(-n6c7ccccc7c7ccccc76)cc5Oc5cccc(c53)O4)c2)cc1]

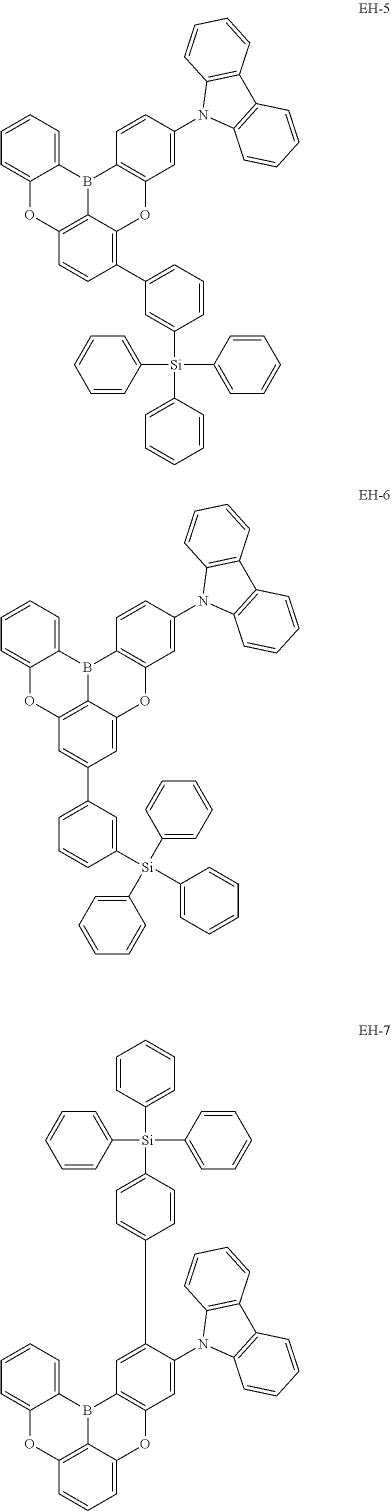 [SMILES: c1ccc([Si](c2ccccc2)(c2ccccc2)c2cccc(-c3ccc4c5c3Oc3cc(-n6c7ccccc7c7ccccc76)ccc3B5c3ccccc3O4)c2)cc1 ; c1ccc([Si](c2ccccc2)(c2ccccc2)c2cccc(-c3cc4c5c(c3)Oc3cc(-n6c7ccccc7c7ccccc76)ccc3B5c3ccccc3O4)c2)cc1 ; c1ccc([Si](c2ccccc2)(c2ccccc2)c2ccc(-c3cc4c(cc3-n3c5ccccc5c5ccccc53)Oc3cccc5c3B4c3ccccc3O5)cc2)cc1]

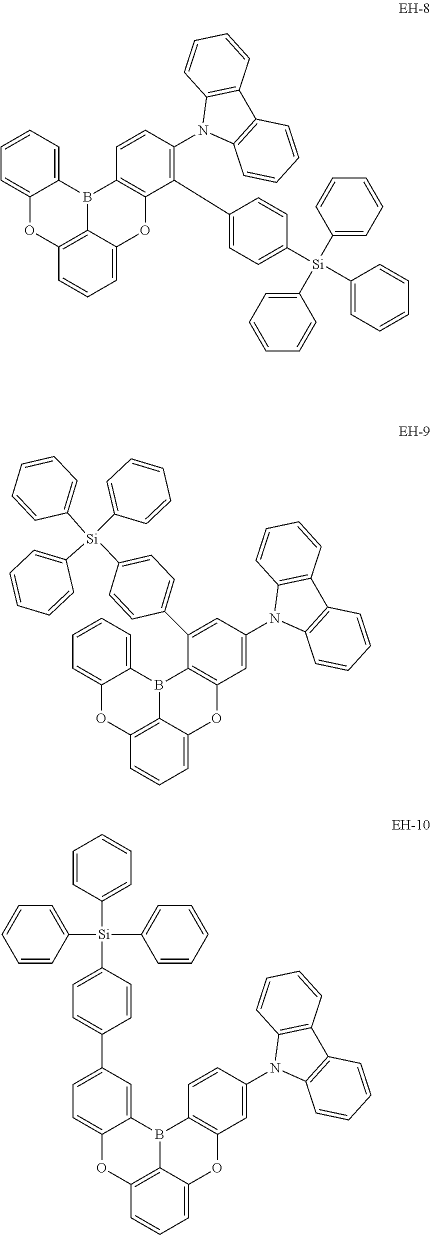 [SMILES: c1ccc([Si](c2ccccc2)(c2ccccc2)c2ccc(-c3c(-n4c5ccccc5c5ccccc54)ccc4c3Oc3cccc5c3B4c3ccccc3O5)cc2)cc1 ; c1ccc([Si](c2ccccc2)(c2ccccc2)c2ccc(-c3cc(-n4c5ccccc5c5ccccc54)cc4c3B3c5ccccc5Oc5cccc(c53)O4)cc2)cc1 ; c1ccc([Si](c2ccccc2)(c2ccccc2)c2ccc(-c3ccc4c(c3)B3c5ccc(-n6c7ccccc7c7ccccc76)cc5Oc5cccc(c53)O4)cc2)cc1]

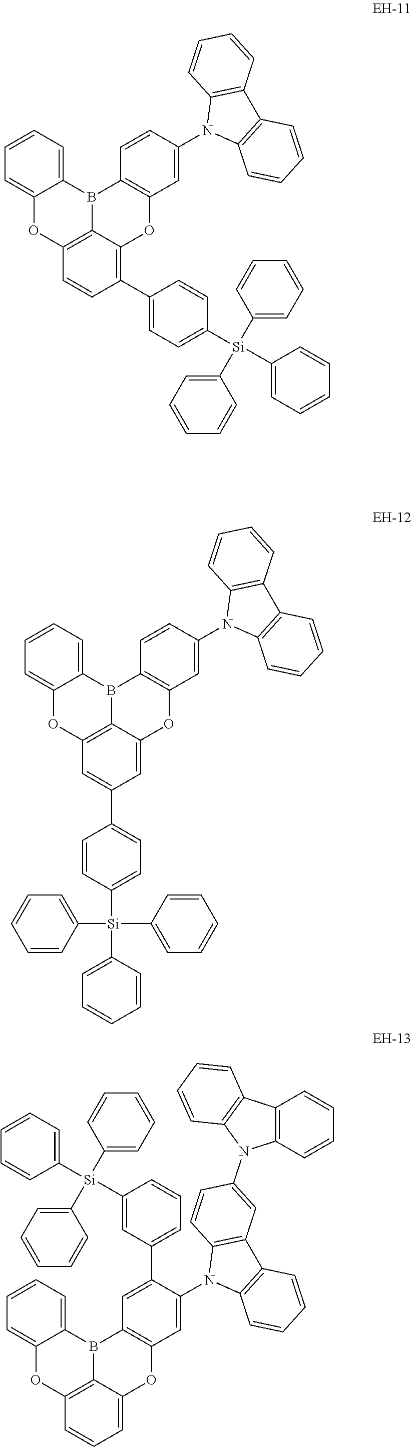 [SMILES: c1ccc([Si](c2ccccc2)(c2ccccc2)c2ccc(-c3ccc4c5c3Oc3cc(-n6c7ccccc7c7ccccc76)ccc3B5c3ccccc3O4)cc2)cc1 ; c1ccc([Si](c2ccccc2)(c2ccccc2)c2ccc(-c3cc4c5c(c3)Oc3cc(-n6c7ccccc7c7ccccc76)ccc3B5c3ccccc3O4)cc2)cc1 ; c1ccc([Si](c2ccccc2)(c2ccccc2)c2cccc(-c3cc4c(cc3-n3c5ccccc5c5cc(-n6c7ccccc7c7ccccc76)ccc53)Oc3cccc5c3B4c3ccccc3O5)c2)cc1]

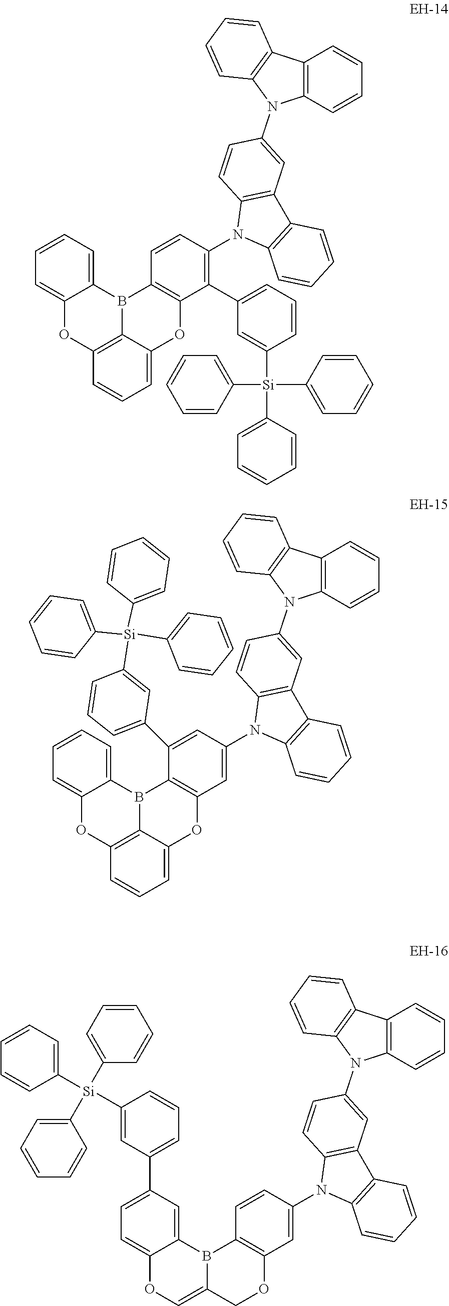

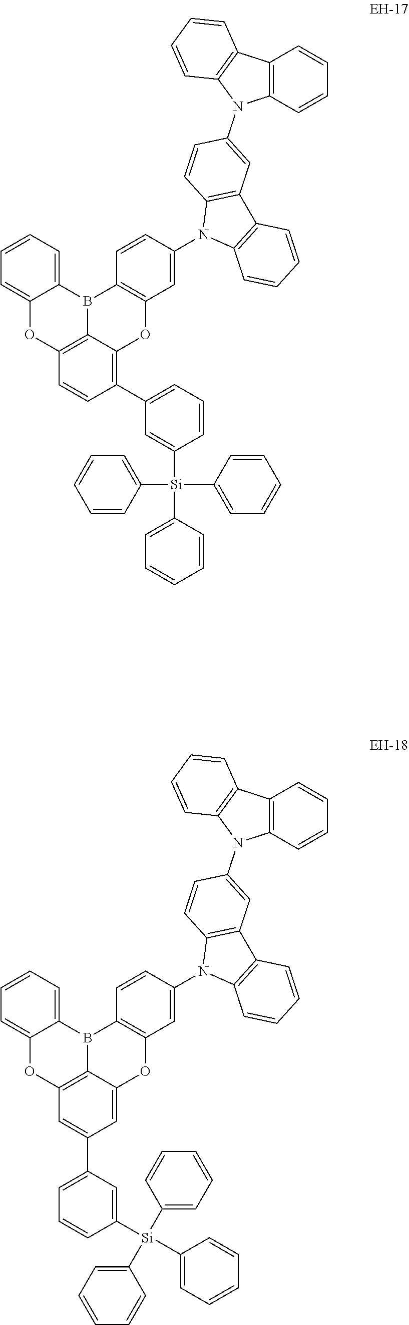 [SMILES: c1ccc([Si](c2ccccc2)(c2ccccc2)c2cccc(-c3ccc4c5c3Oc3cc(-n6c7ccccc7c7cc(-n8c9ccccc9c9ccccc98)ccc76)ccc3B5c3ccccc3O4)c2)cc1 ; c1ccc([Si](c2ccccc2)(c2ccccc2)c2cccc(-c3cc4c5c(c3)Oc3cc(-n6c7ccccc7c7cc(-n8c9ccccc9c9ccccc98)ccc76)ccc3B5c3ccccc3O4)c2)cc1]

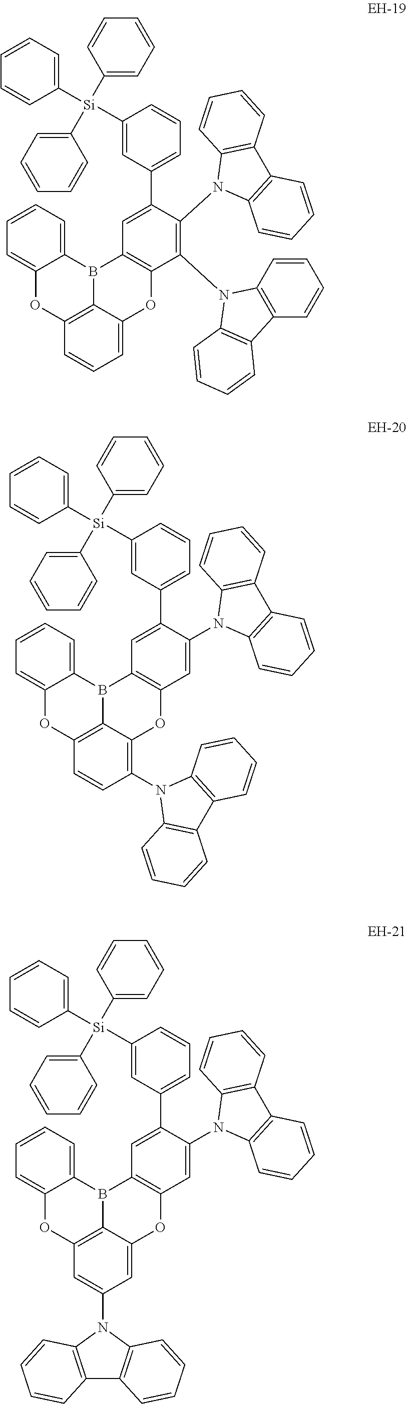 [SMILES: c1ccc([Si](c2ccccc2)(c2ccccc2)c2cccc(-c3cc4c(c(-n5c6ccccc6c6ccccc65)c3-n3c5ccccc5c5ccccc53)Oc3cccc5c3B4c3ccccc3O5)c2)cc1 ; c1ccc([Si](c2ccccc2)(c2ccccc2)c2cccc(-c3cc4c(cc3-n3c5ccccc5c5ccccc53)Oc3c(-n5c6ccccc6c6ccccc65)ccc5c3B4c3ccccc3O5)c2)cc1 ; c1ccc([Si](c2ccccc2)(c2ccccc2)c2cccc(-c3cc4c(cc3-n3c5ccccc5c5ccccc53)Oc3cc(-n5c6ccccc6c6ccccc65)cc5c3B4c3ccccc3O5)c2)cc1]

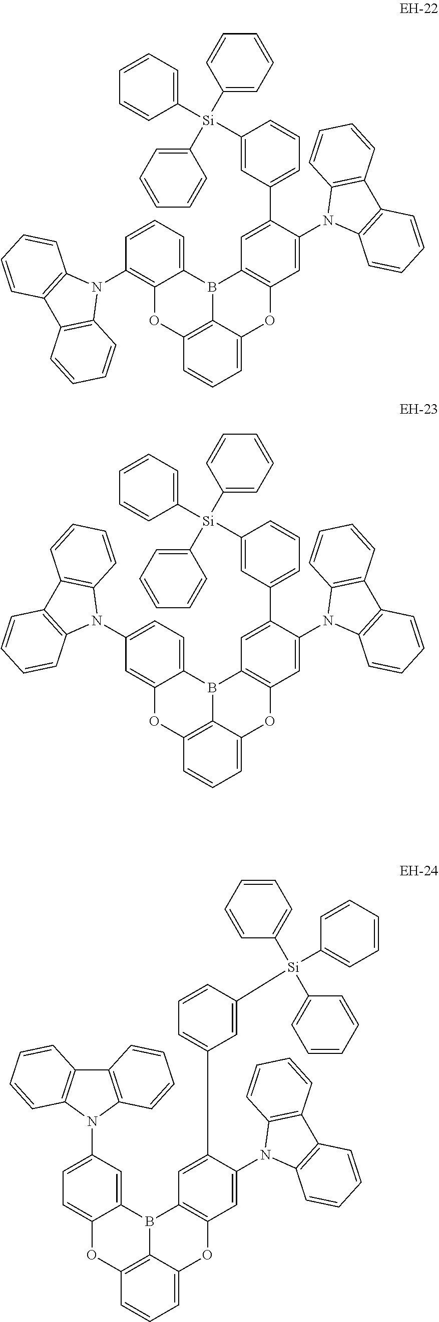 [SMILES: c1ccc([Si](c2ccccc2)(c2ccccc2)c2cccc(-c3cc4c(cc3-n3c5ccccc5c5ccccc53)Oc3cccc5c3B4c3cccc(-n4c6ccccc6c6ccccc64)c3O5)c2)cc1 ; c1ccc([Si](c2ccccc2)(c2ccccc2)c2cccc(-c3cc4c(cc3-n3c5ccccc5c5ccccc53)Oc3cccc5c3B4c3ccc(-n4c6ccccc6c6ccccc64)cc3O5)c2)cc1 ; c1ccc([Si](c2ccccc2)(c2ccccc2)c2cccc(-c3cc4c(cc3-n3c5ccccc5c5ccccc53)Oc3cccc5c3B4c3cc(-n4c6ccccc6c6ccccc64)ccc3O5)c2)cc1]

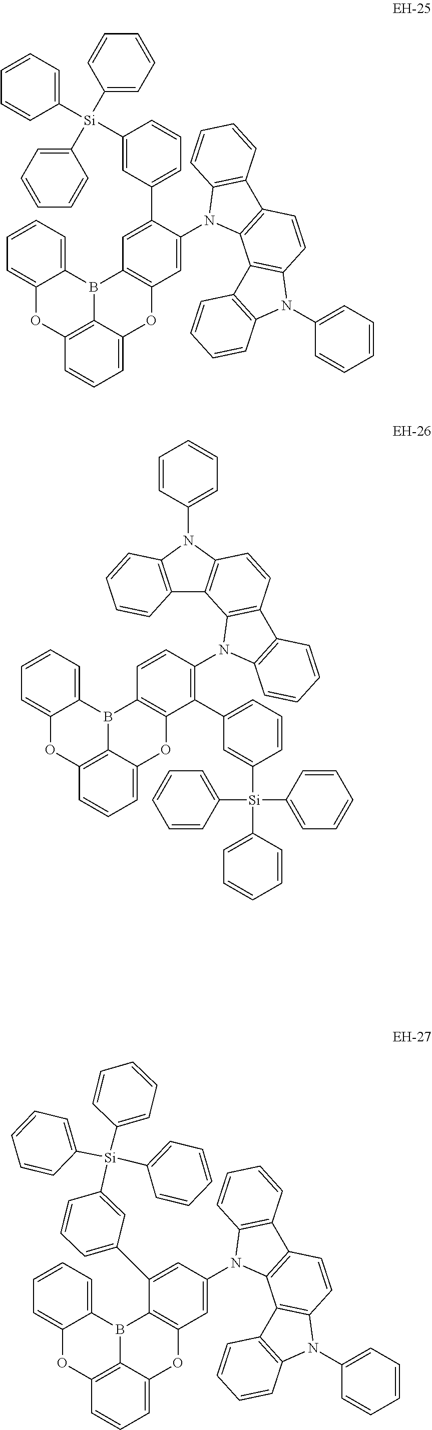 [SMILES: c1ccc(-n2c3ccccc3c3c2ccc2c4ccccc4n(-c4cc5c(cc4-c4cccc([Si](c6ccccc6)(c6ccccc6)c6ccccc6)c4)B4c6ccccc6Oc6cccc(c64)O5)c23)cc1 ; c1ccc(-n2c3ccccc3c3c2ccc2c4ccccc4n(-c4ccc5c(c4-c4cccc([Si](c6ccccc6)(c6ccccc6)c6ccccc6)c4)Oc4cccc6c4B5c4ccccc4O6)c23)cc1 ; c1ccc(-n2c3ccccc3c3c2ccc2c4ccccc4n(-c4cc5c(c(-c6cccc([Si](c7ccccc7)(c7ccccc7)c7ccccc7)c6)c4)B4c6ccccc6Oc6cccc(c64)O5)c23)cc1]

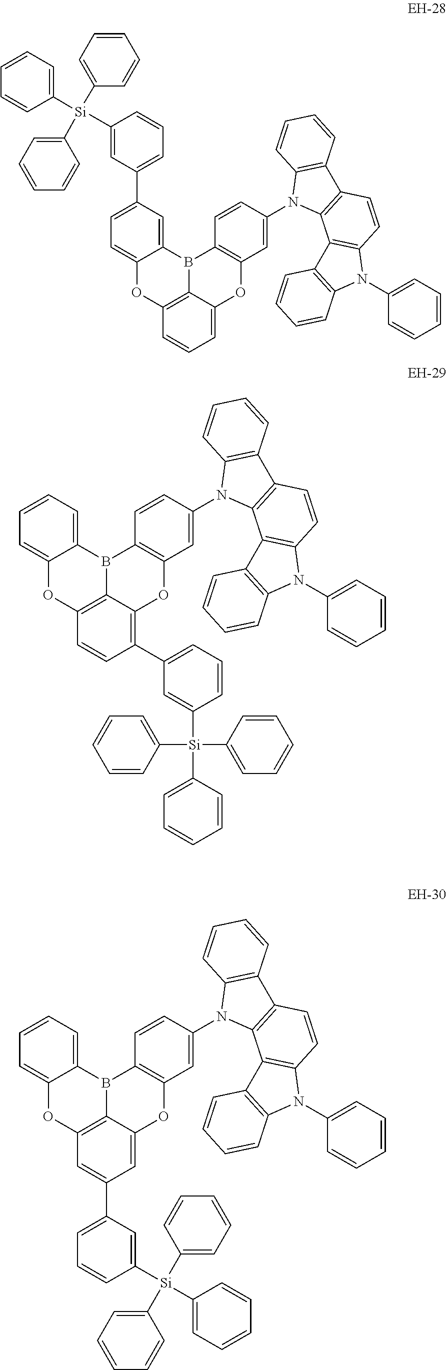 [SMILES: c1ccc(-n2c3ccccc3c3c2ccc2c4ccccc4n(-c4ccc5c(c4)Oc4cccc6c4B5c4cc(-c5cccc([Si](c7ccccc7)(c7ccccc7)c7ccccc7)c5)ccc4O6)c23)cc1 ; c1ccc(-n2c3ccccc3c3c2ccc2c4ccccc4n(-c4ccc5c(c4)Oc4c(-c6cccc([Si](c7ccccc7)(c7ccccc7)c7ccccc7)c6)ccc6c4B5c4ccccc4O6)c23)cc1 ; c1ccc(-n2c3ccccc3c3c2ccc2c4ccccc4n(-c4ccc5c(c4)Oc4cc(-c6cccc([Si](c7ccccc7)(c7ccccc7)c7ccccc7)c6)cc6c4B5c4ccccc4O6)c23)cc1]

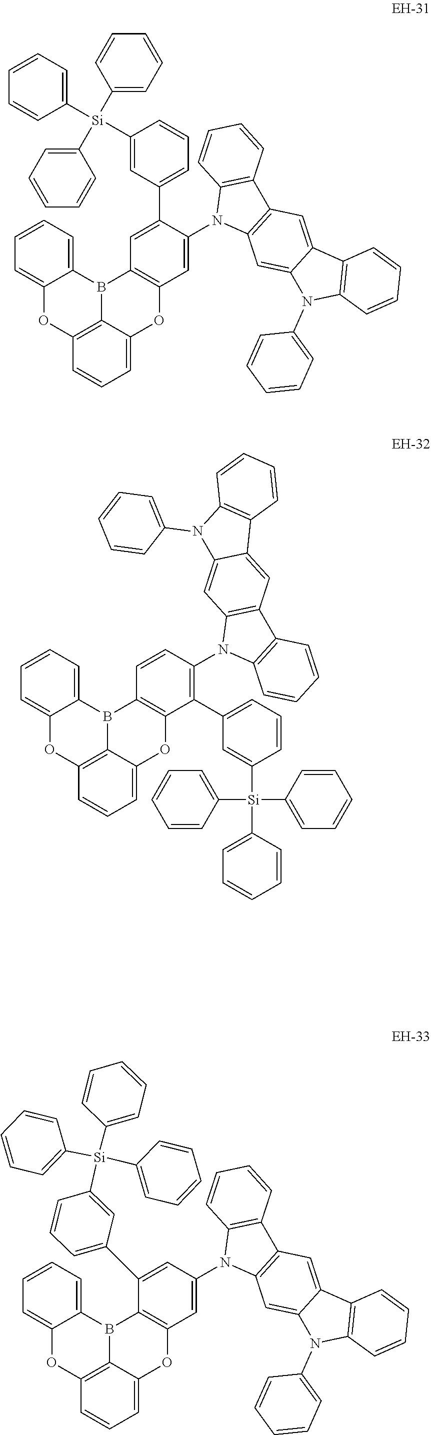 [SMILES: c1ccc(-n2c3ccccc3c3cc4c5ccccc5n(-c5cc6c(cc5-c5cccc([Si](c7ccccc7)(c7ccccc7)c7ccccc7)c5)B5c7ccccc7Oc7cccc(c75)O6)c4cc32)cc1 ; c1ccc(-n2c3ccccc3c3cc4c5ccccc5n(-c5ccc6c(c5-c5cccc([Si](c7ccccc7)(c7ccccc7)c7ccccc7)c5)Oc5cccc7c5B6c5ccccc5O7)c4cc32)cc1 ; c1ccc(-n2c3ccccc3c3cc4c5ccccc5n(-c5cc6c(c(-c7cccc([Si](c8ccccc8)(c8ccccc8)c8ccccc8)c7)c5)B5c7ccccc7Oc7cccc(c75)O6)c4cc32)cc1]

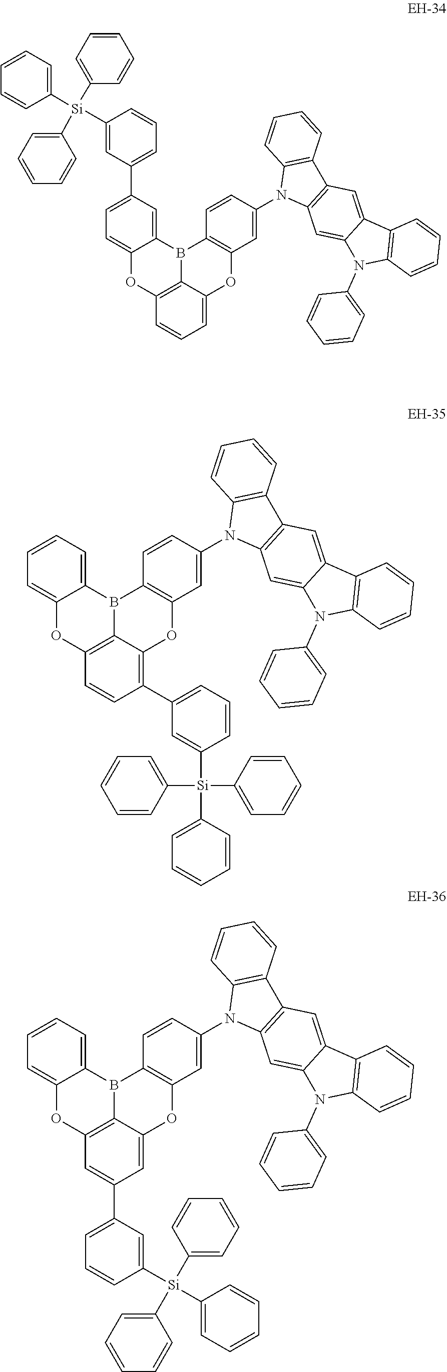 [SMILES: c1ccc(-n2c3ccccc3c3cc4c5ccccc5n(-c5ccc6c(c5)Oc5cccc7c5B6c5cc(-c6cccc([Si](c8ccccc8)(c8ccccc8)c8ccccc8)c6)ccc5O7)c4cc32)cc1 ; c1ccc(-n2c3ccccc3c3cc4c5ccccc5n(-c5ccc6c(c5)Oc5c(-c7cccc([Si](c8ccccc8)(c8ccccc8)c8ccccc8)c7)ccc7c5B6c5ccccc5O7)c4cc32)cc1 ; c1ccc(-n2c3ccccc3c3cc4c5ccccc5n(-c5ccc6c(c5)Oc5cc(-c7cccc([Si](c8ccccc8)(c8ccccc8)c8ccccc8)c7)cc7c5B6c5ccccc5O7)c4cc32)cc1]

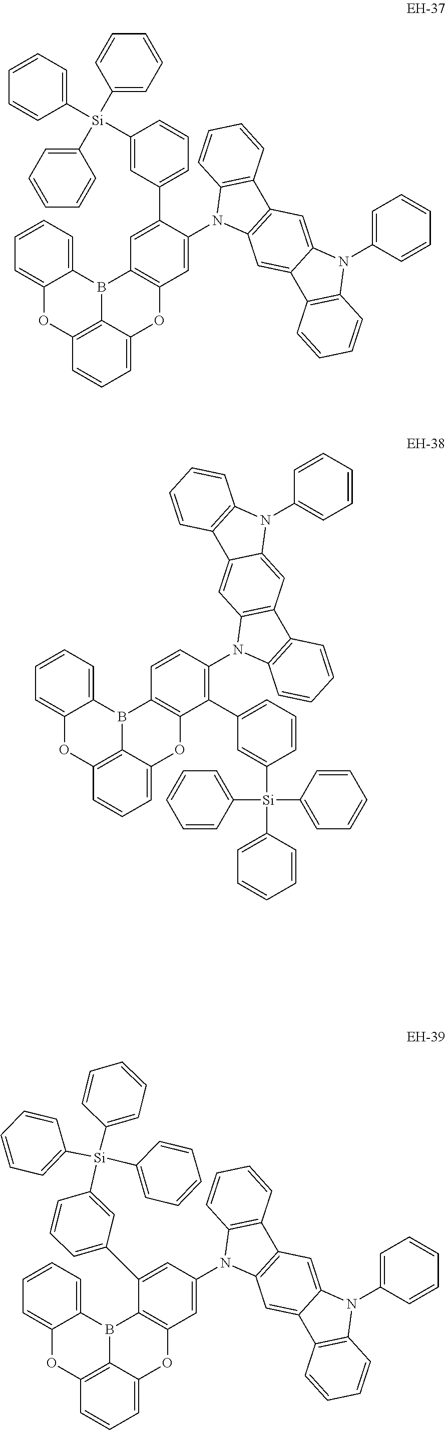 [SMILES: c1ccc(-n2c3ccccc3c3cc4c(cc32)c2ccccc2n4-c2cc3c(cc2-c2cccc([Si](c4ccccc4)(c4ccccc4)c4ccccc4)c2)B2c4ccccc4Oc4cccc(c42)O3)cc1 ; c1ccc(-n2c3ccccc3c3cc4c(cc32)c2ccccc2n4-c2ccc3c(c2-c2cccc([Si](c4ccccc4)(c4ccccc4)c4ccccc4)c2)Oc2cccc4c2B3c2ccccc2O4)cc1 ; c1ccc(-n2c3ccccc3c3cc4c(cc32)c2ccccc2n4-c2cc3c(c(-c4cccc([Si](c5ccccc5)(c5ccccc5)c5ccccc5)c4)c2)B2c4ccccc4Oc4cccc(c42)O3)cc1]

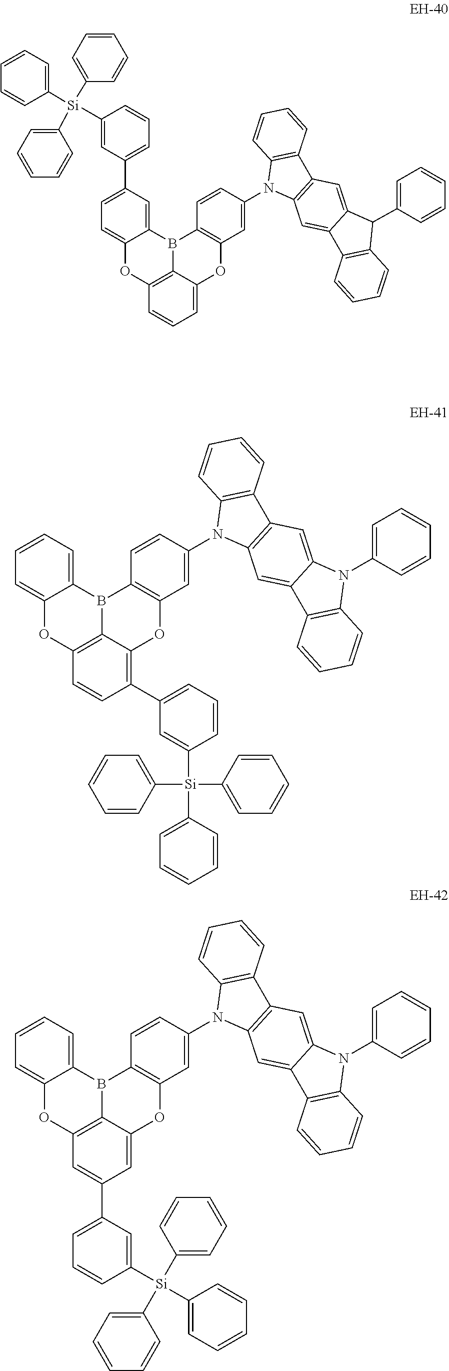 [SMILES: c1ccc(C2c3ccccc3-c3cc4c(cc32)c2ccccc2n4-c2ccc3c(c2)Oc2cccc4c2B3c2cc(-c3cccc([Si](c5ccccc5)(c5ccccc5)c5ccccc5)c3)ccc2O4)cc1 ; c1ccc(-n2c3ccccc3c3cc4c(cc32)c2ccccc2n4-c2ccc3c(c2)Oc2c(-c4cccc([Si](c5ccccc5)(c5ccccc5)c5ccccc5)c4)ccc4c2B3c2ccccc2O4)cc1 ; c1ccc(-n2c3ccccc3c3cc4c(cc32)c2ccccc2n4-c2ccc3c(c2)Oc2cc(-c4cccc([Si](c5ccccc5)(c5ccccc5)c5ccccc5)c4)cc4c2B3c2ccccc2O4)cc1]

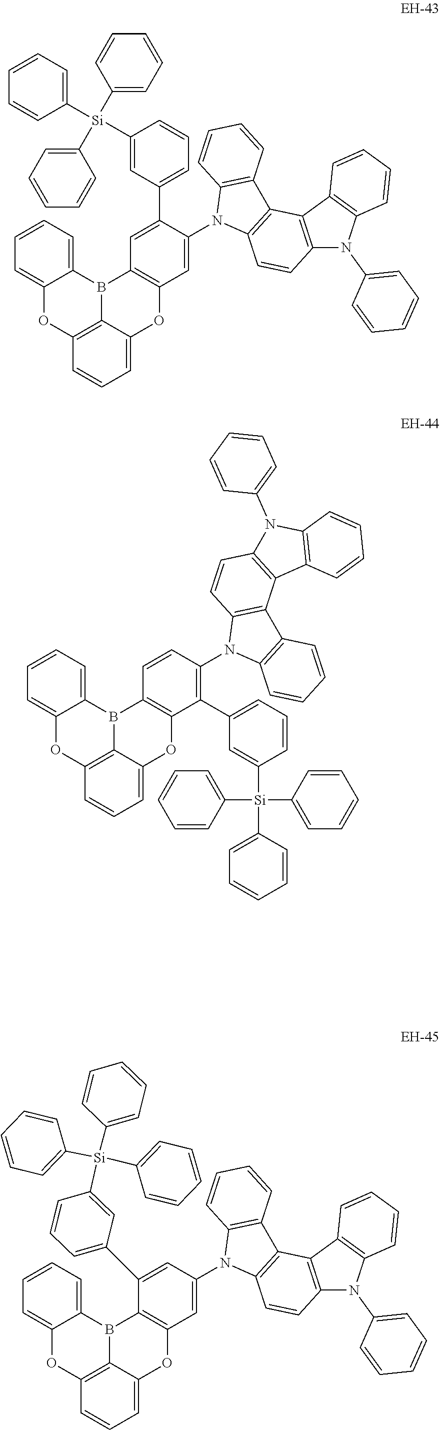 [SMILES: c1ccc(-n2c3ccccc3c3c4c5ccccc5n(-c5cc6c(cc5-c5cccc([Si](c7ccccc7)(c7ccccc7)c7ccccc7)c5)B5c7ccccc7Oc7cccc(c75)O6)c4ccc32)cc1 ; c1ccc(-n2c3ccccc3c3c4c5ccccc5n(-c5ccc6c(c5-c5cccc([Si](c7ccccc7)(c7ccccc7)c7ccccc7)c5)Oc5cccc7c5B6c5ccccc5O7)c4ccc32)cc1 ; c1ccc(-n2c3ccccc3c3c4c5ccccc5n(-c5cc6c(c(-c7cccc([Si](c8ccccc8)(c8ccccc8)c8ccccc8)c7)c5)B5c7ccccc7Oc7cccc(c75)O6)c4ccc32)cc1]

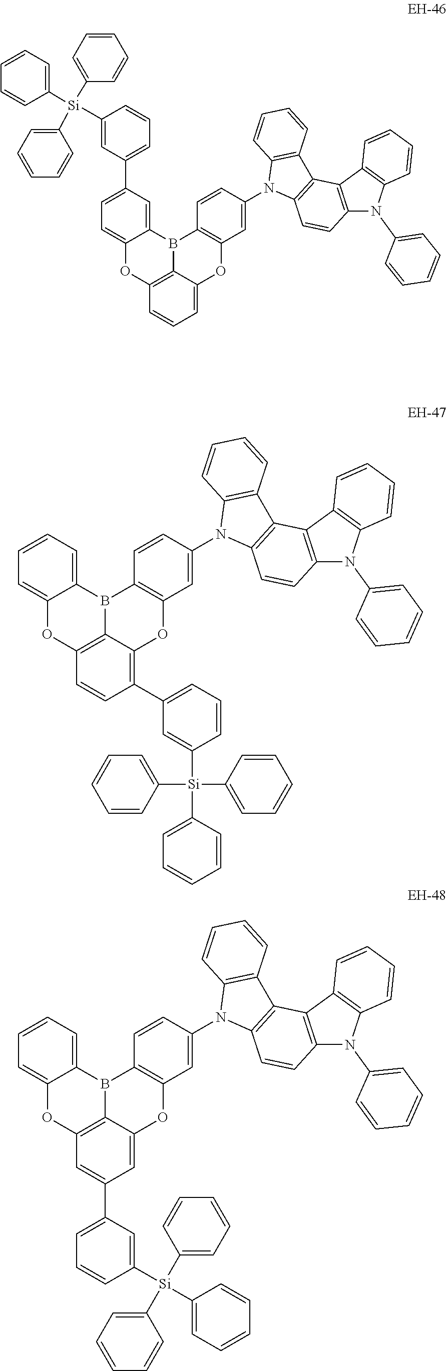 [SMILES: c1ccc(-n2c3ccccc3c3c4c5ccccc5n(-c5ccc6c(c5)Oc5cccc7c5B6c5cc(-c6cccc([Si](c8ccccc8)(c8ccccc8)c8ccccc8)c6)ccc5O7)c4ccc32)cc1 ; c1ccc(-n2c3ccccc3c3c4c5ccccc5n(-c5ccc6c(c5)Oc5c(-c7cccc([Si](c8ccccc8)(c8ccccc8)c8ccccc8)c7)ccc7c5B6c5ccccc5O7)c4ccc32)cc1 ; c1ccc(-n2c3ccccc3c3c4c5ccccc5n(-c5ccc6c(c5)Oc5cc(-c7cccc([Si](c8ccccc8)(c8ccccc8)c8ccccc8)c7)cc7c5B6c5ccccc5O7)c4ccc32)cc1]

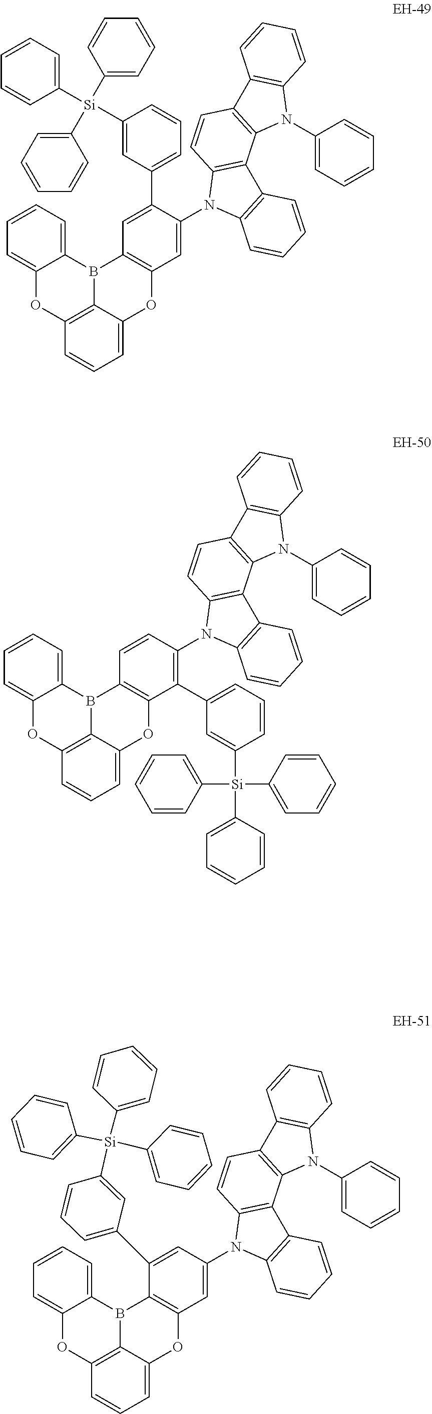 [SMILES: c1ccc(-n2c3ccccc3c3ccc4c(c5ccccc5n4-c4cc5c(cc4-c4cccc([Si](c6ccccc6)(c6ccccc6)c6ccccc6)c4)B4c6ccccc6Oc6cccc(c64)O5)c32)cc1 ; c1ccc(-n2c3ccccc3c3ccc4c(c5ccccc5n4-c4ccc5c(c4-c4cccc([Si](c6ccccc6)(c6ccccc6)c6ccccc6)c4)Oc4cccc6c4B5c4ccccc4O6)c32)cc1 ; c1ccc(-n2c3ccccc3c3ccc4c(c5ccccc5n4-c4cc5c(c(-c6cccc([Si](c7ccccc7)(c7ccccc7)c7ccccc7)c6)c4)B4c6ccccc6Oc6cccc(c64)O5)c32)cc1]

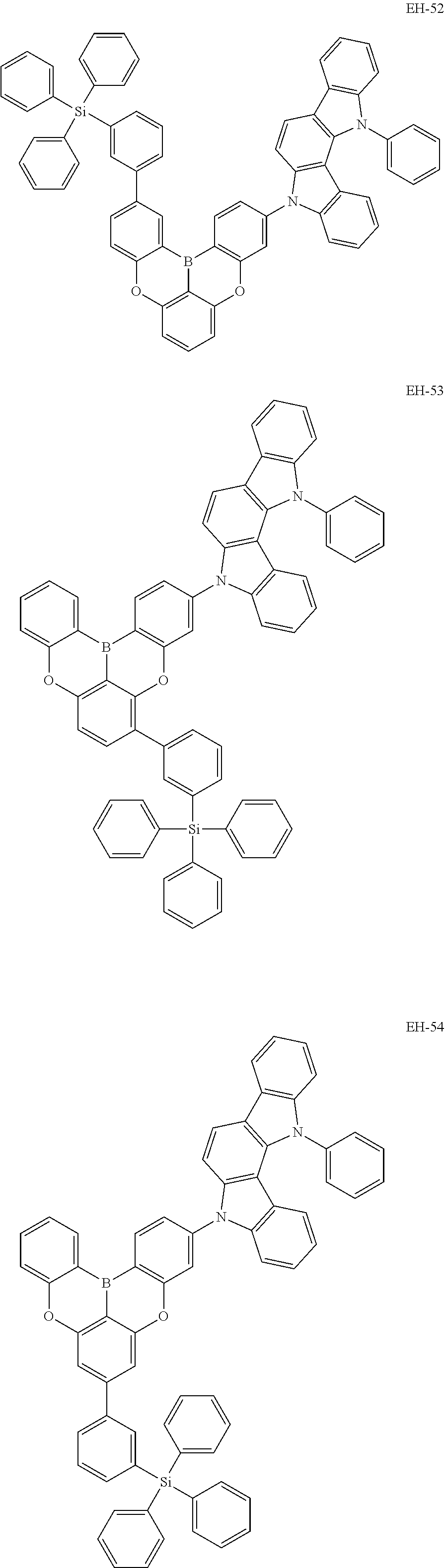 [SMILES: c1ccc(-n2c3ccccc3c3ccc4c(c5ccccc5n4-c4ccc5c(c4)Oc4cccc6c4B5c4cc(-c5cccc([Si](c7ccccc7)(c7ccccc7)c7ccccc7)c5)ccc4O6)c32)cc1 ; c1ccc(-n2c3ccccc3c3ccc4c(c5ccccc5n4-c4ccc5c(c4)Oc4c(-c6cccc([Si](c7ccccc7)(c7ccccc7)c7ccccc7)c6)ccc6c4B5c4ccccc4O6)c32)cc1 ; c1ccc(-n2c3ccccc3c3ccc4c(c5ccccc5n4-c4ccc5c(c4)Oc4cc(-c6cccc([Si](c7ccccc7)(c7ccccc7)c7ccccc7)c6)cc6c4B5c4ccccc4O6)c32)cc1]

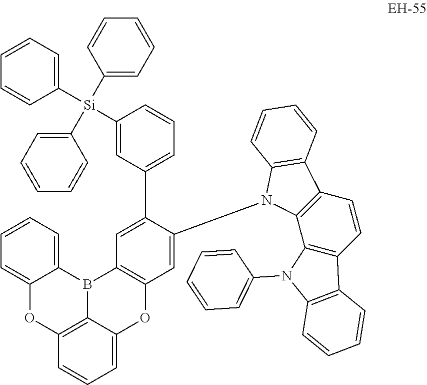 [SMILES: c1ccc(-n2c3ccccc3c3ccc4c5ccccc5n(-c5cc6c(cc5-c5cccc([Si](c7ccccc7)(c7ccccc7)c7ccccc7)c5)B5c7ccccc7Oc7cccc(c75)O6)c4c32)cc1]

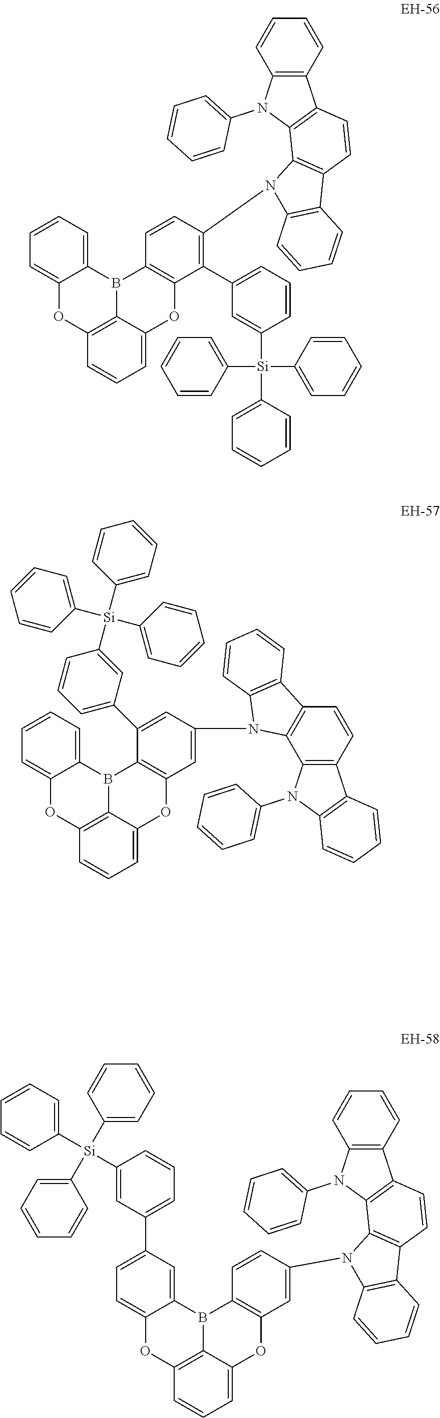 [SMILES: c1ccc(-n2c3ccccc3c3ccc4c5ccccc5n(-c5ccc6c(c5-c5cccc([Si](c7ccccc7)(c7ccccc7)c7ccccc7)c5)Oc5cccc7c5B6c5ccccc5O7)c4c32)cc1 ; c1ccc(-n2c3ccccc3c3ccc4c5ccccc5n(-c5cc6c(c(-c7cccc([Si](c8ccccc8)(c8ccccc8)c8ccccc8)c7)c5)B5c7ccccc7Oc7cccc(c75)O6)c4c32)cc1 ; c1ccc(-n2c3ccccc3c3ccc4c5ccccc5n(-c5ccc6c(c5)Oc5cccc7c5B6c5cc(-c6cccc([Si](c8ccccc8)(c8ccccc8)c8ccccc8)c6)ccc5O7)c4c32)cc1]

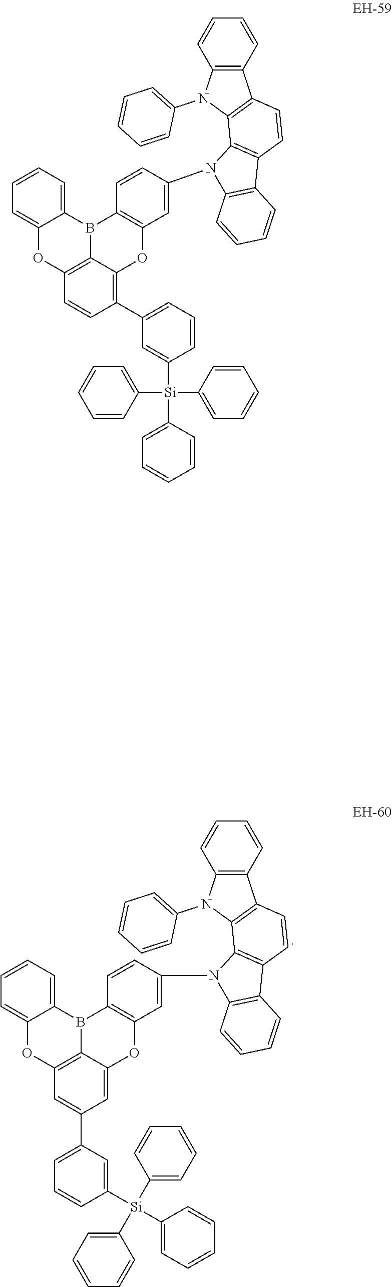 [SMILES: c1ccc(-n2c3ccccc3c3ccc4c5ccccc5n(-c5ccc6c(c5)Oc5c(-c7cccc([Si](c8ccccc8)(c8ccccc8)c8ccccc8)c7)ccc7c5B6c5ccccc5O7)c4c32)cc1 ; c1ccc(-n2c3ccccc3c3ccc4c5ccccc5n(-c5ccc6c(c5)Oc5cc(-c7cccc([Si](c8ccccc8)(c8ccccc8)c8ccccc8)c7)cc7c5B6c5ccccc5O7)c4c32)cc1]

4. The organic light emitting diode according to claim 1, wherein the second compound is one of compounds in Formula 4:

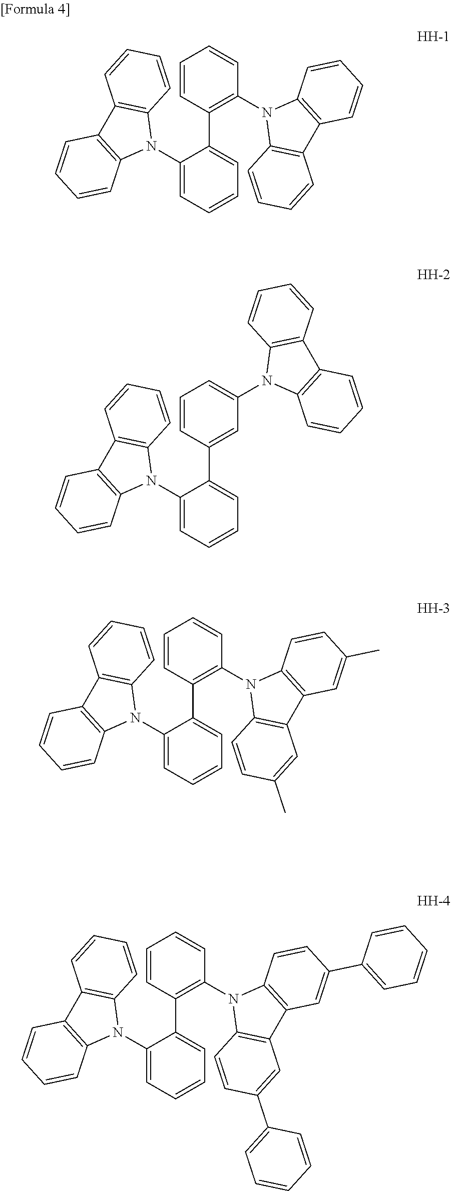 [SMILES: c1ccc(-n2c3ccccc3c3ccccc32)c(-c2ccccc2-n2c3ccccc3c3ccccc32)c1 ; c1cc(-c2ccccc2-n2c3ccccc3c3ccccc32)cc(-n2c3ccccc3c3ccccc32)c1 ; Cc1ccc2c(c1)c1cc(C)ccc1n2-c1ccccc1-c1ccccc1-n1c2ccccc2c2ccccc21 ; c1ccc(-c2ccc3c(c2)c2cc(-c4ccccc4)ccc2n3-c2ccccc2-c2ccccc2-n2c3ccccc3c3ccccc32)cc1]

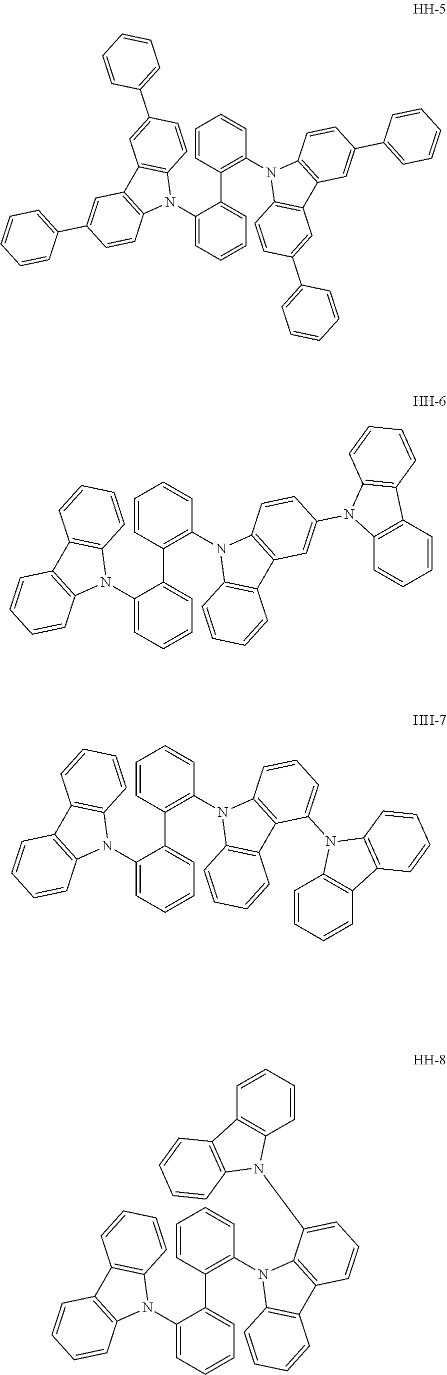 [SMILES: c1ccc(-c2ccc3c(c2)c2cc(-c4ccccc4)ccc2n3-c2ccccc2-c2ccccc2-n2c3ccc(-c4ccccc4)cc3c3cc(-c4ccccc4)ccc32)cc1 ; c1ccc(-n2c3ccccc3c3ccccc32)c(-c2ccccc2-n2c3ccccc3c3cc(-n4c5ccccc5c5ccccc54)ccc32)c1 ; c1ccc(-n2c3ccccc3c3ccccc32)c(-c2ccccc2-n2c3ccccc3c3c(-n4c5ccccc5c5ccccc54)cccc32)c1 ; c1ccc(-n2c3ccccc3c3ccccc32)c(-c2ccccc2-n2c3ccccc3c3cccc(-n4c5ccccc5c5ccccc54)c32)c1]

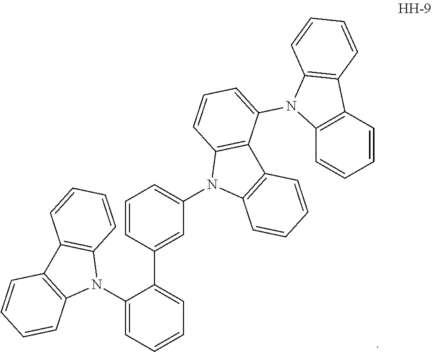 [SMILES: c1cc(-c2ccccc2-n2c3ccccc3c3ccccc32)cc(-n2c3ccccc3c3c(-n4c5ccccc5c5ccccc54)cccc32)c1]

5. The organic light emitting diode according to claim 1, wherein the third compound is one of compounds in Formula 6:

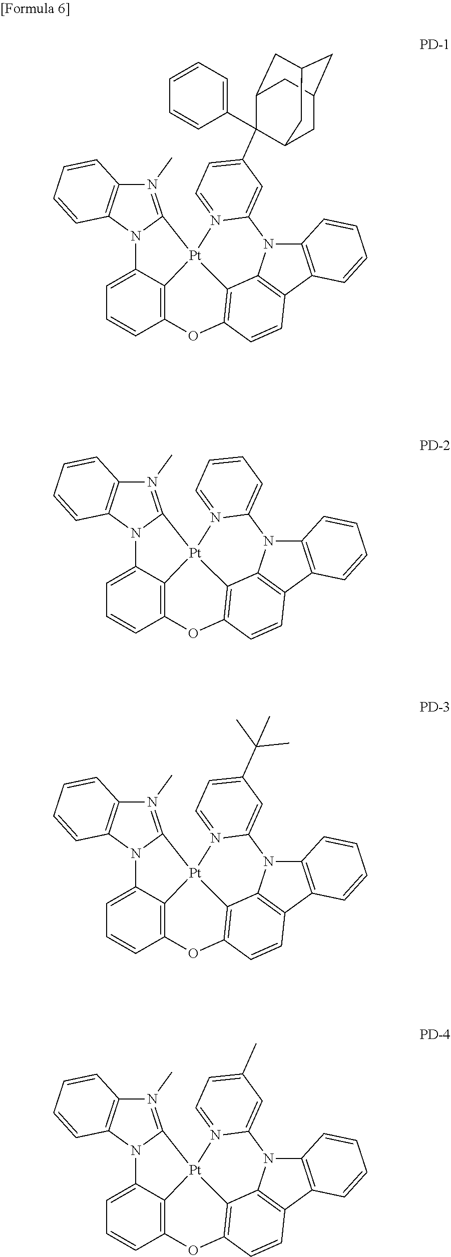

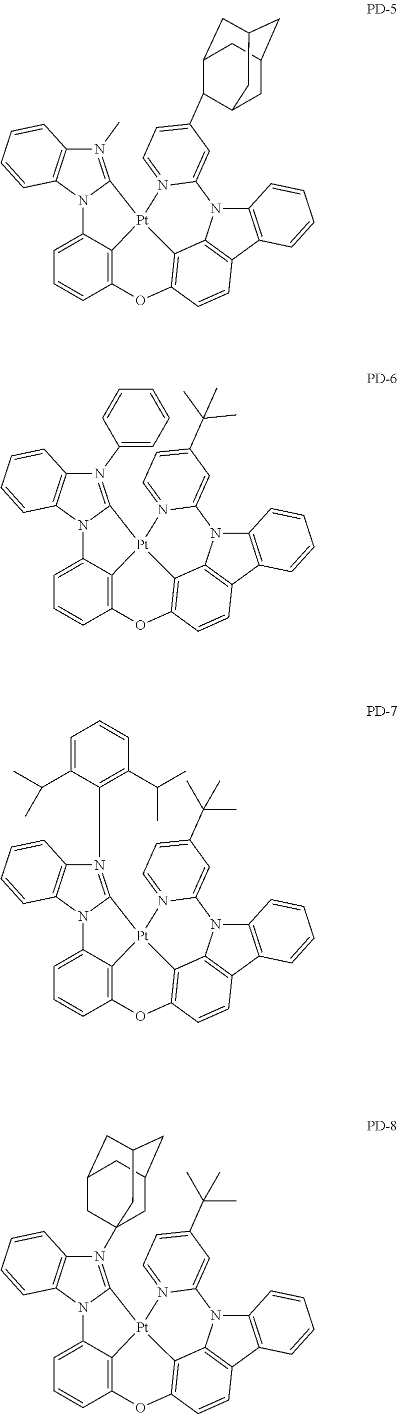

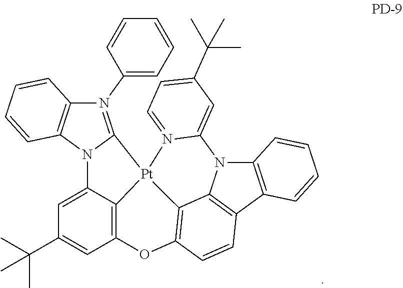

6. The organic light emitting diode according to claim 1, wherein a lowest unoccupied molecular orbital (LUMO) energy level of the first compound is lower than a LUMO energy level of the second compound and is higher than a LUMO energy level of the third compound, and
wherein a difference between the LUMO energy level of the first compound and the LUMO energy level of the third compound is smaller than a difference between the LUMO energy level of the first compound and the LUMO energy level of the second compound.

7. The organic light emitting diode according to claim 6, wherein a difference between a HOMO energy level of the first compound and a HOMO energy level of the third compound is 0.1 eV or more and 0.3 eV or less.

8. The organic light emitting diode according to claim 7, wherein the HOMO energy level of the first compound is higher than a HOMO energy level of the second compound and is lower than the HOMO energy level of the third compound, and
wherein a difference between the HOMO energy level of the first compound and the HOMO energy level of the third compound is smaller than a difference between the HOMO energy level of the first compound and the HOMO energy level of the second compound.

9. The organic light emitting diode according to claim 1, wherein the first blue emitting material layer further includes a first fluorescent compound represented by Formula 7: 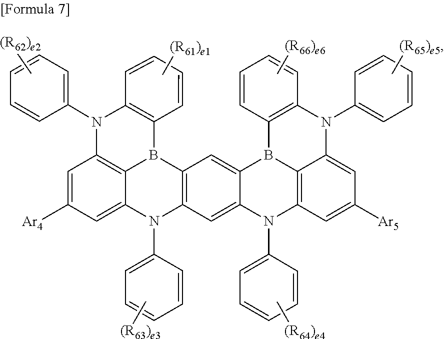
wherein in Formula 7,
each of e1 and e6 is independently an integer of 0 to 4, each of e2 to e5 is independently an integer of 0 to 5,
when e1 is 2 or more, two or more R₆₁ are same or different, when e2 is 2 or more, two or more R₆₂ are same or different, when e3 is 2 or more, two or more R₆₃ are same or different, when e4 is 2 or more, two or more R₆₄ are same or different, when e5 is 2 or more, two or more R₆₅ are same or different, when e6 is 2 or more, two or more R₆₆ are same or different,
each of R₆₁ to R₆₆ is independently selected from the group consisting of deuterium, a substituted or unsubstituted C1 to C20 alkyl group, a substituted or unsubstituted C1 to C20 alkoxy group, a substituted or unsubstituted C6 to C30 arylsilyl group, a substituted or unsubstituted C6 to C30 arylamino group, a substituted or unsubstituted C6 to C30 aryl group and a substituted or unsubstituted C3 to C30 heteroaryl group, and
each of Ar₄ and Ar₅ is independently selected from the group consisting of a substituted or unsubstituted C6 to C30 arylamino group, a substituted or unsubstituted C6 to C30 aryl group and a substituted or unsubstituted C3 to C30 heteroaryl group.

10. The organic light emitting diode according to claim 9, wherein the first fluorescent compound is one of compounds in Formula 8:

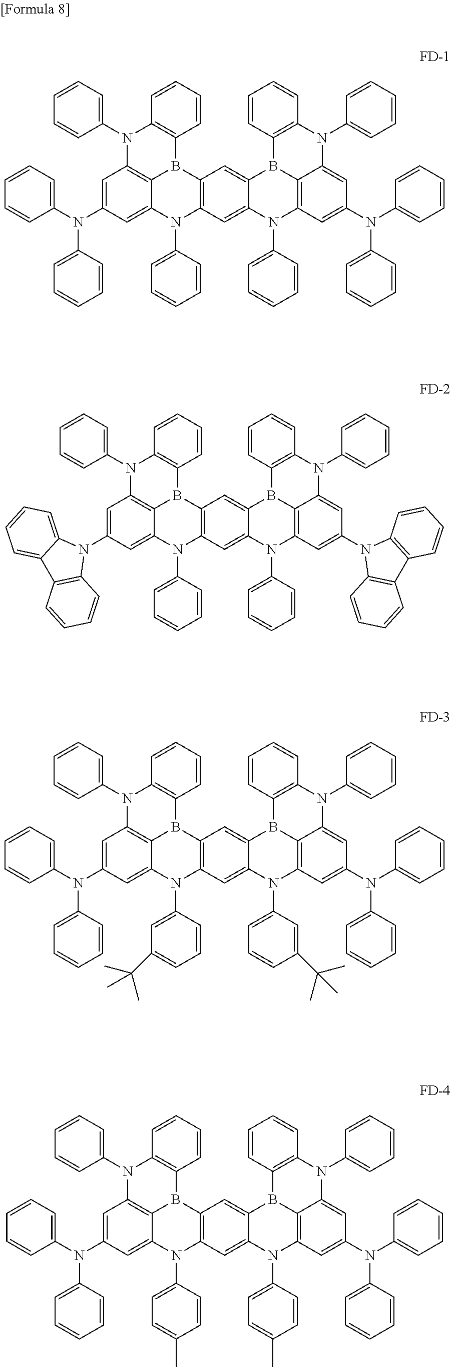

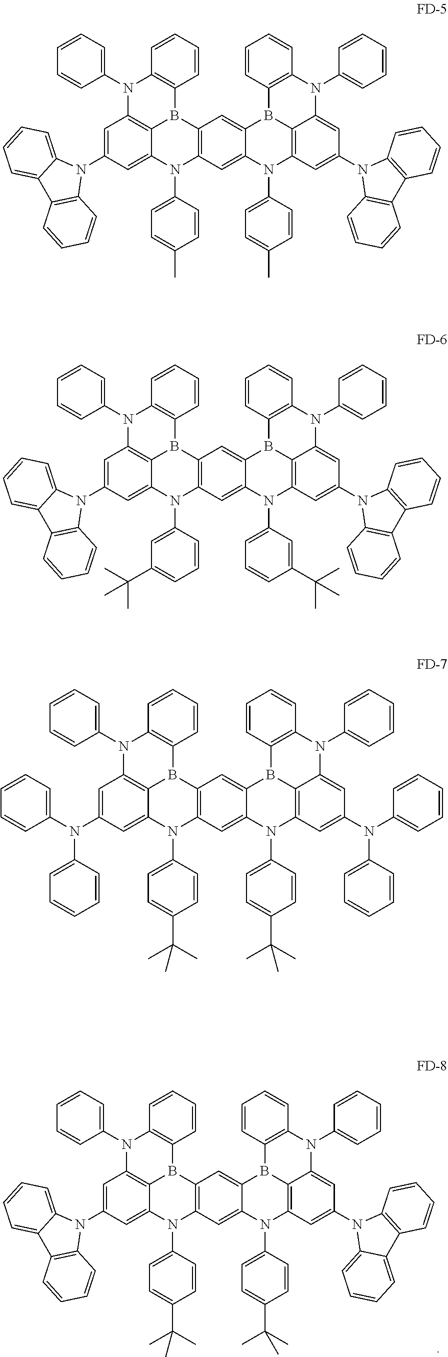

11. The organic light emitting diode according to claim 9, wherein each of a difference between a singlet energy level and a triplet energy level in the first compound and a difference between a singlet energy level and a triplet energy level in the first fluorescent compound is 0.3 eV or less.

12. The organic light emitting diode according to claim 11, wherein the difference between a singlet energy level and a triplet energy level in the first fluorescent compound is smaller than the difference between a singlet energy level and a triplet energy level in the first compound.

13. The organic light emitting diode according to claim 9, wherein a lowest unoccupied molecular orbital (LUMO) energy level of the first compound is lower than a LUMO energy level of the second compound and is higher than a LUMO energy level of the third compound,
wherein the LUMO energy level of the third compound is higher than a LUMO energy level of the first fluorescent compound,
wherein a difference between the LUMO energy level of the first compound and the LUMO energy level of the third compound is smaller than a difference between the LUMO energy level of the first compound and the LUMO energy level of the second compound, and
wherein a difference between the LUMO energy level of the third compound and the LUMO energy level of the first fluorescent compound is equal to or greater than a difference between the LUMO energy level of the first compound and the LUMO energy level of the second compound.

14. The organic light emitting diode according to claim 1, further comprising:
a second blue emitting material layer positioned between the first blue emitting material layer and the second electrode.

15. The organic light emitting diode according to claim 14, wherein the second blue emitting material layer includes a fourth compound, a fifth compound and a sixth compound, and
wherein the fourth compound is represented by Formula 1, the fifth compound is represented by Formula 3, and the sixth compound is represented by Formula 5.

16. The organic light emitting diode according to claim 15, wherein the second blue emitting material layer further includes a second fluorescent compound represented by Formula 7: 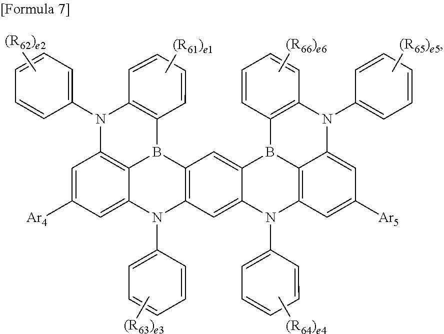
wherein in Formula 7,
each of e1 and e6 is independently an integer of 0 to 4, each of e2 to e5 is independently an integer of 0 to 5,
when e1 is 2 or more, two or more R₆₁ are same or different, when e2 is 2 or more, two or more R₆₂ are same or different, when e3 is 2 or more, two or more R₆₃ are same or different, when e4 is 2 or more, two or more R₆₄ are same or different, when e5 is 2 or more, two or more R₆₅ are same or different, when e6 is 2 or more, two or more R₆₆ are same or different,
each of R₆₁ to R₆₆ is independently selected from the group consisting of deuterium, a substituted or unsubstituted C1 to C20 alkyl group, a substituted or unsubstituted C1 to C20 alkoxy group, a substituted or unsubstituted C6 to C30 arylsilyl group, a substituted or unsubstituted C6 to C30 arylamino group, a substituted or unsubstituted C6 to C30 aryl group and a substituted or unsubstituted C3 to C30 heteroaryl group, and
each of Ar₄ and Ar₅ is independently selected from the group consisting of a substituted or unsubstituted C6 to C30 arylamino group, a substituted or unsubstituted C6 to C30 aryl group and a substituted or unsubstituted C3 to C30 heteroaryl group.

17. The organic light emitting diode according to claim 15, further comprising:
a third emitting material layer positioned between the first and second blue emitting material layers and including a red emitting material layer, a yellow-green emitting material layer and a green emitting material layer.

18. An organic light emitting device, comprising:
a substrate;
the organic light emitting diode according to claim 1 disposed on the substrate; and
an encapsulation layer covering the organic light emitting diode.

19. The organic light emitting device according to claim 18, wherein the first compound is one of compounds in Formula 2:

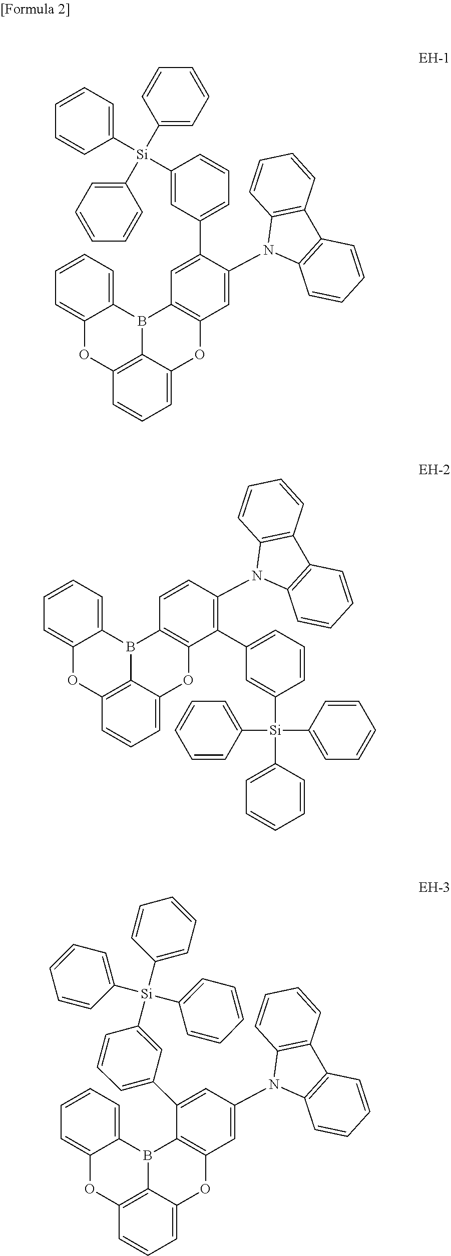 [SMILES: c1ccc([Si](c2ccccc2)(c2ccccc2)c2cccc(-c3cc4c(cc3-n3c5ccccc5c5ccccc53)Oc3cccc5c3B4c3ccccc3O5)c2)cc1 ; c1ccc([Si](c2ccccc2)(c2ccccc2)c2cccc(-c3c(-n4c5ccccc5c5ccccc54)ccc4c3Oc3cccc5c3B4c3ccccc3O5)c2)cc1 ; c1ccc([Si](c2ccccc2)(c2ccccc2)c2cccc(-c3cc(-n4c5ccccc5c5ccccc54)cc4c3B3c5ccccc5Oc5cccc(c53)O4)c2)cc1]

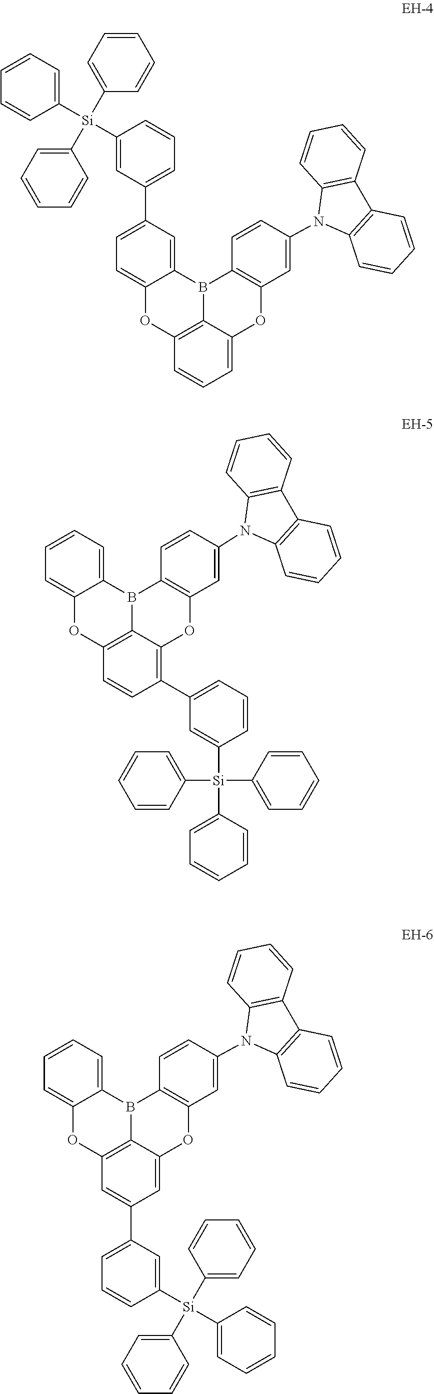 [SMILES: c1ccc([Si](c2ccccc2)(c2ccccc2)c2cccc(-c3ccc4c(c3)B3c5ccc(-n6c7ccccc7c7ccccc76)cc5Oc5cccc(c53)O4)c2)cc1 ; c1ccc([Si](c2ccccc2)(c2ccccc2)c2cccc(-c3ccc4c5c3Oc3cc(-n6c7ccccc7c7ccccc76)ccc3B5c3ccccc3O4)c2)cc1 ; c1ccc([Si](c2ccccc2)(c2ccccc2)c2cccc(-c3cc4c5c(c3)Oc3cc(-n6c7ccccc7c7ccccc76)ccc3B5c3ccccc3O4)c2)cc1]

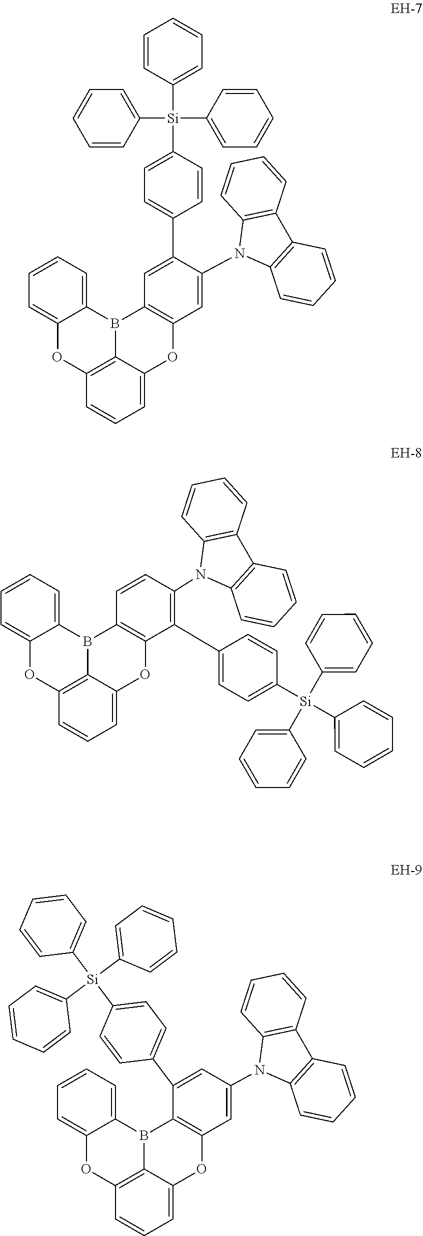 [SMILES: c1ccc([Si](c2ccccc2)(c2ccccc2)c2ccc(-c3cc4c(cc3-n3c5ccccc5c5ccccc53)Oc3cccc5c3B4c3ccccc3O5)cc2)cc1 ; c1ccc([Si](c2ccccc2)(c2ccccc2)c2ccc(-c3c(-n4c5ccccc5c5ccccc54)ccc4c3Oc3cccc5c3B4c3ccccc3O5)cc2)cc1 ; c1ccc([Si](c2ccccc2)(c2ccccc2)c2ccc(-c3cc(-n4c5ccccc5c5ccccc54)cc4c3B3c5ccccc5Oc5cccc(c53)O4)cc2)cc1]

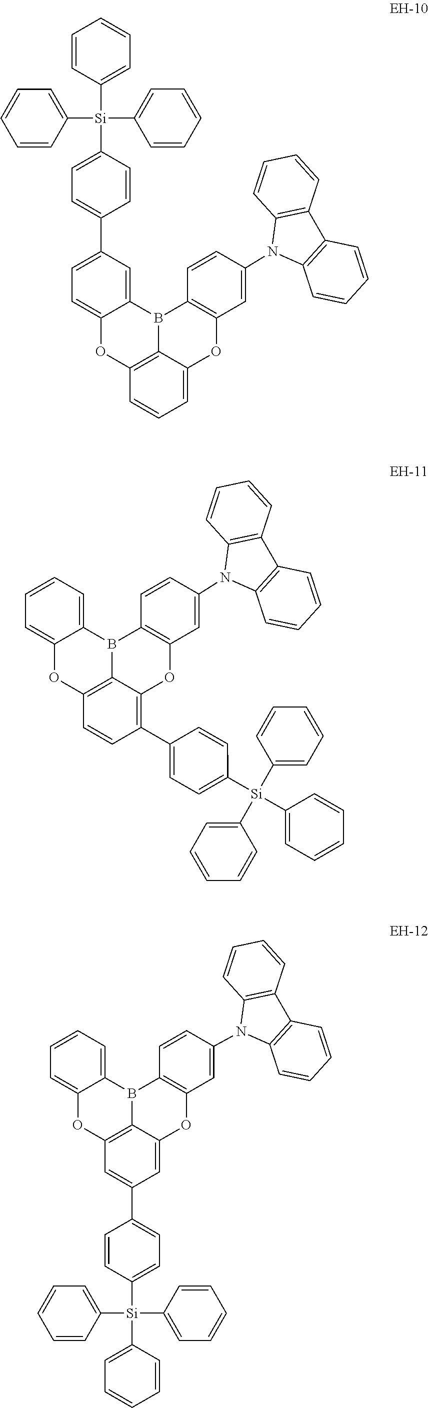 [SMILES: c1ccc([Si](c2ccccc2)(c2ccccc2)c2ccc(-c3ccc4c(c3)B3c5ccc(-n6c7ccccc7c7ccccc76)cc5Oc5cccc(c53)O4)cc2)cc1 ; c1ccc([Si](c2ccccc2)(c2ccccc2)c2ccc(-c3ccc4c5c3Oc3cc(-n6c7ccccc7c7ccccc76)ccc3B5c3ccccc3O4)cc2)cc1 ; c1ccc([Si](c2ccccc2)(c2ccccc2)c2ccc(-c3cc4c5c(c3)Oc3cc(-n6c7ccccc7c7ccccc76)ccc3B5c3ccccc3O4)cc2)cc1]

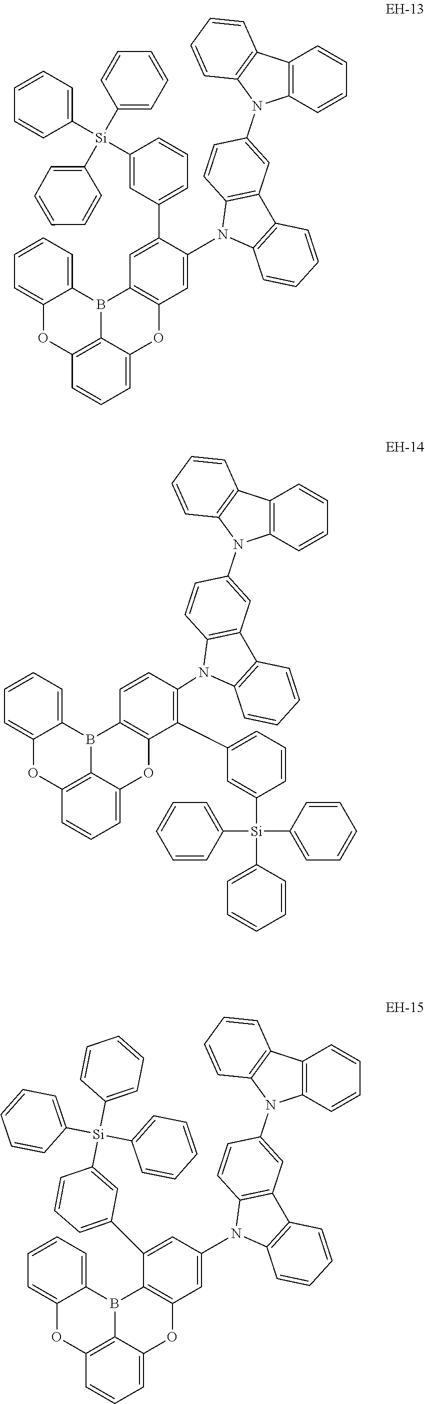 [SMILES: c1ccc([Si](c2ccccc2)(c2ccccc2)c2cccc(-c3cc4c(cc3-n3c5ccccc5c5cc(-n6c7ccccc7c7ccccc76)ccc53)Oc3cccc5c3B4c3ccccc3O5)c2)cc1 ; c1ccc([Si](c2ccccc2)(c2ccccc2)c2cccc(-c3c(-n4c5ccccc5c5cc(-n6c7ccccc7c7ccccc76)ccc54)ccc4c3Oc3cccc5c3B4c3ccccc3O5)c2)cc1 ; c1ccc([Si](c2ccccc2)(c2ccccc2)c2cccc(-c3cc(-n4c5ccccc5c5cc(-n6c7ccccc7c7ccccc76)ccc54)cc4c3B3c5ccccc5Oc5cccc(c53)O4)c2)cc1]

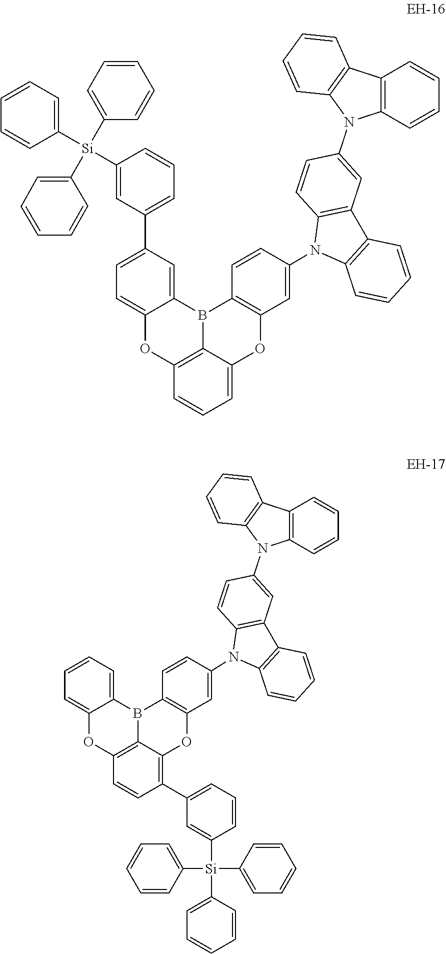 [SMILES: c1ccc([Si](c2ccccc2)(c2ccccc2)c2cccc(-c3ccc4c(c3)B3c5ccc(-n6c7ccccc7c7cc(-n8c9ccccc9c9ccccc98)ccc76)cc5Oc5cccc(c53)O4)c2)cc1 ; c1ccc([Si](c2ccccc2)(c2ccccc2)c2cccc(-c3ccc4c5c3Oc3cc(-n6c7ccccc7c7cc(-n8c9ccccc9c9ccccc98)ccc76)ccc3B5c3ccccc3O4)c2)cc1]

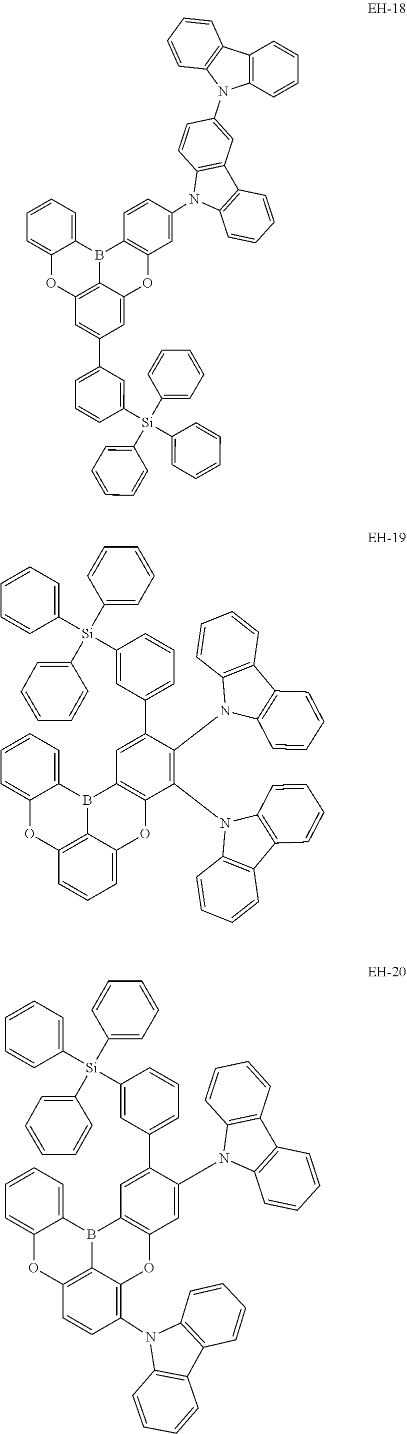 [SMILES: c1ccc([Si](c2ccccc2)(c2ccccc2)c2cccc(-c3cc4c5c(c3)Oc3cc(-n6c7ccccc7c7cc(-n8c9ccccc9c9ccccc98)ccc76)ccc3B5c3ccccc3O4)c2)cc1 ; c1ccc([Si](c2ccccc2)(c2ccccc2)c2cccc(-c3cc4c(c(-n5c6ccccc6c6ccccc65)c3-n3c5ccccc5c5ccccc53)Oc3cccc5c3B4c3ccccc3O5)c2)cc1 ; c1ccc([Si](c2ccccc2)(c2ccccc2)c2cccc(-c3cc4c(cc3-n3c5ccccc5c5ccccc53)Oc3c(-n5c6ccccc6c6ccccc65)ccc5c3B4c3ccccc3O5)c2)cc1]

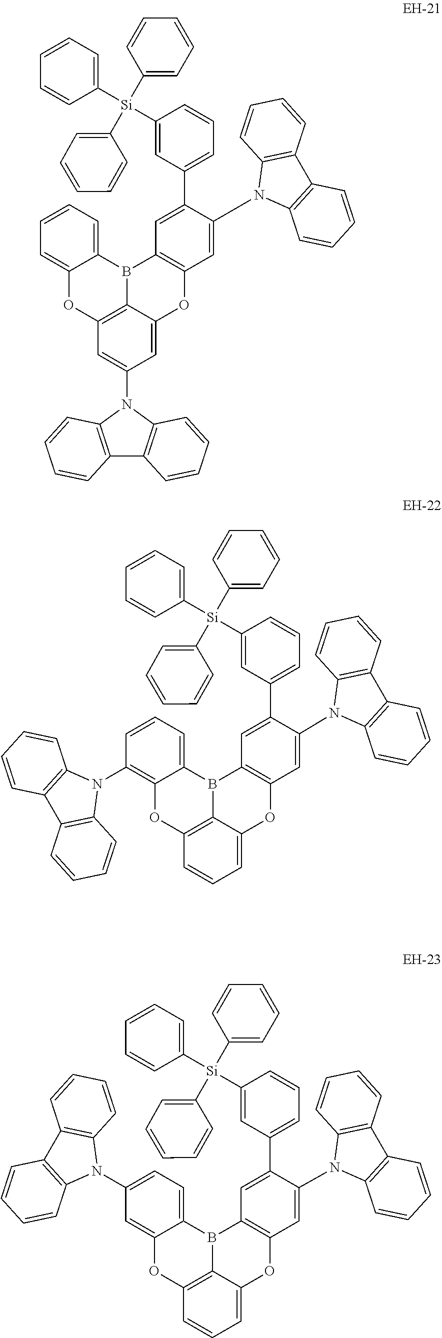 [SMILES: c1ccc([Si](c2ccccc2)(c2ccccc2)c2cccc(-c3cc4c(cc3-n3c5ccccc5c5ccccc53)Oc3cc(-n5c6ccccc6c6ccccc65)cc5c3B4c3ccccc3O5)c2)cc1 ; c1ccc([Si](c2ccccc2)(c2ccccc2)c2cccc(-c3cc4c(cc3-n3c5ccccc5c5ccccc53)Oc3cccc5c3B4c3cccc(-n4c6ccccc6c6ccccc64)c3O5)c2)cc1 ; c1ccc([Si](c2ccccc2)(c2ccccc2)c2cccc(-c3cc4c(cc3-n3c5ccccc5c5ccccc53)Oc3cccc5c3B4c3ccc(-n4c6ccccc6c6ccccc64)cc3O5)c2)cc1]

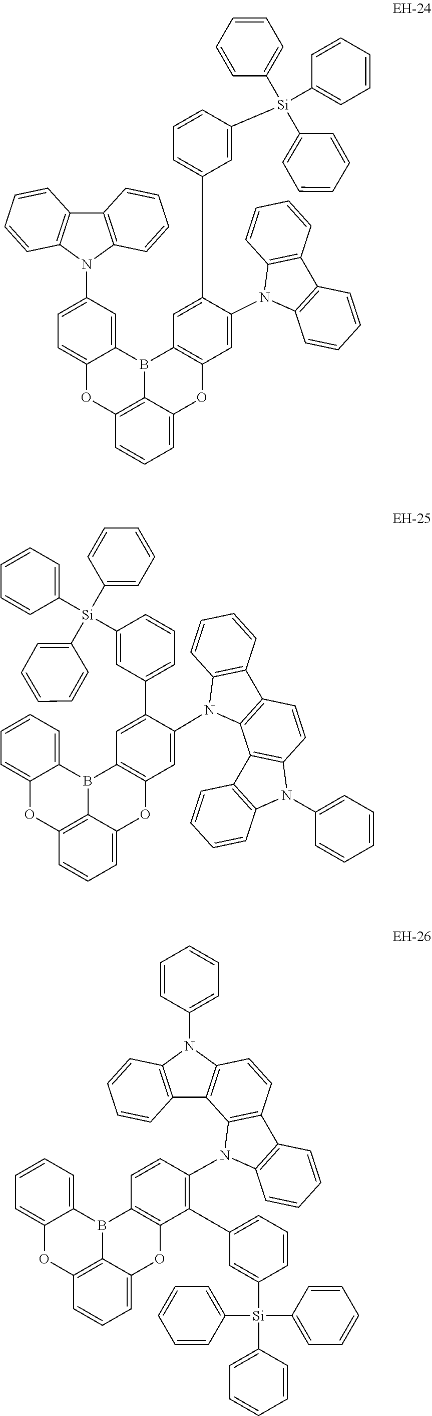 [SMILES: c1ccc([Si](c2ccccc2)(c2ccccc2)c2cccc(-c3cc4c(cc3-n3c5ccccc5c5ccccc53)Oc3cccc5c3B4c3cc(-n4c6ccccc6c6ccccc64)ccc3O5)c2)cc1 ; c1ccc(-n2c3ccccc3c3c2ccc2c4ccccc4n(-c4cc5c(cc4-c4cccc([Si](c6ccccc6)(c6ccccc6)c6ccccc6)c4)B4c6ccccc6Oc6cccc(c64)O5)c23)cc1 ; c1ccc(-n2c3ccccc3c3c2ccc2c4ccccc4n(-c4ccc5c(c4-c4cccc([Si](c6ccccc6)(c6ccccc6)c6ccccc6)c4)Oc4cccc6c4B5c4ccccc4O6)c23)cc1]

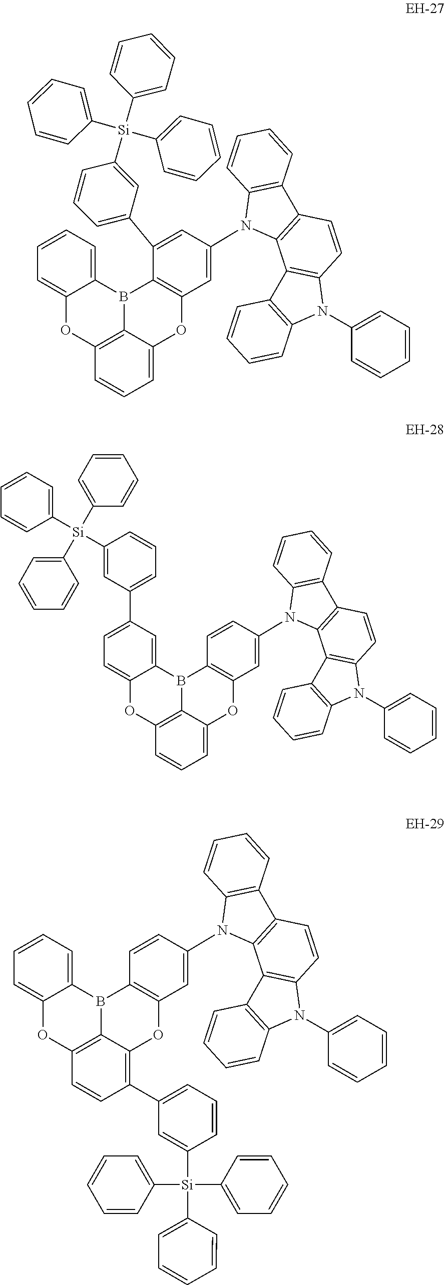 [SMILES: c1ccc(-n2c3ccccc3c3c2ccc2c4ccccc4n(-c4cc5c(c(-c6cccc([Si](c7ccccc7)(c7ccccc7)c7ccccc7)c6)c4)B4c6ccccc6Oc6cccc(c64)O5)c23)cc1 ; c1ccc(-n2c3ccccc3c3c2ccc2c4ccccc4n(-c4ccc5c(c4)Oc4cccc6c4B5c4cc(-c5cccc([Si](c7ccccc7)(c7ccccc7)c7ccccc7)c5)ccc4O6)c23)cc1 ; c1ccc(-n2c3ccccc3c3c2ccc2c4ccccc4n(-c4ccc5c(c4)Oc4c(-c6cccc([Si](c7ccccc7)(c7ccccc7)c7ccccc7)c6)ccc6c4B5c4ccccc4O6)c23)cc1]

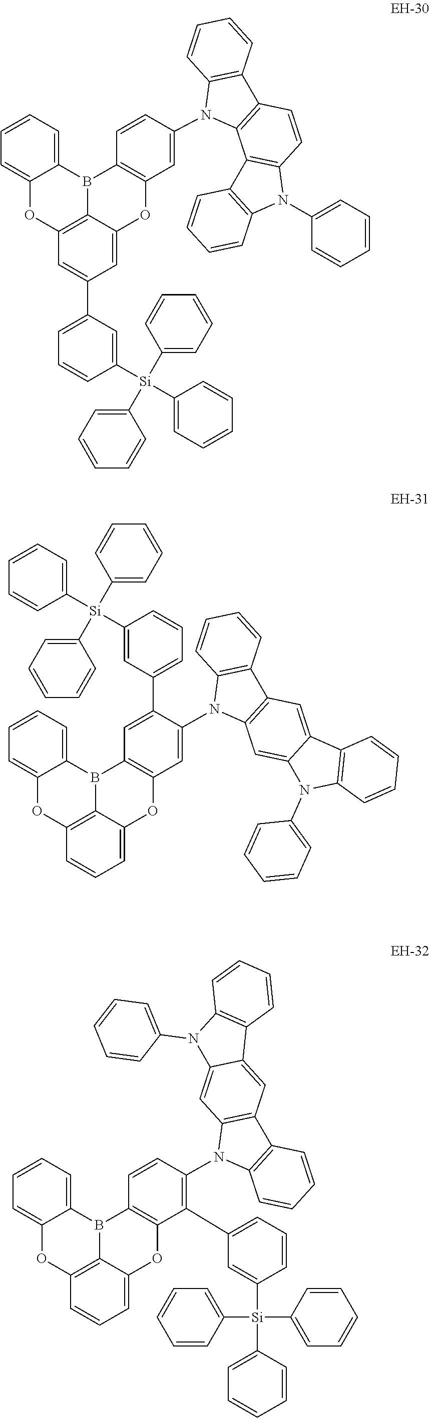 [SMILES: c1ccc(-n2c3ccccc3c3c2ccc2c4ccccc4n(-c4ccc5c(c4)Oc4cc(-c6cccc([Si](c7ccccc7)(c7ccccc7)c7ccccc7)c6)cc6c4B5c4ccccc4O6)c23)cc1 ; c1ccc(-n2c3ccccc3c3cc4c5ccccc5n(-c5cc6c(cc5-c5cccc([Si](c7ccccc7)(c7ccccc7)c7ccccc7)c5)B5c7ccccc7Oc7cccc(c75)O6)c4cc32)cc1 ; c1ccc(-n2c3ccccc3c3cc4c5ccccc5n(-c5ccc6c(c5-c5cccc([Si](c7ccccc7)(c7ccccc7)c7ccccc7)c5)Oc5cccc7c5B6c5ccccc5O7)c4cc32)cc1]

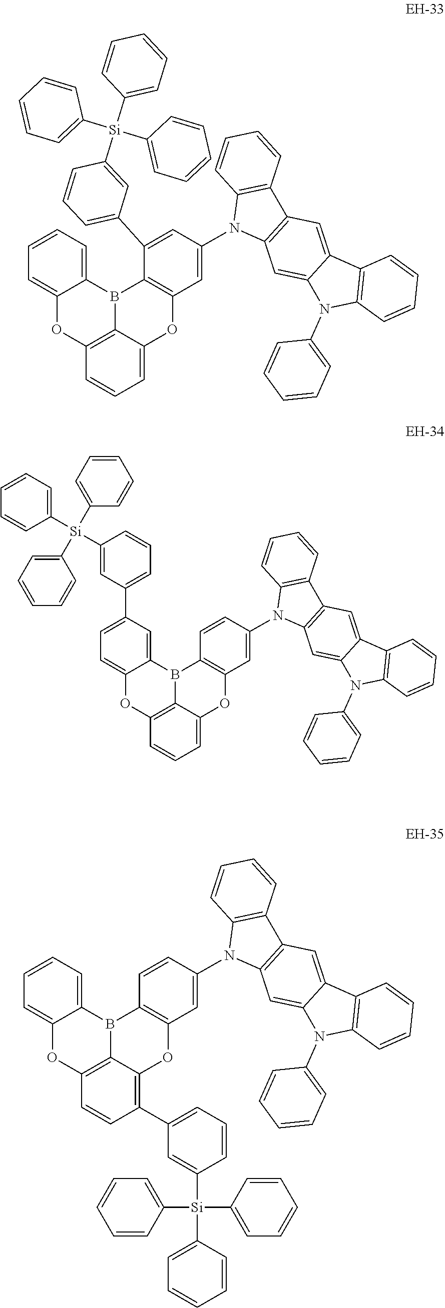 [SMILES: c1ccc(-n2c3ccccc3c3cc4c5ccccc5n(-c5cc6c(c(-c7cccc([Si](c8ccccc8)(c8ccccc8)c8ccccc8)c7)c5)B5c7ccccc7Oc7cccc(c75)O6)c4cc32)cc1 ; c1ccc(-n2c3ccccc3c3cc4c5ccccc5n(-c5ccc6c(c5)Oc5cccc7c5B6c5cc(-c6cccc([Si](c8ccccc8)(c8ccccc8)c8ccccc8)c6)ccc5O7)c4cc32)cc1 ; c1ccc(-n2c3ccccc3c3cc4c5ccccc5n(-c5ccc6c(c5)Oc5c(-c7cccc([Si](c8ccccc8)(c8ccccc8)c8ccccc8)c7)ccc7c5B6c5ccccc5O7)c4cc32)cc1]

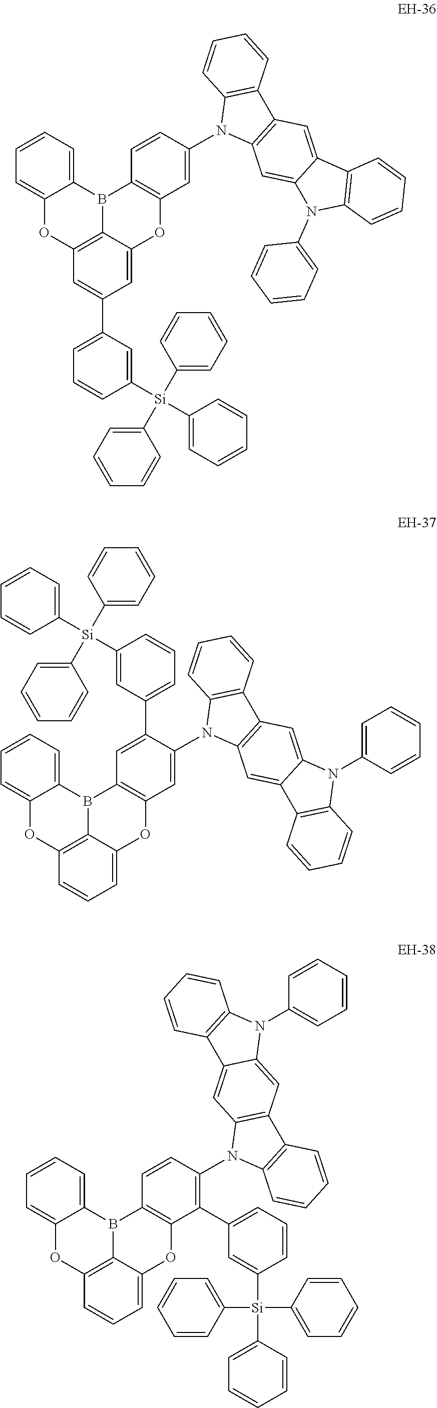 [SMILES: c1ccc(-n2c3ccccc3c3cc4c5ccccc5n(-c5ccc6c(c5)Oc5cc(-c7cccc([Si](c8ccccc8)(c8ccccc8)c8ccccc8)c7)cc7c5B6c5ccccc5O7)c4cc32)cc1 ; c1ccc(-n2c3ccccc3c3cc4c(cc32)c2ccccc2n4-c2cc3c(cc2-c2cccc([Si](c4ccccc4)(c4ccccc4)c4ccccc4)c2)B2c4ccccc4Oc4cccc(c42)O3)cc1 ; c1ccc(-n2c3ccccc3c3cc4c(cc32)c2ccccc2n4-c2ccc3c(c2-c2cccc([Si](c4ccccc4)(c4ccccc4)c4ccccc4)c2)Oc2cccc4c2B3c2ccccc2O4)cc1]

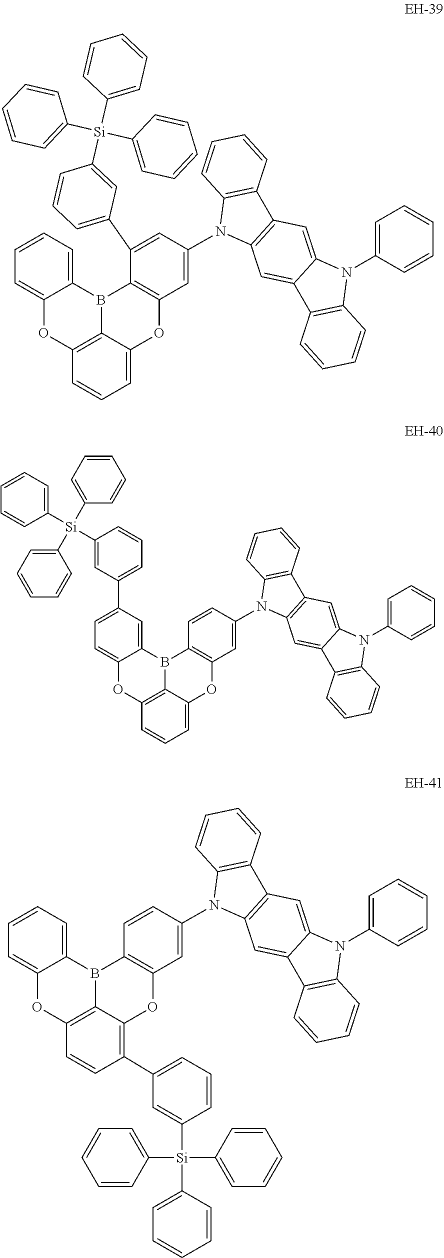 [SMILES: c1ccc(-n2c3ccccc3c3cc4c(cc32)c2ccccc2n4-c2cc3c(c(-c4cccc([Si](c5ccccc5)(c5ccccc5)c5ccccc5)c4)c2)B2c4ccccc4Oc4cccc(c42)O3)cc1 ; c1ccc(-n2c3ccccc3c3cc4c(cc32)c2ccccc2n4-c2ccc3c(c2)Oc2cccc4c2B3c2cc(-c3cccc([Si](c5ccccc5)(c5ccccc5)c5ccccc5)c3)ccc2O4)cc1 ; c1ccc(-n2c3ccccc3c3cc4c(cc32)c2ccccc2n4-c2ccc3c(c2)Oc2c(-c4cccc([Si](c5ccccc5)(c5ccccc5)c5ccccc5)c4)ccc4c2B3c2ccccc2O4)cc1]

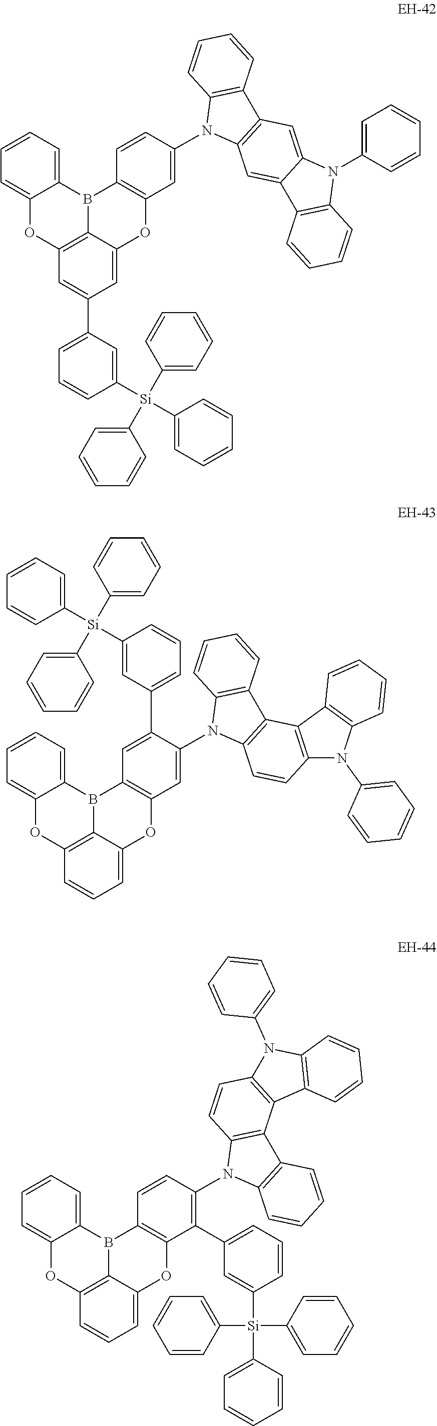 [SMILES: c1ccc(-n2c3ccccc3c3cc4c(cc32)c2ccccc2n4-c2ccc3c(c2)Oc2cc(-c4cccc([Si](c5ccccc5)(c5ccccc5)c5ccccc5)c4)cc4c2B3c2ccccc2O4)cc1 ; c1ccc(-n2c3ccccc3c3c4c5ccccc5n(-c5cc6c(cc5-c5cccc([Si](c7ccccc7)(c7ccccc7)c7ccccc7)c5)B5c7ccccc7Oc7cccc(c75)O6)c4ccc32)cc1 ; c1ccc(-n2c3ccccc3c3c4c5ccccc5n(-c5ccc6c(c5-c5cccc([Si](c7ccccc7)(c7ccccc7)c7ccccc7)c5)Oc5cccc7c5B6c5ccccc5O7)c4ccc32)cc1]

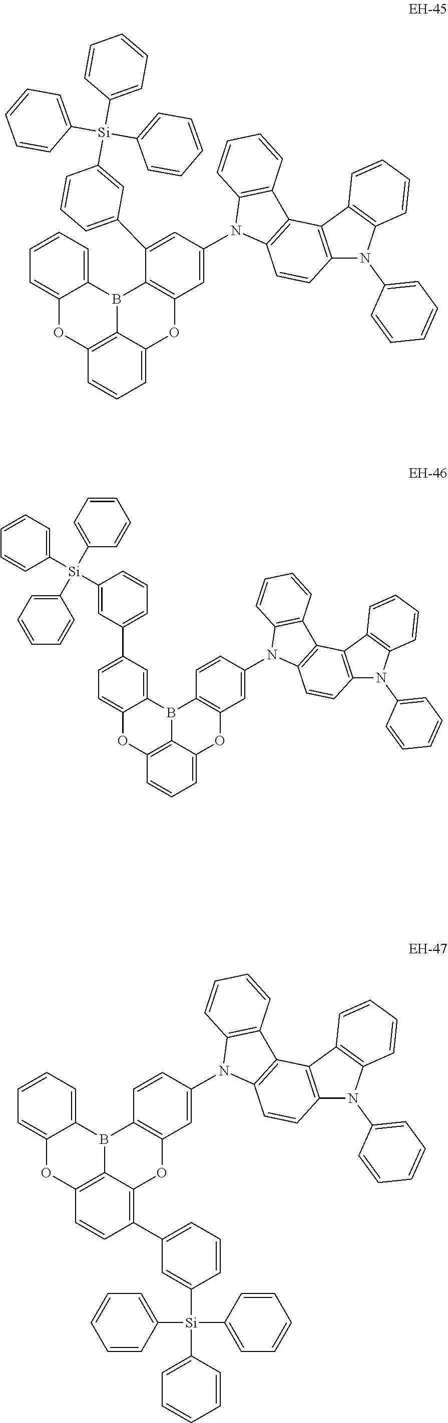 [SMILES: c1ccc(-n2c3ccccc3c3c4c5ccccc5n(-c5cc6c(c(-c7cccc([Si](c8ccccc8)(c8ccccc8)c8ccccc8)c7)c5)B5c7ccccc7Oc7cccc(c75)O6)c4ccc32)cc1 ; c1ccc(-n2c3ccccc3c3c4c5ccccc5n(-c5ccc6c(c5)Oc5cccc7c5B6c5cc(-c6cccc([Si](c8ccccc8)(c8ccccc8)c8ccccc8)c6)ccc5O7)c4ccc32)cc1 ; c1ccc(-n2c3ccccc3c3c4c5ccccc5n(-c5ccc6c(c5)Oc5c(-c7cccc([Si](c8ccccc8)(c8ccccc8)c8ccccc8)c7)ccc7c5B6c5ccccc5O7)c4ccc32)cc1]

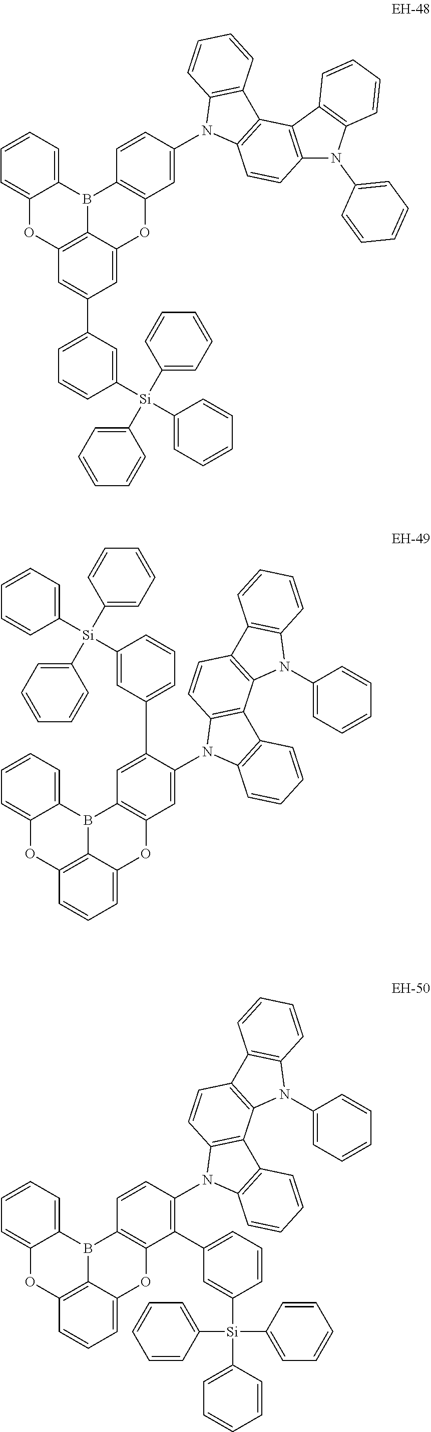 [SMILES: c1ccc(-n2c3ccccc3c3c4c5ccccc5n(-c5ccc6c(c5)Oc5cc(-c7cccc([Si](c8ccccc8)(c8ccccc8)c8ccccc8)c7)cc7c5B6c5ccccc5O7)c4ccc32)cc1 ; c1ccc(-n2c3ccccc3c3ccc4c(c5ccccc5n4-c4cc5c(cc4-c4cccc([Si](c6ccccc6)(c6ccccc6)c6ccccc6)c4)B4c6ccccc6Oc6cccc(c64)O5)c32)cc1 ; c1ccc(-n2c3ccccc3c3ccc4c(c5ccccc5n4-c4ccc5c(c4-c4cccc([Si](c6ccccc6)(c6ccccc6)c6ccccc6)c4)Oc4cccc6c4B5c4ccccc4O6)c32)cc1]

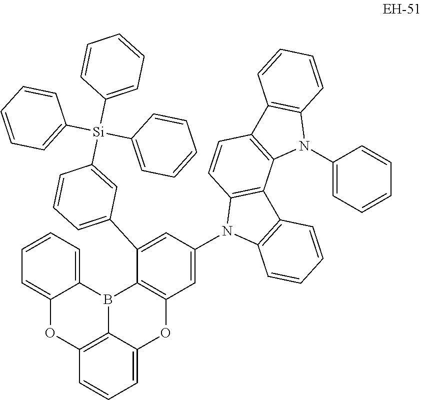 [SMILES: c1ccc(-n2c3ccccc3c3ccc4c(c5ccccc5n4-c4cc5c(c(-c6cccc([Si](c7ccccc7)(c7ccccc7)c7ccccc7)c6)c4)B4c6ccccc6Oc6cccc(c64)O5)c32)cc1]

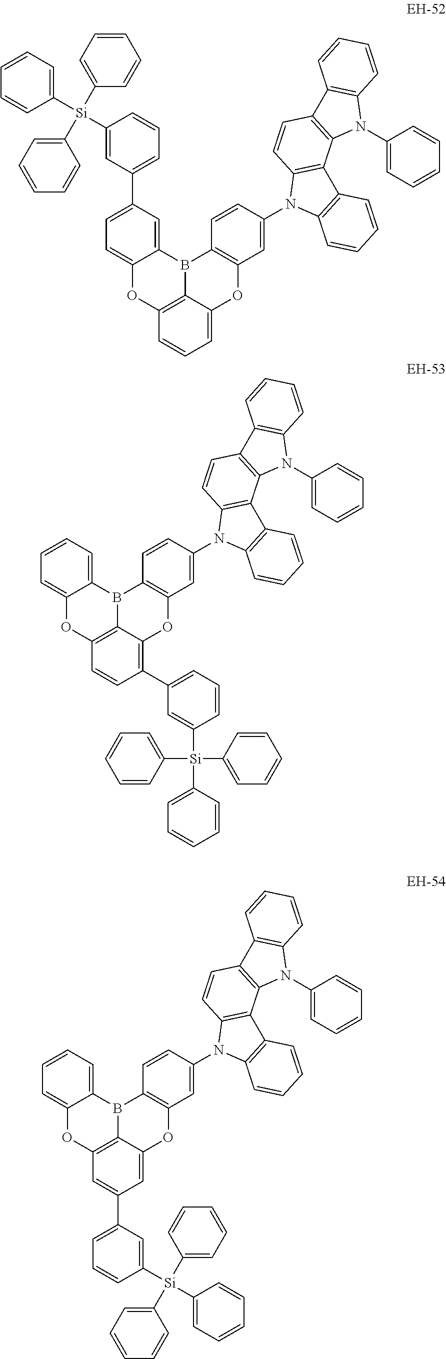 [SMILES: c1ccc(-n2c3ccccc3c3ccc4c(c5ccccc5n4-c4ccc5c(c4)Oc4cccc6c4B5c4cc(-c5cccc([Si](c7ccccc7)(c7ccccc7)c7ccccc7)c5)ccc4O6)c32)cc1 ; c1ccc(-n2c3ccccc3c3ccc4c(c5ccccc5n4-c4ccc5c(c4)Oc4c(-c6cccc([Si](c7ccccc7)(c7ccccc7)c7ccccc7)c6)ccc6c4B5c4ccccc4O6)c32)cc1 ; c1ccc(-n2c3ccccc3c3ccc4c(c5ccccc5n4-c4ccc5c(c4)Oc4cc(-c6cccc([Si](c7ccccc7)(c7ccccc7)c7ccccc7)c6)cc6c4B5c4ccccc4O6)c32)cc1]

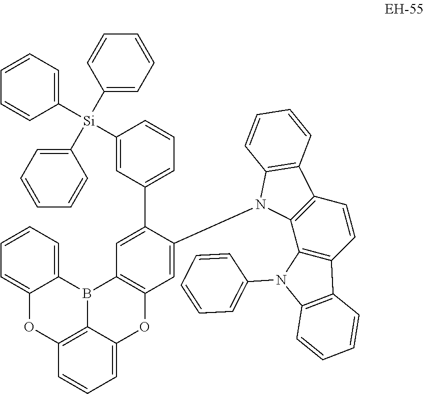 [SMILES: c1ccc(-n2c3ccccc3c3ccc4c5ccccc5n(-c5cc6c(cc5-c5cccc([Si](c7ccccc7)(c7ccccc7)c7ccccc7)c5)B5c7ccccc7Oc7cccc(c75)O6)c4c32)cc1]

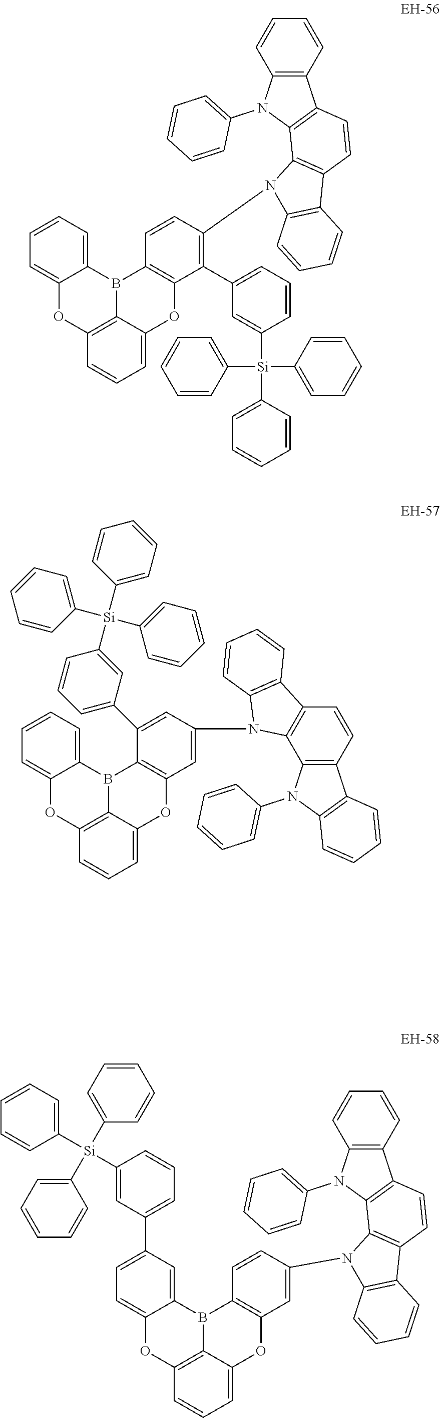 [SMILES: c1ccc(-n2c3ccccc3c3ccc4c5ccccc5n(-c5ccc6c(c5-c5cccc([Si](c7ccccc7)(c7ccccc7)c7ccccc7)c5)Oc5cccc7c5B6c5ccccc5O7)c4c32)cc1 ; c1ccc(-n2c3ccccc3c3ccc4c5ccccc5n(-c5cc6c(c(-c7cccc([Si](c8ccccc8)(c8ccccc8)c8ccccc8)c7)c5)B5c7ccccc7Oc7cccc(c75)O6)c4c32)cc1 ; c1ccc(-n2c3ccccc3c3ccc4c5ccccc5n(-c5ccc6c(c5)Oc5cccc7c5B6c5cc(-c6cccc([Si](c8ccccc8)(c8ccccc8)c8ccccc8)c6)ccc5O7)c4c32)cc1]

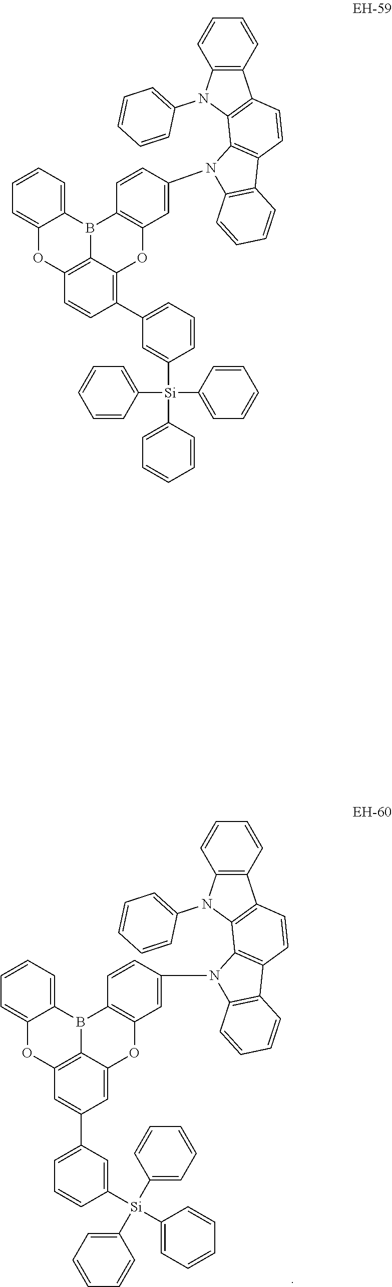 [SMILES: c1ccc(-n2c3ccccc3c3ccc4c5ccccc5n(-c5ccc6c(c5)Oc5c(-c7cccc([Si](c8ccccc8)(c8ccccc8)c8ccccc8)c7)ccc7c5B6c5ccccc5O7)c4c32)cc1 ; c1ccc(-n2c3ccccc3c3ccc4c5ccccc5n(-c5ccc6c(c5)Oc5cc(-c7cccc([Si](c8ccccc8)(c8ccccc8)c8ccccc8)c7)cc7c5B6c5ccccc5O7)c4c32)cc1]

20. The organic light emitting device according to claim 18, wherein the second compound is one of compounds in Formula 4:

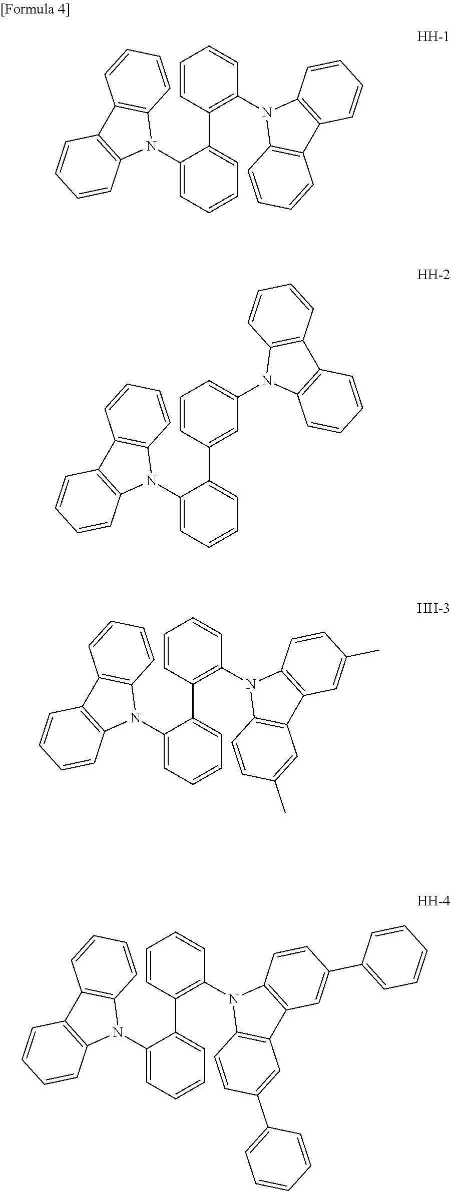 [SMILES: c1ccc(-n2c3ccccc3c3ccccc32)c(-c2ccccc2-n2c3ccccc3c3ccccc32)c1 ; c1cc(-c2ccccc2-n2c3ccccc3c3ccccc32)cc(-n2c3ccccc3c3ccccc32)c1 ; Cc1ccc2c(c1)c1cc(C)ccc1n2-c1ccccc1-c1ccccc1-n1c2ccccc2c2ccccc21 ; c1ccc(-c2ccc3c(c2)c2cc(-c4ccccc4)ccc2n3-c2ccccc2-c2ccccc2-n2c3ccccc3c3ccccc32)cc1]

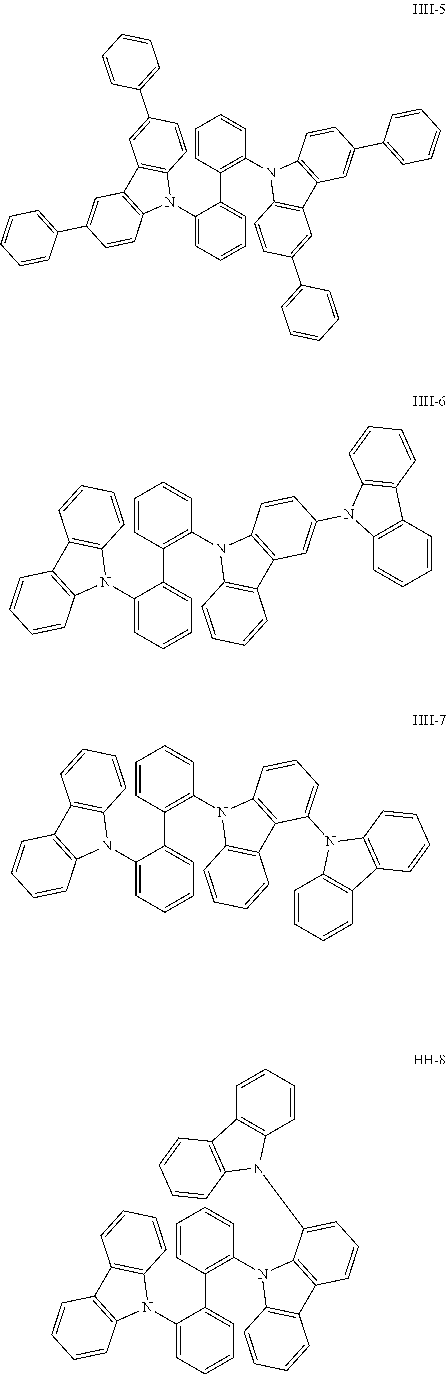 [SMILES: c1ccc(-c2ccc3c(c2)c2cc(-c4ccccc4)ccc2n3-c2ccccc2-c2ccccc2-n2c3ccc(-c4ccccc4)cc3c3cc(-c4ccccc4)ccc32)cc1 ; c1ccc(-n2c3ccccc3c3ccccc32)c(-c2ccccc2-n2c3ccccc3c3cc(-n4c5ccccc5c5ccccc54)ccc32)c1 ; c1ccc(-n2c3ccccc3c3ccccc32)c(-c2ccccc2-n2c3ccccc3c3c(-n4c5ccccc5c5ccccc54)cccc32)c1 ; c1ccc(-n2c3ccccc3c3ccccc32)c(-c2ccccc2-n2c3ccccc3c3cccc(-n4c5ccccc5c5ccccc54)c32)c1]

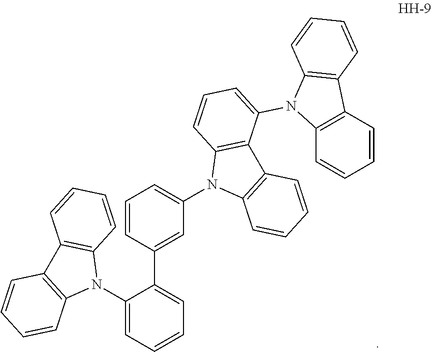 [SMILES: c1cc(-c2ccccc2-n2c3ccccc3c3ccccc32)cc(-n2c3ccccc3c3c(-n4c5ccccc5c5ccccc54)cccc32)c1]

21. The organic light emitting device according to claim 18, wherein the third compound is one of compounds in Formula 6: 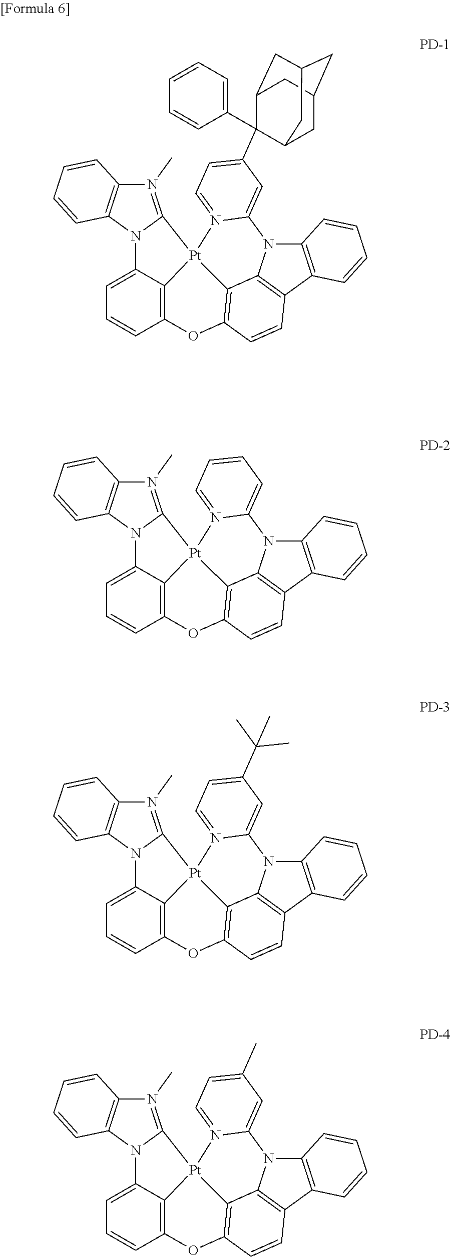 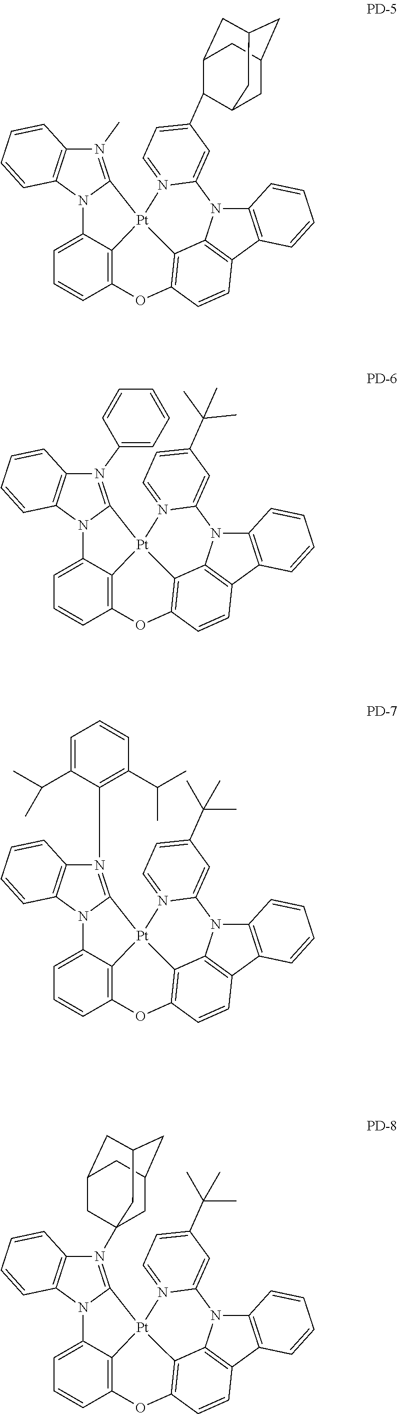 [chemical structure]
